(19) United States
(12) Patent Application Publication
(10) Pub. No.: US 2020/0136050 A1
(43) Pub. Date: Apr. 30, 2020

(54) COMPOSITION FOR ORGANIC LAYER OF ORGANIC SOLAR CELL AND METHOD FOR MANUFACTURING ORGANIC SOLAR CELL USING SAME

(71) Applicant: LG CHEM, LTD., Seoul (KR)

(72) Inventors: Doowhan CHOI, Daejeon (KR); Jiyoung LEE, Daejeon (KR); Songrim JANG, Daejeon (KR); Bogyu LIM, Daejeon (KR)

(21) Appl. No.: 16/619,531

(22) PCT Filed: Mar. 7, 2019
(86) PCT No.: PCT/KR2019/002651

§ 371 Date: Dec. 5, 2019

(30) Foreign Application Priority Data
Mar. 9, 2018 (KR) 10-2018-0028139

(51) Int. Cl. H01L 51/00; H01L 51/42; H01L 51/44

(52) U.S. Cl. CPC H01L 51/0043; H01L 51/0074; H01L 51/0069; H01L 51/441; H01L 51/0073; H01L 51/0036; H01L 51/4253; H01L 51/0072

(57) ABSTRACT

The present specification relates to a composition for an organic material layer of an organic solar cell, the composition including: a polymer including a first unit represented by Formula 1, a second unit represented by Formula 2, a third unit represented by Formula 3 or 4; and a non-halogen-based solvent, a method for manufacturing an organic solar cell using the same, and an organic solar cell manufactured thereby.

### TECHNICAL FIELD

This application claims priority to and the benefit of Korean Patent Application No. 10-2018-0028139 filed in the Korean Intellectual Property Office on Mar. 9, 2018, the entire contents of which are incorporated herein by reference.

The present specification relates to a composition for an organic material layer of an organic solar cell and a method for manufacturing an organic solar cell using the same.

### BACKGROUND ART

An organic solar cell is a device which may directly convert solar energy into electric energy by applying a photovoltaic effect. A solar cell may be divided into an inorganic solar cell and an organic solar cell, depending on the materials constituting a thin film. Typical solar cells are manufactured using a p-n junction by doping crystalline silicon (Si), which is an inorganic semiconductor. Electrons and holes generated by absorbing light diffuse to p-n junction points and move to an electrode while being accelerated by the electric field. The power conversion efficiency in this process is defined as the ratio of electric power given to an external circuit and solar power entering the solar cell, and the efficiency have reached approximately 24% when measured under a currently standardized virtual solar irradiation condition. However, since inorganic solar cells in the related art have already shown the limitation in economic feasibility and material demands and supplies, an organic semiconductor solar cell, which is easily processed and inexpensive and has various functionalities, has drawn attention as a long-term alternative energy source.

For the solar cell, it is important to increase efficiency so as to output as much electric energy as possible from solar energy. In order to increase the efficiency of the solar cell, it is important to generate as many excitons as possible inside a semiconductor, but it is also important to pull the generated charges to the outside without loss. One of the reasons for the charge loss is the dissipation of generated electrons and holes due to recombination. Various methods have been proposed to deliver generated electrons and holes to an electrode without loss, but additional processes are required in most cases, and accordingly, manufacturing costs may be increased.

### DETAILED DESCRIPTION OF INVENTION

### Technical Problem

The present specification provides a composition for an organic material layer of an organic solar cell, a method for manufacturing an organic solar cell using the composition, and an organic solar cell obtained thereby.

### Technical Solution

An exemplary embodiment of the present specification provides a composition for an organic material layer of an organic solar cell, the composition including: a polymer including a first unit represented by the following Formula 1, a second unit represented by the following Formula 2, and a third unit represented by the following Formula 3 or 4; and a non-halogen-based solvent.

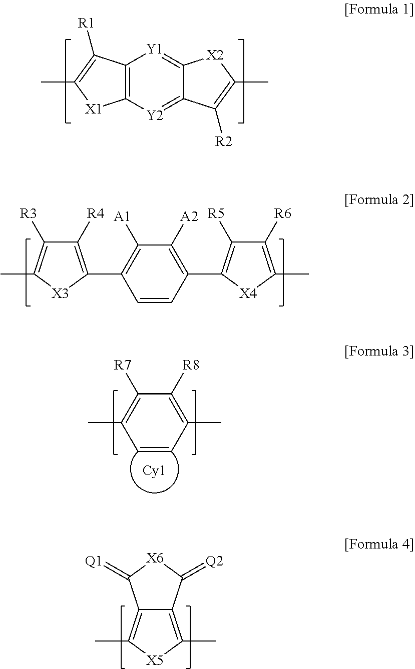

In Formulae 1 to 4,

X1 to X6 are the same as or different from each other, and are each independently CRR′, NR, O, SiRR′, PR, S, GeRR′, Se, or Te,

Y1 and Y2 are the same as or different from each other, and are each independently CR″, N, SiR″, P, or GeR″,

A1 and A2 are the same as or different from each other, and are each independently a halogen group,

Cy1 is a substituted or unsubstituted hetero ring,

Q1 and Q2 are the same as or different from each other, and are each independently O or S, and

R, R′, R″, and R1 to R8 are the same as or different from each other, and are each independently hydrogen; deuterium; a halogen group; a nitrile group; a nitro group; an imide group; an amide group; a hydroxyl group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted amine group; a substituted or unsubstituted aryl group; or a substituted or unsubstituted heterocyclic group.

Further, another exemplary embodiment of the present specification provides a method for manufacturing an organic solar cell, the organic solar cell including: a first electrode; a second electrode provided to face the first electrode; and an organic material layer having one or more layers provided between the first electrode and the second electrode and including a photoactive layer, in which one or more layers of the organic material layer are formed by using the above-described composition for an organic material layer of an organic solar cell.

In addition, still another exemplary embodiment of the present specification provides an organic solar cell including: a first electrode; a second electrode provided to face the first electrode; and an organic material layer having one or more organic layers provided between the first electrode and the second electrode and including a photoactive layer, in which one or more layers of the organic material layer are formed by using the above-described composition for an organic material layer of an organic solar cell.

### Advantageous Effects

A polymer according to an exemplary embodiment of the present specification may achieve high efficiency in an organic solar cell even when an organic material layer of the organic solar cell is manufactured by using a non-halogen-based solvent.

Further, the polymer according to an exemplary embodiment of the present specification has thermal stability as a conductive material, and has excellent solubility and high electron mobility. Accordingly, the polymer according to an exemplary embodiment of the present specification may exhibit excellent electrical characteristics when applied to an organic solar cell.

In addition, the polymer according to an exemplary embodiment of the present specification has a high HOMO energy level, and thus, when an organic solar cell including the polymer is implemented, the organic solar cell has excellent efficiency characteristics.

### BRIEF DESCRIPTION OF DRAWINGS

FIG. 1 is a view illustrating an organic solar cell according to an exemplary embodiment of the present specification.

FIG. 2 is a photograph illustrating the results of manufacturing devices in Comparative Examples 3 and 4.

FIG. 3 is a photograph illustrating the results of manufacturing devices in Comparative Examples 6 and 7.

### EXPLANATION OF REFERENCE NUMERALS AND SYMBOLS

101: First electrode
102: Electron transport layer
103: Photoactive layer
104: Hole transport layer
105: Second electrode

### BEST MODE

Hereinafter, the present specification will be described in more detail.

In the present specification, the ‘unit’ means a repeated structure included in a monomer of a polymer, and a structure in which the monomer is bonded to the polymer by polymerization.

In the present specification, the meaning of ‘including a unit’ means that the unit is included in a main chain in the polymer.

When one part “includes” one constituent element in the present specification, unless otherwise specifically described, this does not mean that another constituent element is excluded, but means that another constituent element may be further included.

In the present specification, the energy level means a size of energy. Accordingly, even when the energy level is expressed in the negative (−) direction from the vacuum level, it is interpreted that the energy level means an absolute value of the corresponding energy value. For example, the HOMO energy level means the distance from the vacuum level to the highest occupied molecular orbital. Further, the LUMO energy level means the distance from the vacuum level to the lowest unoccupied molecular orbital.

An exemplary embodiment of the present specification provides a composition for an organic material layer of an organic solar cell, the composition including: a polymer including a first unit represented by the following Formula 1, a second unit represented by the following Formula 2, and a third unit represented by the following Formula 3 or 4; and a non-halogen-based solvent.

Since organic solar cells are lightweight and flexible and may implement various colors, the organic solar cells have been studied in many places, but a halogen-based solvent has been mainly used as a solvent used in the solution process in most cases. However, the halogen-based solvent is fatal not only to the environment, but also to health, which may be a major obstacle to commercialization. However, the polymer developed by the present inventors may provide a device with high efficiency even when the polymer is applied to the device by a process using a non-halogen-based solvent.

As the non-halogen-based solvent, a non-halogen-based solvent, which serves as a solvent for the polymer included in the composition, and simultaneously, does not include halogen, may be used. For example, the non-halogen-based solvent may have solubility for the polymer of 0.1 wt % or more, specifically, 0.1 wt % to 10 wt %. The solubility is based on 100 wt % of the solvent, and a method for measuring the solubility may use, for example, a method of dissolving the polymer in 1 ml of the solvent and measuring how much the polymer is dissolved without particles. The solubility of 0.1 wt % means that 1 mg (0.1 wt %) of the polymer may be dissolved in 1 ml of the solvent, and the solubility of 10 wt % means that 100 mg (10 wt %) of the polymer may be dissolved in 1 ml of the solvent.

According to an exemplary embodiment of the present application, the non-halogen-based solvent has a relative polarity of preferably 0.75 or less. The relative polarity means a relative numerical value of a polarity index.

According to an exemplary embodiment of the present application, the non-halogen-based solvent has a boiling point of preferably 50° C. to 300° C.

As described above, when a non-halogen-based solvent satisfies the above-described solubility, the above-described polymer may be dissolved well in a solvent, which enables a device to be manufactured by the solution process. According to an example, it is preferred that the non-halogen-based solvent also has a solubility for an electron acceptor, to be described below, of 0.1 wt % or more, for example, 0.1 wt % to 10 wt %.

Further, when the non-halogen-based solvent satisfies the solubility, the relative polarity, and the boiling point described above, an appropriate phase separation is achieved when a film is formed by using a composition in which a polymer that functions as an electron donor and a material that functions as an electron acceptor are dissolved in a solvent, so that it is possible to improve the efficiency of a photoactive layer of an organic solar cell. Specifically, depending on the solvent, the solubilities of an electron donor and an electron acceptor may be different and the distribution of the electron donor and the electron acceptor in the solvent may vary, so that differences in surface form, morphology, and molecular crystallinity of a photoactive layer to be finally manufactured occur depending on the solvent, and these differences affect the performance and efficiency of the device. When the non-halogen-based solvent satisfies the solubility, the relative polarity, and the boiling point described above, smooth surface characteristics may be obtained, the morphology is appropriately mixed at around 10 nm, and the molecular crystallinity is a large face-on type, so that the efficiency of the device may be improved. The surface of a film or photoactive layer formed by the composition may be confirmed by AFM or TEM analysis, and the inside of the film or photoactive layer may be analyzed by GIXD analysis.

In an exemplary embodiment of the present specification, a content of the non-halogen-based solvent in 100 wt % of the composition may be determined according to the process condition, the material used together, and the like.

The non-halogen-based solvent may also be trapped inside an organic material layer during the process of forming the organic material layer such as the photoactive layer of the organic solar cell, and may be completely evaporated during the drying process.

In an exemplary embodiment of the present specification, the non-halogen-based solvent may include one or two or more selected from toluene, xylene, 2-methylanisole, ethylbenzene, trimethylbenzene, tolyl acetate, p-tolyl ether, and diphenyl ether. As a preferred example, the non-halogen-based solvent is toluene or 2-methylanisole.

In an exemplary embodiment of the present specification, the polymer includes: the first unit represented by Formula 1; the second unit represented by Formula 2; and the third unit represented by Formula 3 or 4.

In particular, the polymer includes the second unit represented by Formula 2. In an exemplary embodiment of the present specification, A1 and A2 are mutually substituted at the ortho position of the benzene ring. In this case, the polymer exhibits low crystallinity, so that a small domain is formed. Accordingly, an organic solar cell including the polymer exhibits excellent electrical characteristics and has excellent efficiency.

Examples of the substituents will be described below, but are not limited thereto.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present specification, the term “substituted or unsubstituted” means being substituted with one or more substituents selected from the group consisting of deuterium; a halogen group; a nitrile group; a nitro group; an imide group; an amide group; a hydroxyl group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted silyl group; a substituted or unsubstituted boron group; a substituted or unsubstituted amine group; a substituted or unsubstituted aryl group; and a substituted or unsubstituted heterocyclic group or being substituted with a substituent to which two or more substituents are linked among the substituents exemplified above, or having no substituent. For example, “the substituent to which two or more substituents are linked” may be a biphenyl group. That is, the biphenyl group may also be an aryl group, and may be interpreted as a substituent to which two phenyl groups are linked.

In the present specification, the number of carbon atoms of an imide group is not particularly limited, but is preferably 1 to 30. Specifically, the imide group may be a compound having the following structures, but is not limited thereto.

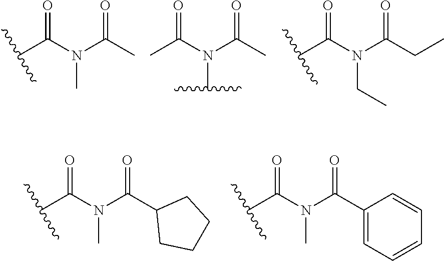

In the present specification, for an amide group, one or two nitrogen atoms of the amide group may be substituted with hydrogen, a straight-chained, branched, or cyclic alkyl group having 1 to 30 carbon atoms, or an aryl group having 6 to 30 carbon atoms. Specifically, the amide group may be a compound having the following structural formulae, but is not limited thereto.

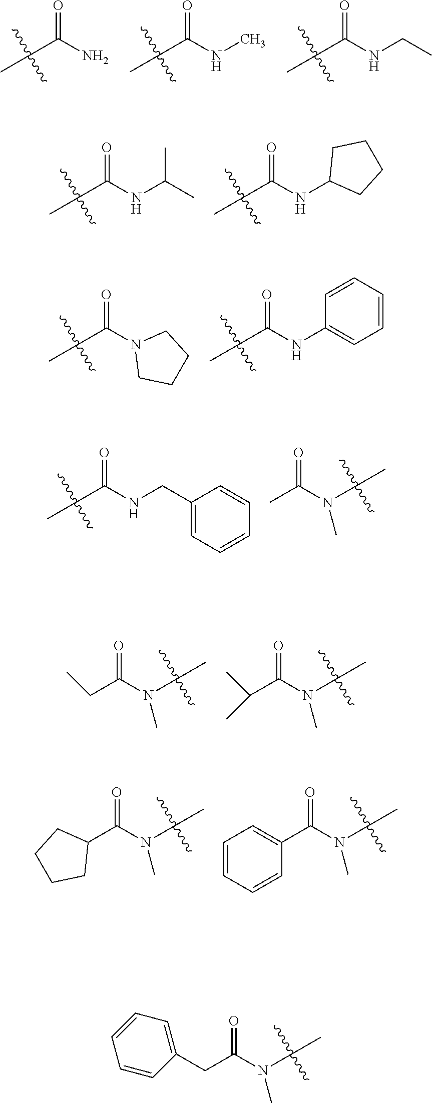

In the present specification, examples of a halogen group include fluorine, chlorine, bromine or iodine.

In the present specification, the alkyl group may be straight-chained or branched, and the number of carbon atoms thereof is not particularly limited, but is preferably 1 to 50. Specific examples thereof include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, 5-methylhexyl, and the like, but are not limited thereto.

In the present specification, a cycloalkyl group is not particularly limited, but has preferably 3 to 60 carbon atoms, and specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present specification, the alkoxy group may be straight-chained, branched, or cyclic. The number of carbon atoms of the alkoxy group is not particularly limited, but is preferably 1 to 20. Specific examples thereof include methoxy, ethoxy, n-propoxy, isopropoxy, i-propyloxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, benzyloxy, p-methylbenzyloxy, and the like, but are not limited thereto.

In the present specification, the alkenyl group may be straight-chained or branched, and the number of carbon atoms thereof is not particularly limited, but is preferably 2 to 40. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present specification, when the aryl group is a monocyclic aryl group, the number of carbon atoms thereof is not particularly limited, but is preferably 6 to 25. Specific examples of the monocyclic aryl group include a phenyl group, a biphenyl group, a terphenyl group, and the like, but are not limited thereto.

In the present specification, when the aryl group is a polycyclic aryl group, the number of carbon atoms thereof is not particularly limited, but is preferably 10 to 24. Specific examples of the polycyclic aryl group include a naphthyl group, an anthracenyl group, a phenanthryl group, a pyrenyl group, a perylenyl group, a chrysenyl group, a fluorenyl group, and the like, but are not limited thereto.

In the present specification, the fluorenyl group may be substituted, and adjacent substituents may be bonded to each other to form a ring.

When the fluorenyl group is substituted, the substituent may be

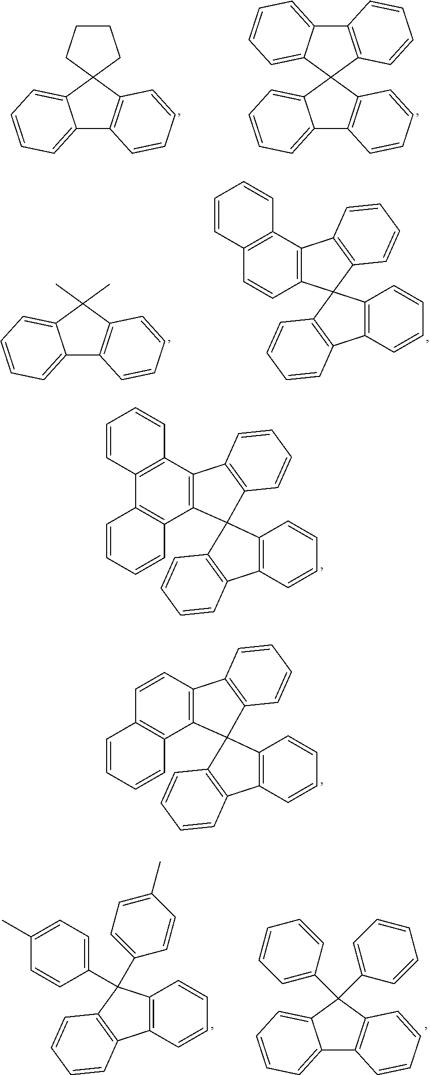

and the like. However, the substituent is not limited thereto.

In the present specification, a heterocyclic group includes one or more atoms other than carbon, that is, one or more heteroatoms, and specifically, the heteroatom may include one or more atoms selected from the group consisting of O, N, Se, S, and the like. The number of carbon atoms of the heterocyclic group is not particularly limited, but is preferably 2 to 60. Examples of the heterocyclic group include a thiophene group, a furan group, a pyrrole group, an imidazole group, a thiazole group, an oxazole group, an oxadiazole group, a triazole group, a pyridyl group, a bipyridyl group, a pyrimidyl group, a triazine group, a triazole group, an acridyl group, a pyridazine group, a pyrazinyl group, a qinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzimidazole group, a benzothiazole group, a benzocarbazole group, a benzothiophene group, a dibenzothiophene group, a benzofuranyl group, a phenanthridyl group, a phenanthroline group, a thiazolyl group, an isoxazolyl group, an oxadiazolyl group, a thiadiazolyl group, a benzothiazolyl group, a phenothiazinyl group, a dibenzofuranyl group, and the like, but are not limited thereto.

In the present specification, the number of carbon atoms of an amine group is not particularly limited, but is preferably 1 to 30. An N atom of the amine group may be substituted with an aryl group, an alkyl group, an arylalkyl group, a heterocyclic group, and the like, and specific examples of the amine group include a methylamine group, a dimethylamine group, an ethylamine group, a diethylamine group, a phenylamine group, a naphthylamine group, a biphenylamine group, an anthracenylamine group, a 9-methyl-anthracenylamine group, a diphenylamine group, a phenylnaphthylamine group, a ditolylamine group, a phenyltolylamine group, a triphenylamine group, and the like, but are not limited thereto.

In the present specification, the aryl group in the aryloxy group, the arylthioxy group, and the arylsulfoxy group is the same as the above-described examples of the aryl group. Specifically, examples of the aryloxy group include phenoxy, p-tolyloxy, m-tolyloxy, 3,5-dimethyl-phenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyl oxy, 1-anthryloxy, 2-anthryloxy, 9-anthryloxy, 1-phenanthryloxy, 3-phenanthryloxy, 9-phenanthryloxy, and the like, examples of the arylthioxy group include a phenylthioxy group, a 2-methylphenylthioxy group, a 4-tert-butylphenylthioxy group, and the like, and examples of the arylsulfoxy group include a benzenesulfoxy group, a p-toluenesulfoxy group, and the like, but the examples are not limited thereto.

In the present specification, the alkyl group in the alkylthioxy group and the alkylsulfoxy group is the same as the above-described examples of the alkyl group. Specifically, examples of the alkylthioxy group include a methylthioxy group, an ethylthioxy group, a tert-butylthioxy group, a hexylthioxy group, an octylthioxy group, and the like, and examples of the alkylsulfoxy group include a methylsulfoxy group, an ethylsulfoxy group, a propylsulfoxy group, a butylsulfoxy group, and the like, but the examples are not limited thereto. Further, in the present specification, the alkylthioxy group means a compound including S instead of O of the alkoxy group.

In the present specification, the hetero ring may be cycloheteroalkyl, cycloheteroalkenyl, cycloheteroketone, an aliphatic hetero ring, an aromatic hetero ring, or a fused ring thereof, and may be selected from the examples of the heterocyclic group, except for the hetero ring which is not a monovalent group.

According to an exemplary embodiment of the present specification, in Formula 1, X1 is S.

According to an exemplary embodiment of the present specification, in Formula 1, X2 is S.

According to an exemplary embodiment of the present specification, in Formula 1, Y1 is CR″.

According to an exemplary embodiment of the present specification, in Formula 1, Y2 is CR″.

According to an exemplary embodiment of the present specification, in Formula 1, R1 is hydrogen.

According to an exemplary embodiment of the present specification, in Formula 1, R2 is hydrogen.

According to an exemplary embodiment of the present specification, the first unit is represented by the following Formula 1-1.

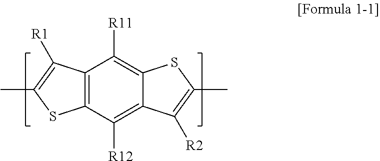

In Formula 1-1,

definitions of R1 and R2 are the same as those defined in Formula 1, and

R11 and R12 are the same as or different from each other, and are each independently a substituted or unsubstituted alkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted aryl group; or a substituted or unsubstituted heterocyclic group.

According to an exemplary embodiment of the present specification, in Formula 1-1, R11 is a substituted or unsubstituted straight-chained or branched alkoxy group; a substituted or unsubstituted aryl group; or a substituted or unsubstituted heterocyclic group.

According to an exemplary embodiment of the present specification, in Formula 1-1, R11 is a straight-chained or branched alkoxy group; an aryl group which is substituted with a straight-chained or branched alkoxy group; or a heterocyclic group which is substituted with one or more selected from a straight-chained or branched alkyl group, a straight-chained or branched alkylthioxy group, and a halogen group.

According to an exemplary embodiment of the present specification, in Formula 1-1, R11 is a straight-chained or branched alkoxy group; a phenyl group which is substituted with a straight-chained or branched alkoxy group; or a thiophene group which is substituted with one or more selected from a straight-chained or branched alkyl group, a straight-chained or branched alkylthioxy group, and a halogen group.

According to an exemplary embodiment of the present specification, in Formula 1-1, R12 is a substituted or unsubstituted straight-chained or branched alkoxy group; a substituted or unsubstituted aryl group; or a substituted or unsubstituted heterocyclic group.

According to an exemplary embodiment of the present specification, in Formula 1-1, R12 is a straight-chained or branched alkoxy group; an aryl group which is substituted with a straight-chained or branched alkoxy group; or a heterocyclic group which is substituted with one or more selected from a straight-chained or branched alkyl group, a straight-chained or branched alkylthioxy group, and a halogen group.

According to an exemplary embodiment of the present specification, in Formula 1-1, R12 is a straight-chained or branched alkoxy group; a phenyl group which is substituted with a straight-chained or branched alkoxy group; or a thiophene group which is substituted with one or more selected from a straight-chained or branched alkyl group, a straight-chained or branched alkylthioxy group, and a halogen group.

According to an exemplary embodiment of the present specification, the first unit is represented by any one of the following Formulae 1-2 to 1-6.

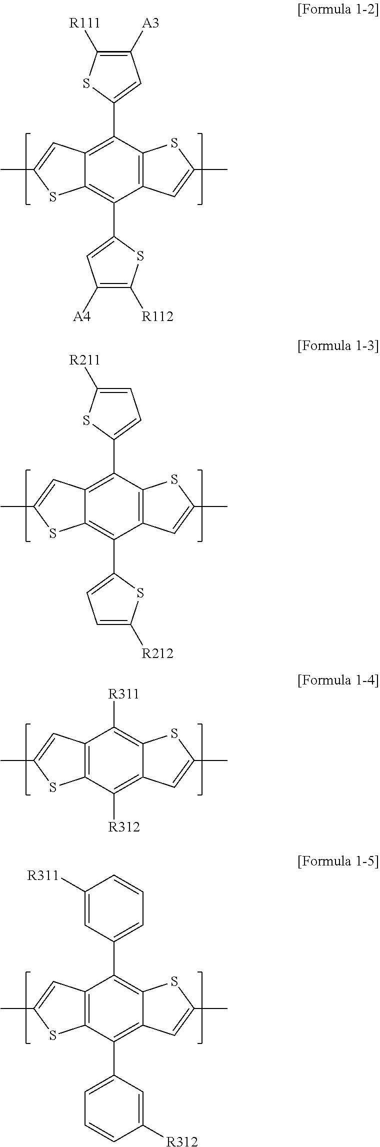

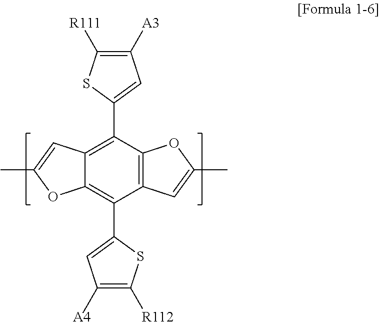

In Formulae 1-2 to 1-6,

A3 and A4 are the same as or different from each other, and are each independently a halogen group,

R111, R112, R211, and R212 are the same as or different from each other, and are each independently a substituted or unsubstituted alkyl group; or a substituted or unsubstituted alkylthioxy group, and

R311 and R312 are the same as or different from each other, and are each independently a substituted or unsubstituted alkyl group; or a substituted or unsubstituted alkoxy group.

According to an exemplary embodiment of the present specification, in Formulae 1-2 and 1-6, R111 is a substituted or unsubstituted straight-chained or branched alkyl group.

According to an exemplary embodiment of the present specification, in Formulae 1-2 and 1-6, R111 is a straight-chained or branched alkyl group.

According to an exemplary embodiment of the present specification, in Formulae 1-2 and 1-6, R111 is a branched alkyl group.

According to an exemplary embodiment of the present specification, in Formulae 1-2 and 1-6, R111 is a 2-ethylhexyl group.

According to an exemplary embodiment of the present specification, in Formulae 1-2 and 1-6, R112 is a substituted or unsubstituted straight-chained or branched alkyl group.

According to an exemplary embodiment of the present specification, in Formulae 1-2 and 1-6, R112 is a straight-chained or branched alkyl group.

According to an exemplary embodiment of the present specification, in Formulae 1-2 and 1-6, R112 is a branched alkyl group.

According to an exemplary embodiment of the present specification, in Formulae 1-2 and 1-6, R112 is a 2-ethylhexyl group.

According to an exemplary embodiment of the present specification, in Formula 1-3, R211 is a substituted or unsubstituted straight-chained or branched alkyl group; or a substituted or unsubstituted straight-chained or branched alkylthioxy group.

According to an exemplary embodiment of the present specification, in Formula 1-3, R211 is a straight-chained or branched alkyl group; or a straight-chained or branched alkylthioxy group.

According to an exemplary embodiment of the present specification, in Formula 1-3, R211 is a branched alkyl group; or a branched alkylthioxy group.

According to an exemplary embodiment of the present specification, in Formula 1-3, R211 is a 2-ethylhexyl group; or a 2-ethylhexylthioxy group.

According to an exemplary embodiment of the present specification, in Formula 1-3, R212 is a substituted or unsubstituted straight-chained or branched alkyl group; or a substituted or unsubstituted straight-chained or branched alkylthioxy group.

According to an exemplary embodiment of the present specification, in Formula 1-3, R212 is a straight-chained or branched alkyl group; or a straight-chained or branched alkylthioxy group.

According to an exemplary embodiment of the present specification, in Formula 1-3, R212 is a branched alkyl group; or a branched alkylthioxy group.

According to an exemplary embodiment of the present specification, in Formula 1-3, R212 is a 2-ethylhexyl group; or a 2-ethylhexylthioxy group.

According to an exemplary embodiment of the present specification, in Formulae 1-4 and 1-5, R311 is a substituted or unsubstituted straight-chained or branched alkoxy group.

According to an exemplary embodiment of the present specification, in Formulae 1-4 and 1-5, R311 is a straight-chained or branched alkoxy group.

According to an exemplary embodiment of the present specification, in Formulae 1-4 and 1-5, R311 is a branched alkoxy group.

According to an exemplary embodiment of the present specification, in Formulae 1-4 and 1-5, R311 is a 2-ethylhexyloxy group.

According to an exemplary embodiment of the present specification, in Formulae 1-4 and 1-5, R312 is a substituted or unsubstituted straight-chained or branched alkoxy group.

According to an exemplary embodiment of the present specification, in Formulae 1-4 and 1-5, R312 is a straight-chained or branched alkoxy group.

According to an exemplary embodiment of the present specification, in Formulae 1-4 and 1-5, R312 is a branched alkoxy group.

According to an exemplary embodiment of the present specification, in Formulae 1-4 and 1-5, R312 is a 2-ethylhexyloxy group.

According to an exemplary embodiment of the present specification, in Formula 2, X3 is S.

According to an exemplary embodiment of the present specification, in Formula 2, X4 is S.

According to an exemplary embodiment of the present specification, the second unit is represented by the following Formula 2-1.

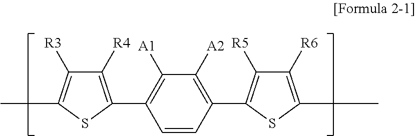

In Formula 2-1,

definitions of R3 to R6, A1, and A2 are the same as those defined in Formula 2.

According to an exemplary embodiment of the present specification, in Formula 2, R3 to R6 are hydrogen.

According to an exemplary embodiment of the present specification, in Formula 2, A1 and A2 are fluorine.

According to an exemplary embodiment of the present specification, the second unit is represented by the following Formula 2-2.

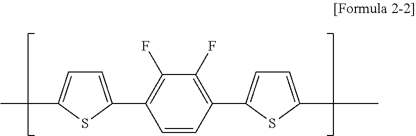

According to an exemplary embodiment of the present specification, in Formula 3, Cy includes one or more of N, O, S, Si, Ge, Te, P, and Se as a heteroatom, and is a substituted or unsubstituted hetero ring.

According to an exemplary embodiment of the present specification, in Formula 3, Cy includes one or more of N, O, S, Si, Ge, Te, P, and Se as a heteroatom, and is a substituted or unsubstituted monocyclic 5-membered or 6-membered hetero ring.

According to an exemplary embodiment of the present specification, the third unit is represented by the following Formula 3-1 or 3-2.

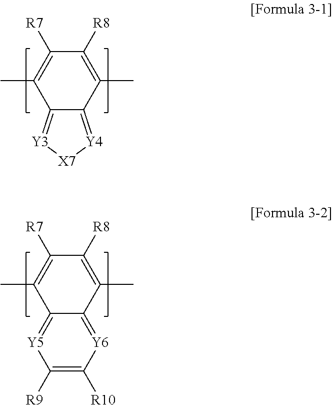

In Formulae 3-1 and 3-2,

definitions of R7 and R8 are the same as those defined in Formula 3,

X7 is CRR′, NR, O, SiRR′, PR, S, GeRR′, Se, or Te,

Y3 to Y6 are the same as or different from each other, and are each independently CR″, N, SiR″, P, or GeR″, and

R, R′, R″, R9, and R10 are the same as or different from each other, and are each independently hydrogen; a substituted or unsubstituted alkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted aryl group; or a substituted or unsubstituted heterocyclic group.

According to an exemplary embodiment of the present specification, in Formula 4, X5 is S.

According to an exemplary embodiment of the present specification, in Formula 4, X6 is NR.

According to an exemplary embodiment of the present specification, in Formula 4, Q1 and Q2 are O.

According to an exemplary embodiment of the present specification, the third unit is represented by any one of the following Formulae 3-3 to 3-7.

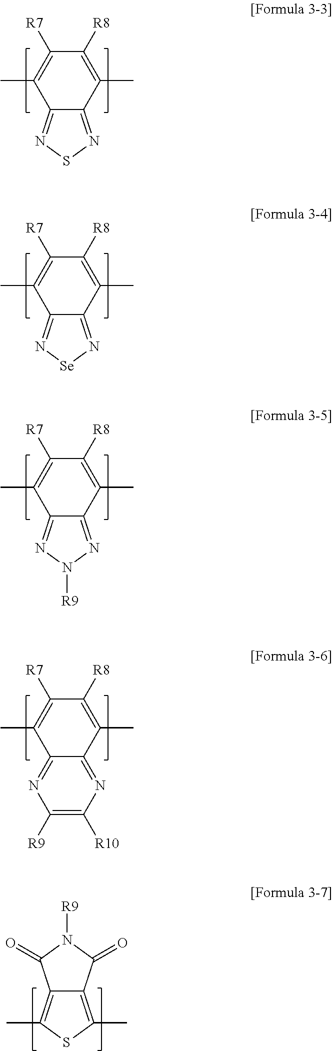

In Formulae 3-3 to 3-7,

definitions of R7 and R8 are the same as those defined in Formula 3, and

R9 and R10 are the same as or different from each other, and are each independently hydrogen; a substituted or unsubstituted alkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted aryl group; or a substituted or unsubstituted heterocyclic group.

According to an exemplary embodiment of the present specification, in Formula 3, R7 is hydrogen; or a substituted or unsubstituted alkoxy group.

According to an exemplary embodiment of the present specification, in Formula 3, R7 is hydrogen; or a substituted or unsubstituted straight-chained or branched alkoxy group.

According to an exemplary embodiment of the present specification, in Formula 3, R7 is hydrogen; or a straight-chained or branched alkoxy group.

According to an exemplary embodiment of the present specification, in Formula 3, R7 is hydrogen; or a straight-chained alkoxy group.

According to an exemplary embodiment of the present specification, in Formula 3, R7 is hydrogen; or a C₁ to C₂₀ straight-chained alkoxy group.

According to an exemplary embodiment of the present specification, in Formula 3, R7 is hydrogen; or a C₁₀ to C₂₀ straight-chained alkoxy group.

According to an exemplary embodiment of the present specification, in Formula 3, R7 is hydrogen; or an n-dodecyloxy group.

According to an exemplary embodiment of the present specification, in Formula 3, R7 is a branched alkoxy group.

According to an exemplary embodiment of the present specification, in Formula 3, R7 is a C₃ to C₂₀ branched alkoxy group.

According to an exemplary embodiment of the present specification, in Formula 3, R7 is a C₁₀ to C₂₀ branched alkoxy group.

According to an exemplary embodiment of the present specification, in Formula 3, R7 is a 2-butyloctyloxy group.

According to an exemplary embodiment of the present specification, in Formula 3, R8 is hydrogen; or a substituted or unsubstituted alkoxy group.

According to an exemplary embodiment of the present specification, in Formula 3, R8 is hydrogen; or a substituted or unsubstituted straight-chained or branched alkoxy group.

According to an exemplary embodiment of the present specification, in Formula 3, R8 is hydrogen; or a straight-chained or branched alkoxy group.

According to an exemplary embodiment of the present specification, in Formula 3, R8 is hydrogen; or a straight-chained alkoxy group.

According to an exemplary embodiment of the present specification, in Formula 3, R8 is hydrogen; or a C₁ to C₂₀ straight-chained alkoxy group.

According to an exemplary embodiment of the present specification, in Formula 3, R8 is hydrogen; or a C₁₀ to C₂₀ straight-chained alkoxy group.

According to an exemplary embodiment of the present specification, in Formula 3, R8 is hydrogen; or an n-dodecyloxy group.

According to an exemplary embodiment of the present specification, in Formula 3, R8 is a branched alkoxy group.

According to an exemplary embodiment of the present specification, in Formula 3, R8 is a C₃ to C₂₀ branched alkoxy group.

According to an exemplary embodiment of the present specification, in Formula 3, R8 is a C₁₀ to C₂₀ branched alkoxy group.

According to an exemplary embodiment of the present specification, in Formula 3, R8 is a 2-butyloctyloxy group.

According to an exemplary embodiment of the present specification, in Formulae 3-3 and 3-4, R7 is a substituted or unsubstituted alkoxy group.

According to an exemplary embodiment of the present specification, in Formulae 3-3 and 3-4, R7 is a substituted or unsubstituted straight-chained or branched alkoxy group.

According to an exemplary embodiment of the present specification, in Formulae 3-3 and 3-4, R7 is a straight-chained or branched alkoxy group.

According to an exemplary embodiment of the present specification, in Formulae 3-3 and 3-4, R7 is a straight-chained alkoxy group.

According to an exemplary embodiment of the present specification, in Formulae 3-3 and 3-4, R7 is hydrogen; or a C₁ to C₂₀ straight-chained alkoxy group.

According to an exemplary embodiment of the present specification, in Formulae 3-3 and 3-4, R7 is hydrogen; or a C₁₀ to C₂₀ straight-chained alkoxy group.

According to an exemplary embodiment of the present specification, in Formulae 3-3 and 3-4, R7 is an n-dodecyloxy group.

According to an exemplary embodiment of the present specification, in Formulae 3-3 and 3-4, R7 is a branched alkoxy group.

According to an exemplary embodiment of the present specification, in Formulae 3-3 and 3-4, R7 is a C₃ to C₂₀ branched alkoxy group.

According to an exemplary embodiment of the present specification, in Formulae 3-3 and 3-4, R7 is a C₁₀ to C₂₀ branched alkoxy group.

According to an exemplary embodiment of the present specification, in Formulae 3-3 and 3-4, R7 is a 2-butyloctyloxy group.

According to an exemplary embodiment of the present specification, in Formulae 3-3 and 3-4, R8 is a substituted or unsubstituted alkoxy group.

According to an exemplary embodiment of the present specification, in Formulae 3-3 and 3-4, R8 is a substituted or unsubstituted straight-chained or branched alkoxy group.

According to an exemplary embodiment of the present specification, in Formulae 3-3 and 3-4, R8 is a straight-chained or branched alkoxy group.

According to an exemplary embodiment of the present specification, in Formulae 3-3 and 3-4, R8 is a straight-chained alkoxy group.

According to an exemplary embodiment of the present specification, in Formulae 3-3 and 3-4, R8 is hydrogen; or a C₁ to C₂₀ straight-chained alkoxy group.

According to an exemplary embodiment of the present specification, in Formulae 3-3 and 3-4, R8 is hydrogen; or a C₁₀ to C₂₀ straight-chained alkoxy group.

According to an exemplary embodiment of the present specification, in Formulae 3-3 and 3-4, R8 is an n-dodecyloxy group.

According to an exemplary embodiment of the present specification, in Formulae 3-3 and 3-4, R8 is a branched alkoxy group.

According to an exemplary embodiment of the present specification, in Formulae 3-3 and 3-4, R8 is a C₃ to C₂₀ branched alkoxy group.

According to an exemplary embodiment of the present specification, in Formulae 3-3 and 3-4, R8 is a C₁₀ to C₂₀ branched alkoxy group.

According to an exemplary embodiment of the present specification, in Formulae 3-3 and 3-4, R8 is a 2-butyloctyloxy group.

According to an exemplary embodiment of the present specification, in Formulae 3-5 and 3-6, R7 and R8 are hydrogen.

According to an exemplary embodiment of the present specification, in Formula 3-5, R9 is a substituted or unsubstituted alkyl group.

According to an exemplary embodiment of the present specification, in Formula 3-5, R9 is a substituted or unsubstituted straight-chained or branched alkyl group.

According to an exemplary embodiment of the present specification, in Formula 3-5, R9 is a branched alkyl group.

According to an exemplary embodiment of the present specification, in Formula 3-5, R9 is a C₆ to Cᵢₛ branched alkyl group.

According to an exemplary embodiment of the present specification, in Formula 3-5, R9 is a C₈ to C₁₂ branched alkyl group.

According to an exemplary embodiment of the present specification, in Formula 3-5, R9 is a 2-ethylhexyl group or a 2-butyloctyl group.

According to an exemplary embodiment of the present specification, in Formula 3-6, R9 and R10 are the same as or different from each other, and are each independently a substituted or unsubstituted aryl group.

According to an exemplary embodiment of the present specification, in Formula 3-6, R9 and R10 are the same as or different from each other, and are each independently an aryl group which is substituted with a straight-chained or branched alkoxy group.

According to an exemplary embodiment of the present specification, in Formula 3-6, R9 and R10 are the same as or different from each other, and are each independently a phenyl group which is substituted with a straight-chained or branched alkoxy group.

According to an exemplary embodiment of the present specification, in Formula 3-6, R9 and R10 are the same as or different from each other, and are each independently a phenyl group which is substituted with a straight-chained alkoxy group.

According to an exemplary embodiment of the present specification, in Formula 3-6, R9 to R10 are a phenyl group which is substituted with an n-octyloxy group.

According to an exemplary embodiment of the present specification, in Formula 3-7, R9 is a substituted or unsubstituted alkyl group.

According to an exemplary embodiment of the present specification, in Formula 3-7, R9 is a substituted or unsubstituted straight-chained or branched alkyl group.

According to an exemplary embodiment of the present specification, in Formula 3-7, R9 is a branched alkyl group.

According to an exemplary embodiment of the present specification, in Formula 3-7, R9 is a 2-ethylhexyl group.

According to an exemplary embodiment of the present specification, the polymer includes a unit represented by the following Formula 5.

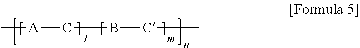

In Formula 5,

l is a mole fraction, and a real number of 0<l<1,

m is a mole fraction, and a real number of 0<m<1,

l+m=1,

A is the first unit represented by Formula 1,

B is the second unit represented by Formula 2,

C and C′ are the same as or different from each other, and are each independently the third unit represented by Formula 3 or Formula 4, and

n is a repeating number of the unit, and an integer from 1 to 10,000.

A1 and A2 in the second unit represented by Formula 2-1 of the present specification interact with an S atom of thiophene or A1 and A2 in the second unit represented by Formula 2-1 interact with an S atom of the first unit represented by Formula 1-1.

Here, the interaction means that chemical structures or atoms constituting the chemical structures form a non-covalent bonding interaction, which affects each other by an action other than a covalent bond, and may mean, for example, a chalcogen bond.

In addition, in an exemplary embodiment of the present specification, the third unit represented by any one of Formulae 3-3 to 3-7 may include R7 and R8 to form a planar structure through the interactions of O atoms of R7 and R8; A1 and A2 of the second unit represented by Formula 2; and an S atom of the first unit represented by Formula 1.

Accordingly, when the polymer according to an exemplary embodiment of the present specification is included, a device with high efficiency may be provided because an increase in current may be induced.

According to an exemplary embodiment of the present specification, A is the first unit represented by Formula 1-1.

According to an exemplary embodiment of the present specification, B is the second unit represented by Formula 2-1.

According to an exemplary embodiment of the present specification, C is the third unit represented by any one selected from Formulae 3-3 to 3-7.

According to an exemplary embodiment of the present specification, C′ is the third unit represented by any one selected from Formulae 3-3 to 3-7.

According to an exemplary embodiment of the present specification, the polymer includes a unit represented by the following Formula 5-1 or 5-2.

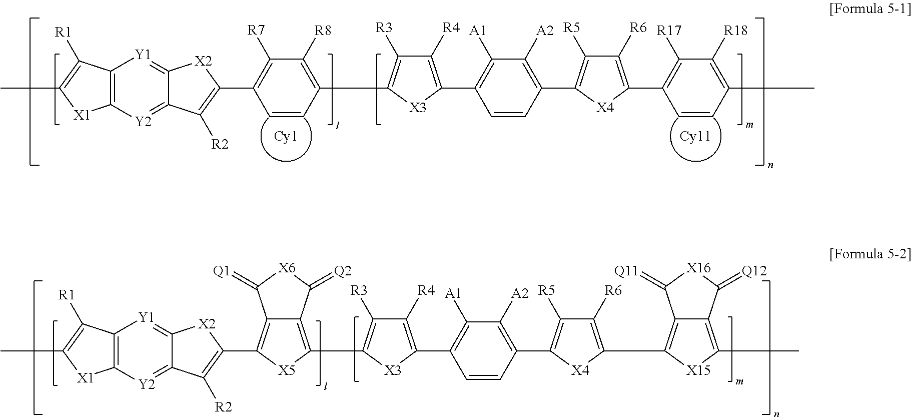

In Formulae 5-1 and 5-2,

definitions of X1 to X6, Y1, Y2, R1 to R8, Cy1, Q1, Q2, A1, and A2 are the same as those defined in Formulae 1 to 4,

Cy11 is a substituted or unsubstituted hetero ring,

Q11 and Q12 are the same as or different from each other, and are each independently O or S,

X15 and X16 are the same as or different from each other, and are each independently CRR′, NR, O, SiRR′, PR, S, GeRR′, Se, or Te,

R, R′, R17, and R18 are the same as or different from each other, and are each independently hydrogen; deuterium; a halogen group; a nitrile group; a nitro group; an imide group; an amide group; a hydroxyl group; a substituted or unsubstituted alkyl group; a substituted or unsubstituted cycloalkyl group; a substituted or unsubstituted alkoxy group; a substituted or unsubstituted aryloxy group; a substituted or unsubstituted alkylthioxy group; a substituted or unsubstituted arylthioxy group; a substituted or unsubstituted alkylsulfoxy group; a substituted or unsubstituted arylsulfoxy group; a substituted or unsubstituted alkenyl group; a substituted or unsubstituted amine group; a substituted or unsubstituted aryl group; or a substituted or unsubstituted heterocyclic group,

l is a mole fraction, and a real number of 0<l<1,

m is a mole fraction, and a real number of 0<m<1,

l+m=1, and

n is a repeating number of the unit, and an integer from 1 to 10,000.

According to an exemplary embodiment of the present specification, the polymer includes a unit represented by the following Formula 5-3.

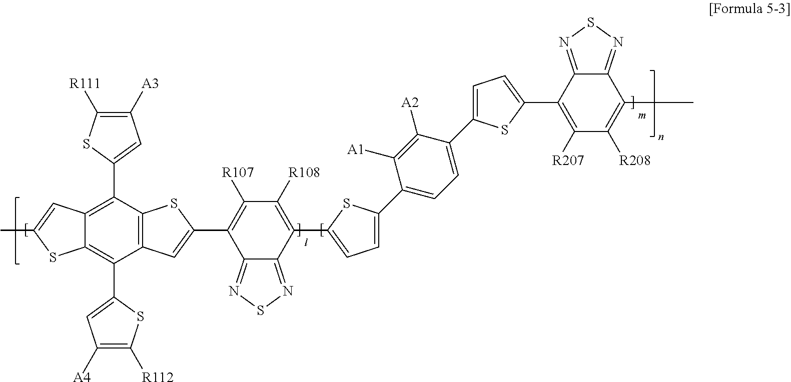

In Formula 5-3,

A1 to A4 are the same as or different from each other, and are each independently a halogen group,

R107, R108, R207, and R208 are the same as or different from each other, and are each independently a substituted or unsubstituted alkoxy group,

R111 and R112 are the same as or different from each other, and are each independently a substituted or unsubstituted alkyl group; or a substituted or unsubstituted alkylthioxy group,

l is a mole fraction, and a real number of 0<l<1,

m is a mole fraction, and a real number of 0<m<1,

l+m=1, and

n is a repeating number of the unit, and an integer from 1 to 10,000.

According to an exemplary embodiment of the present specification, the polymer includes a unit represented by any one of the following Formulae 5-4 to 5-39.

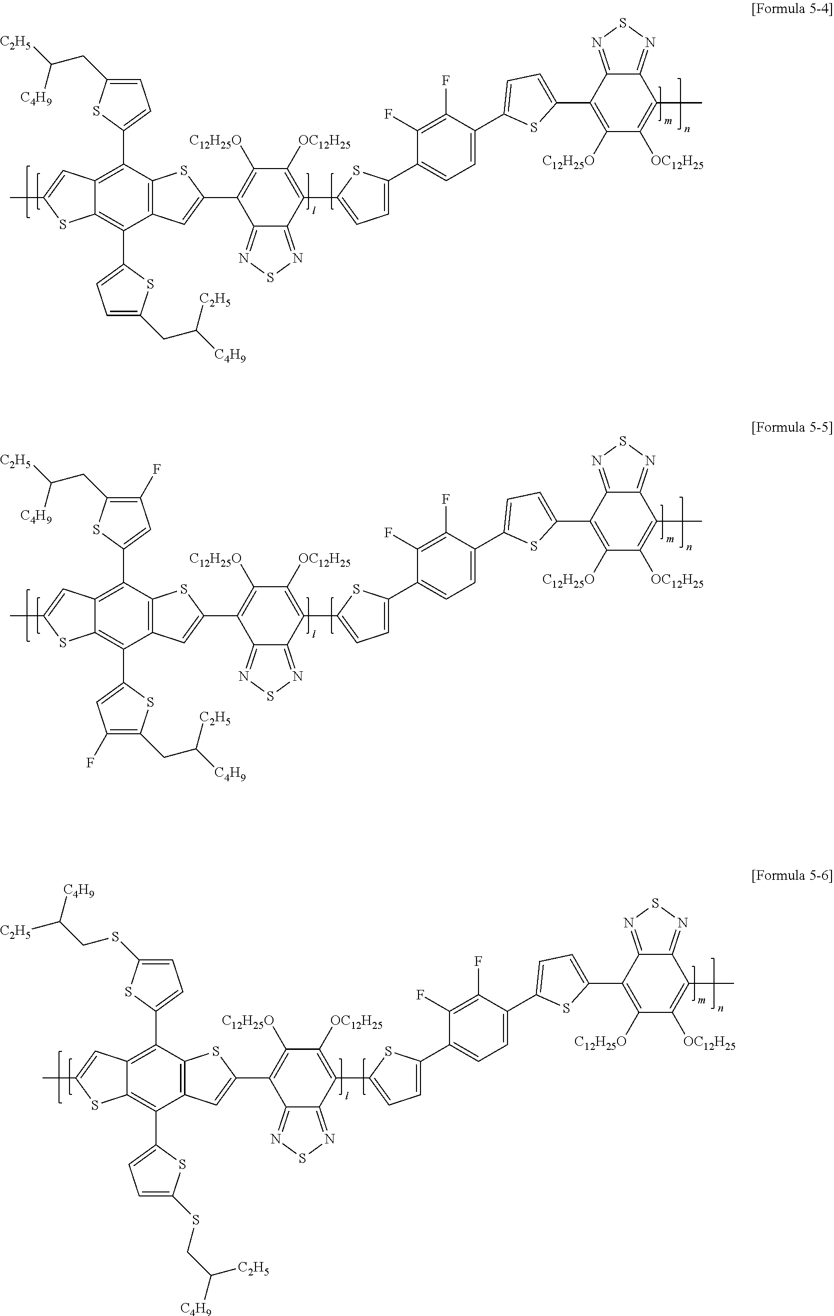

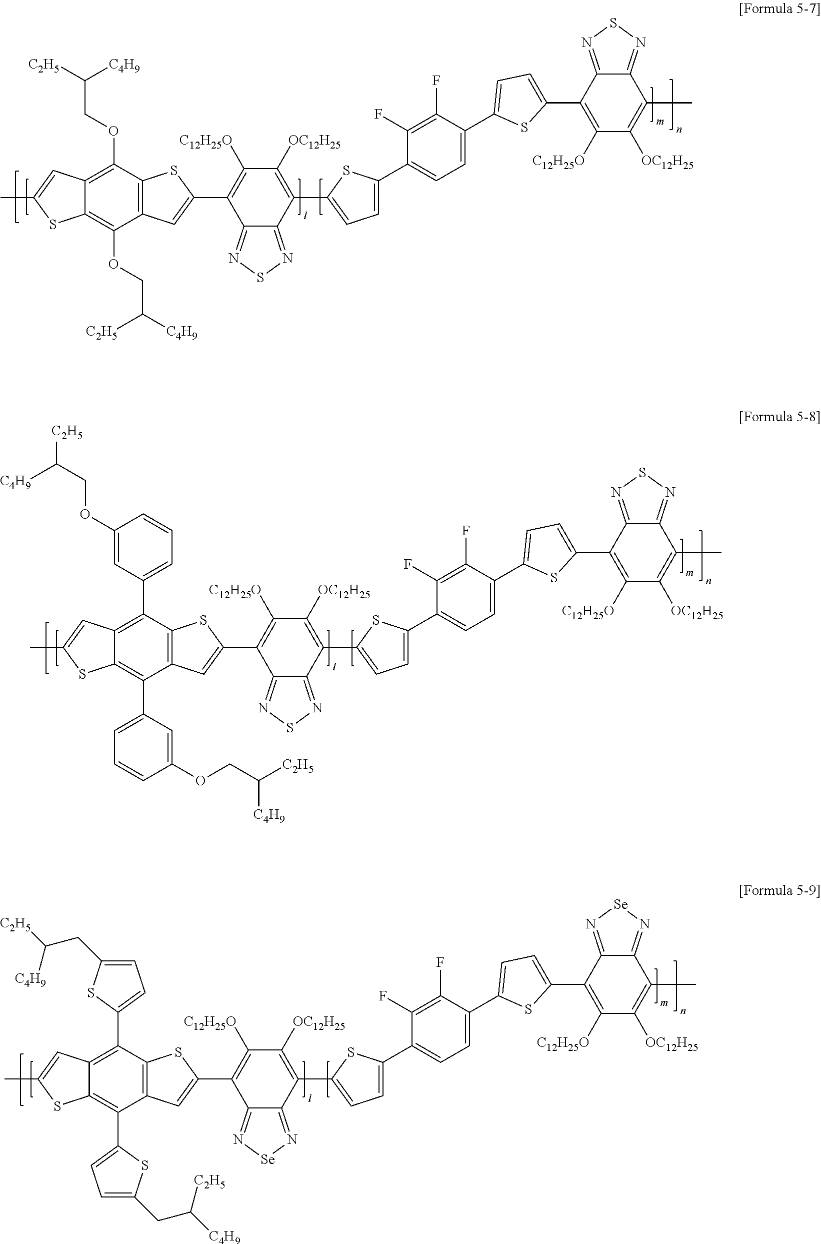

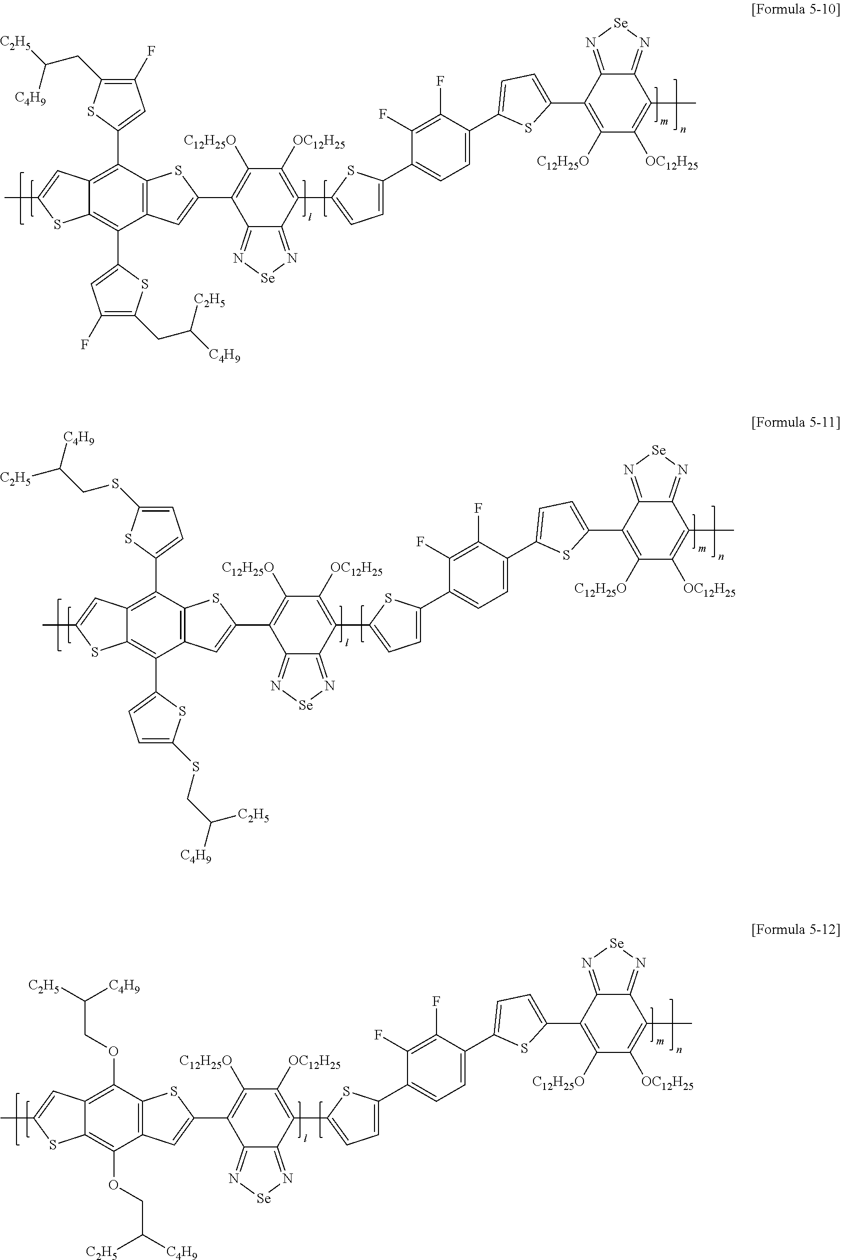

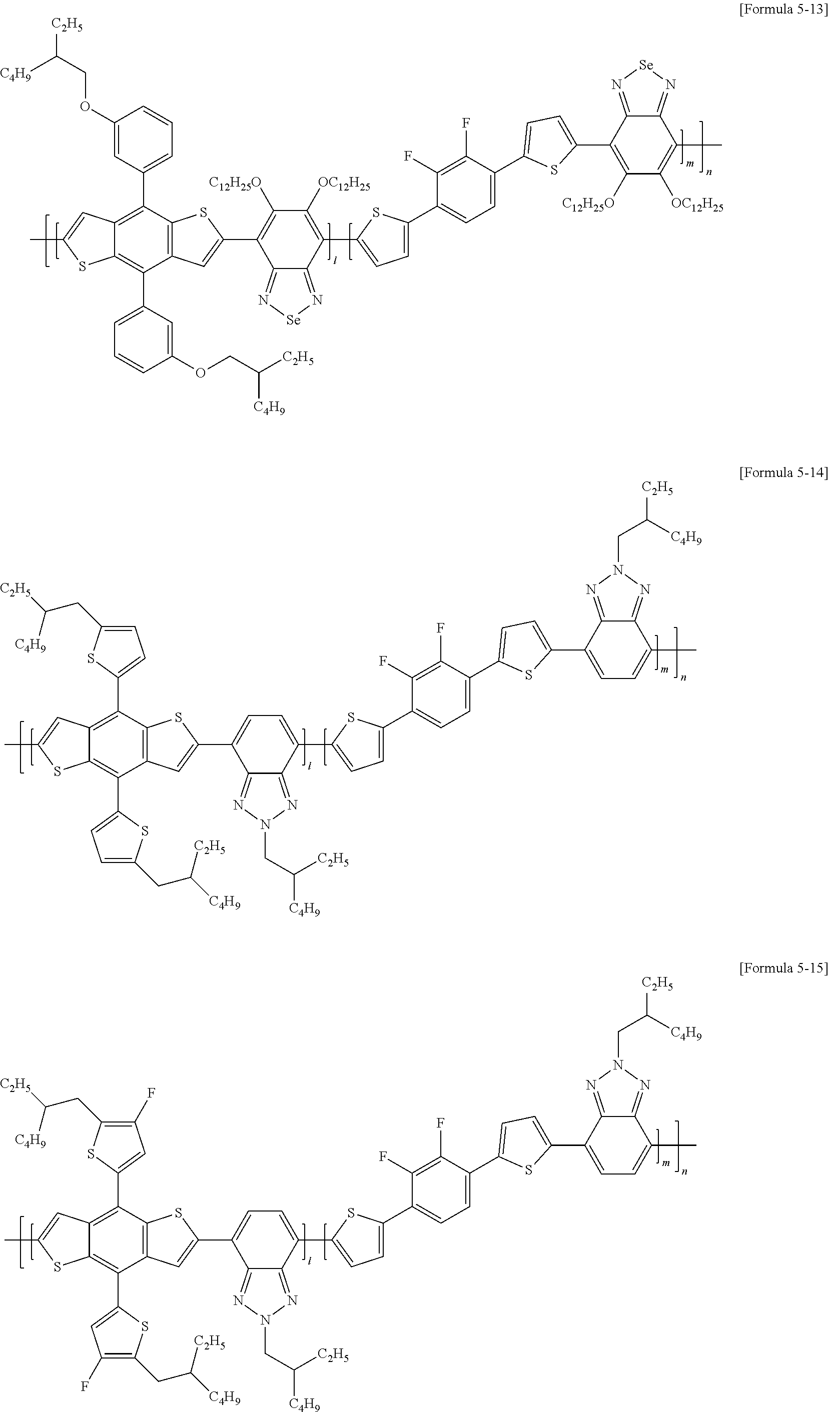

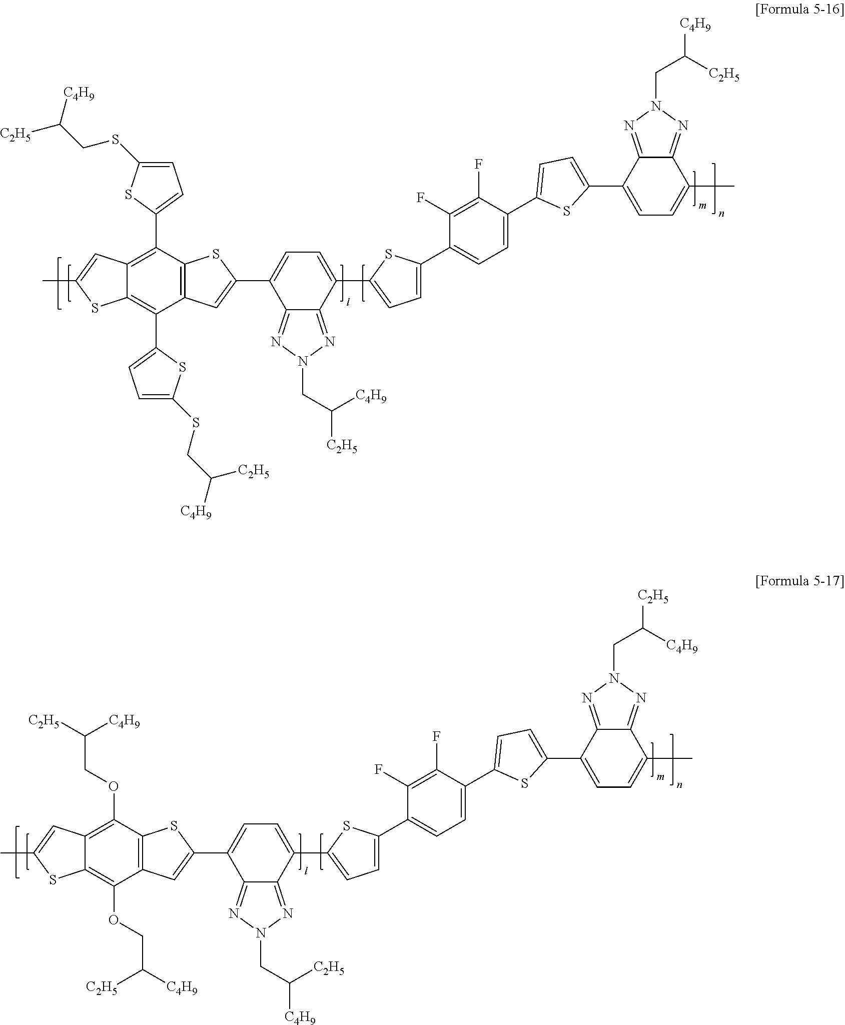

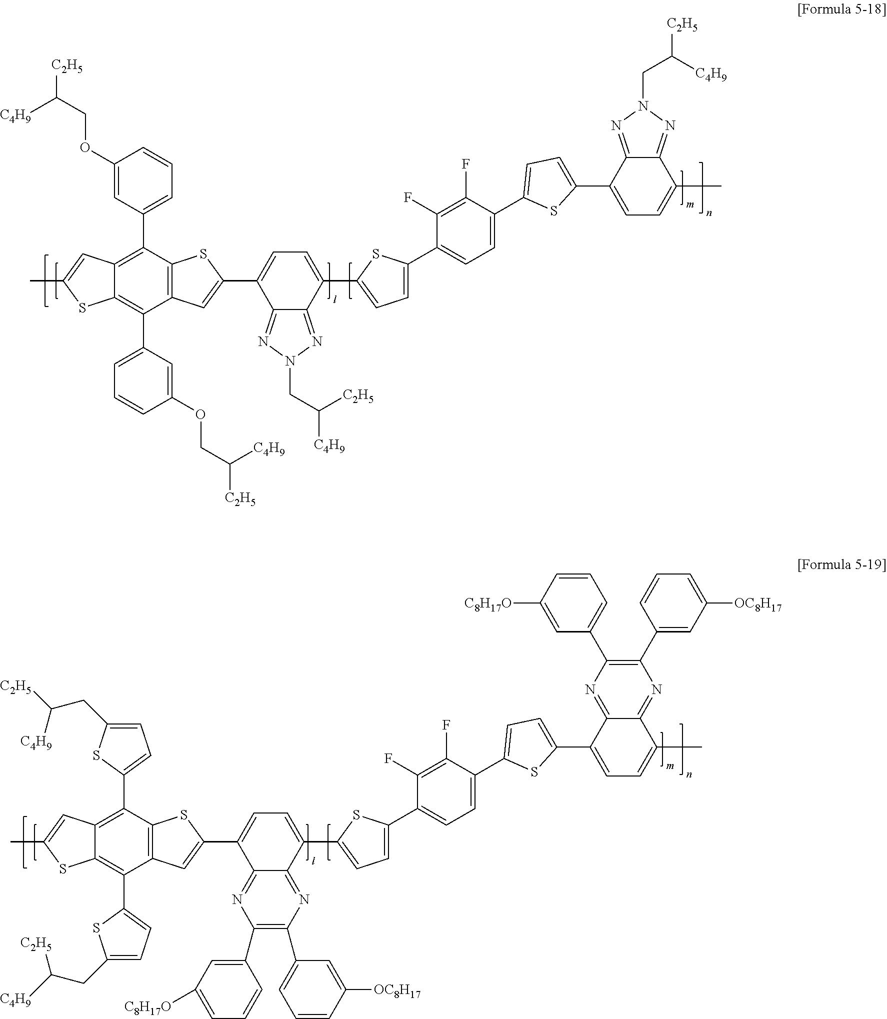

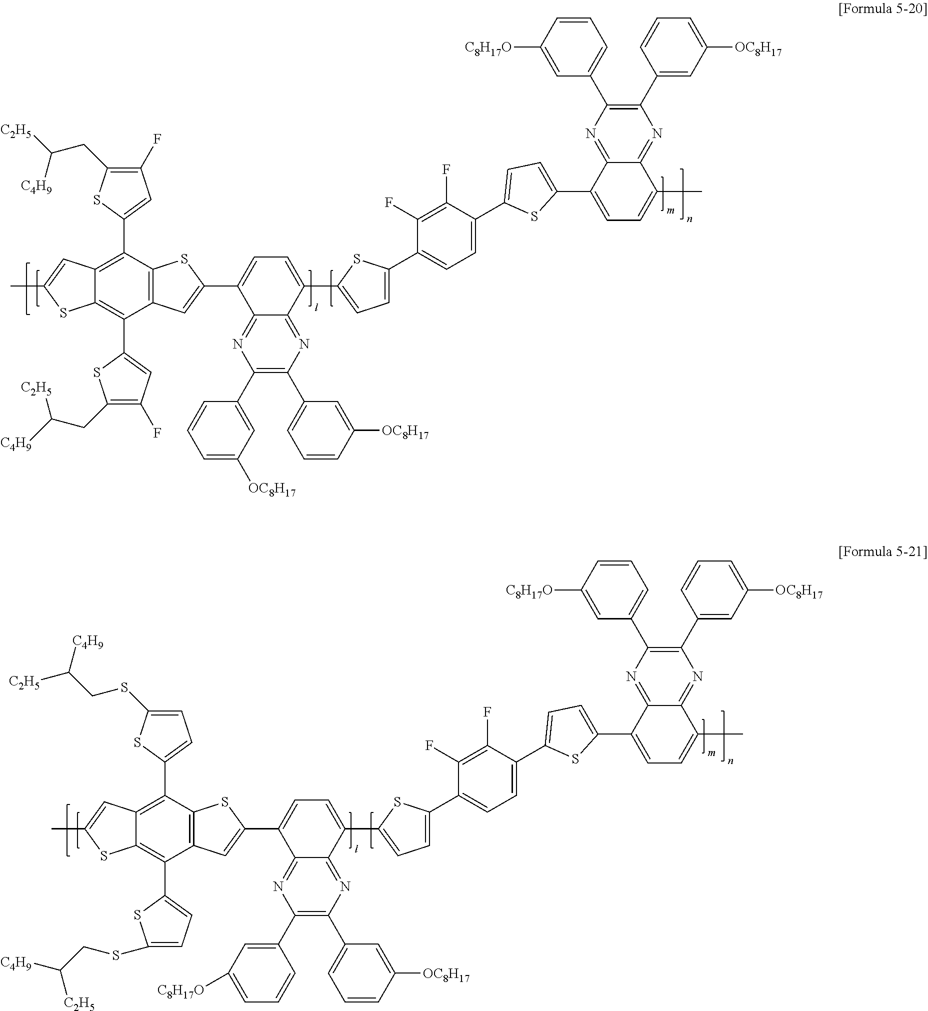

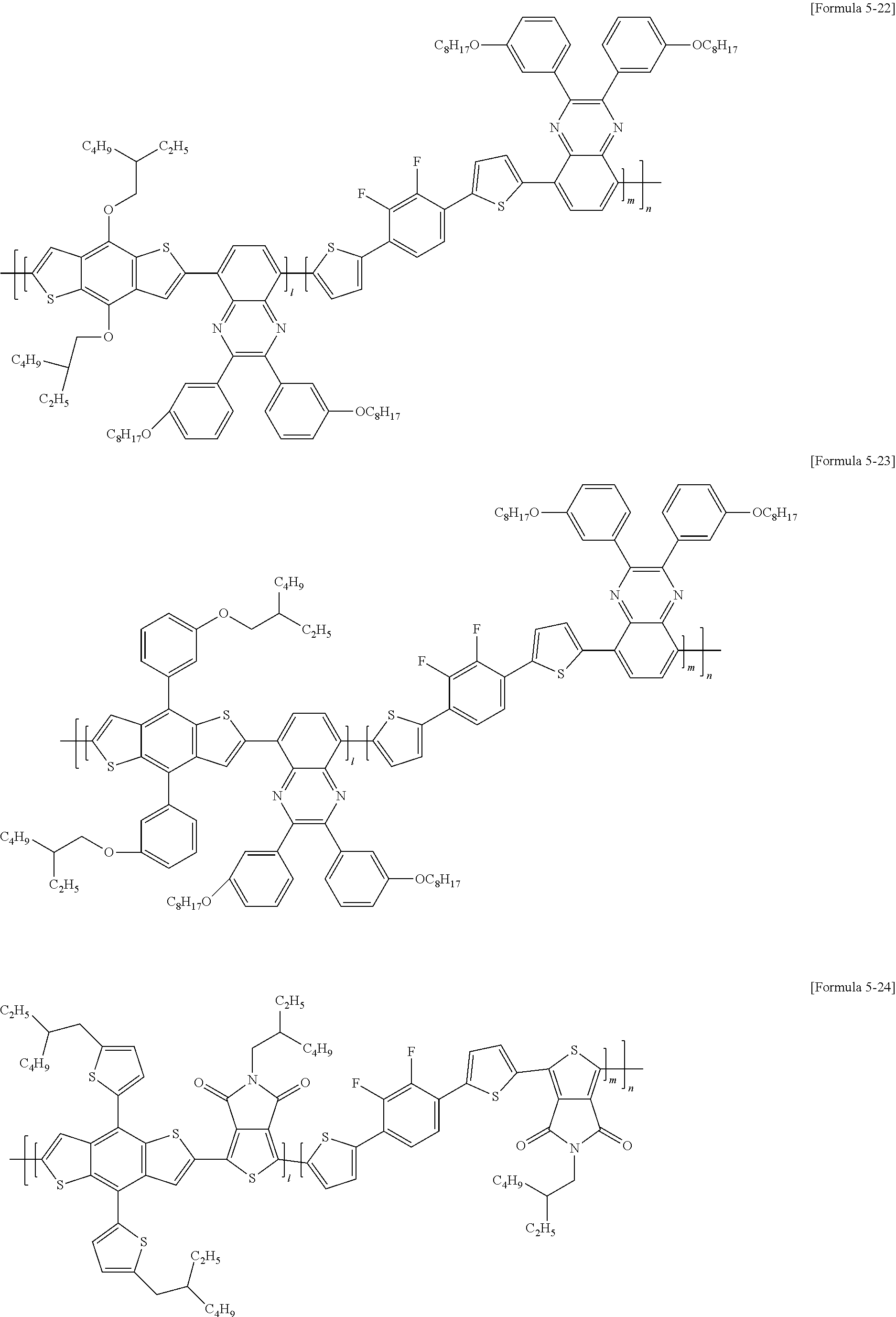

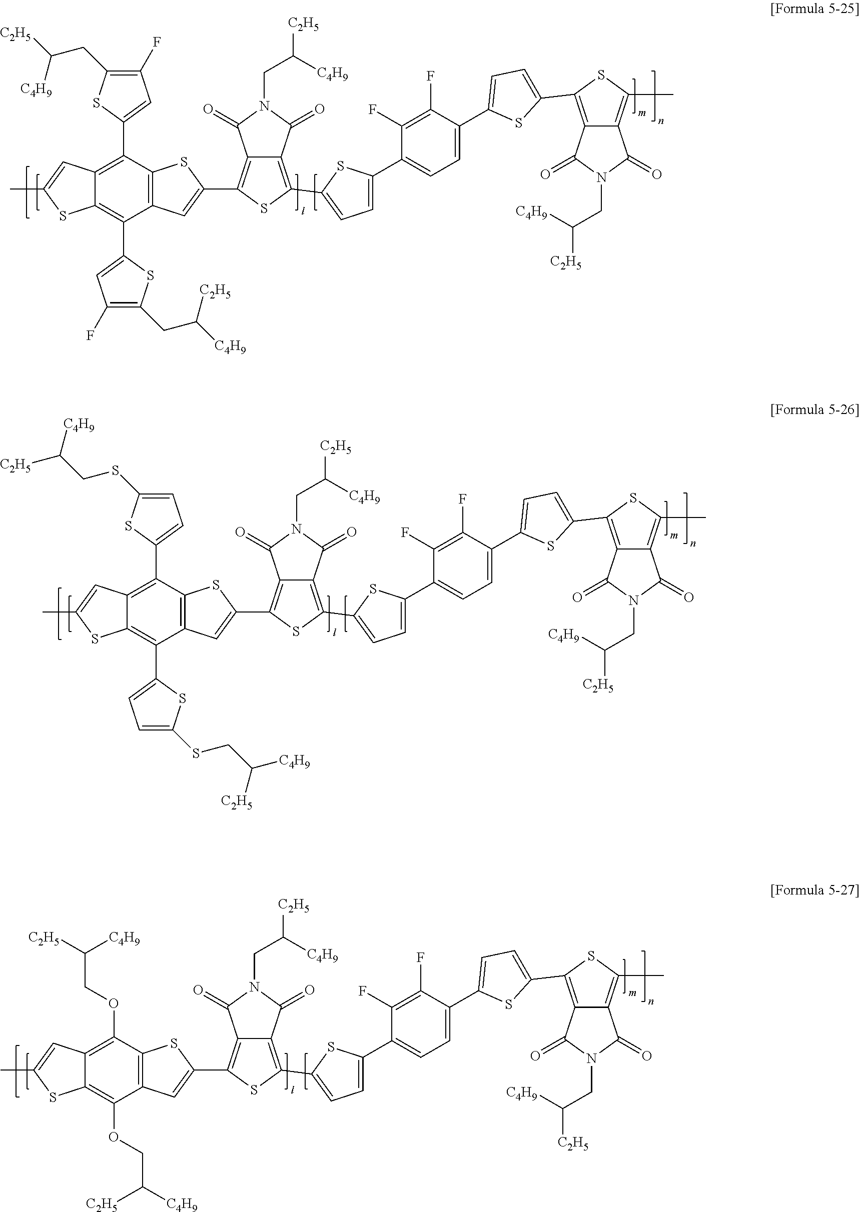

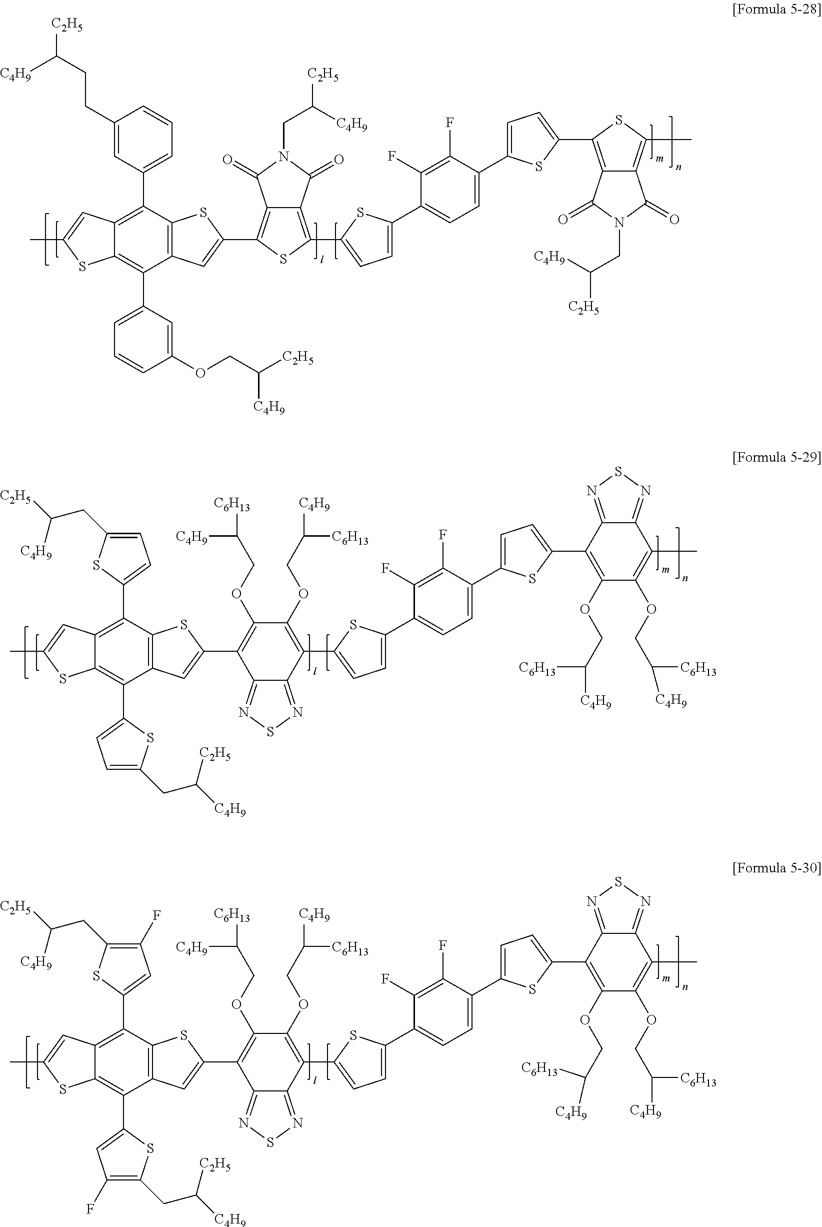

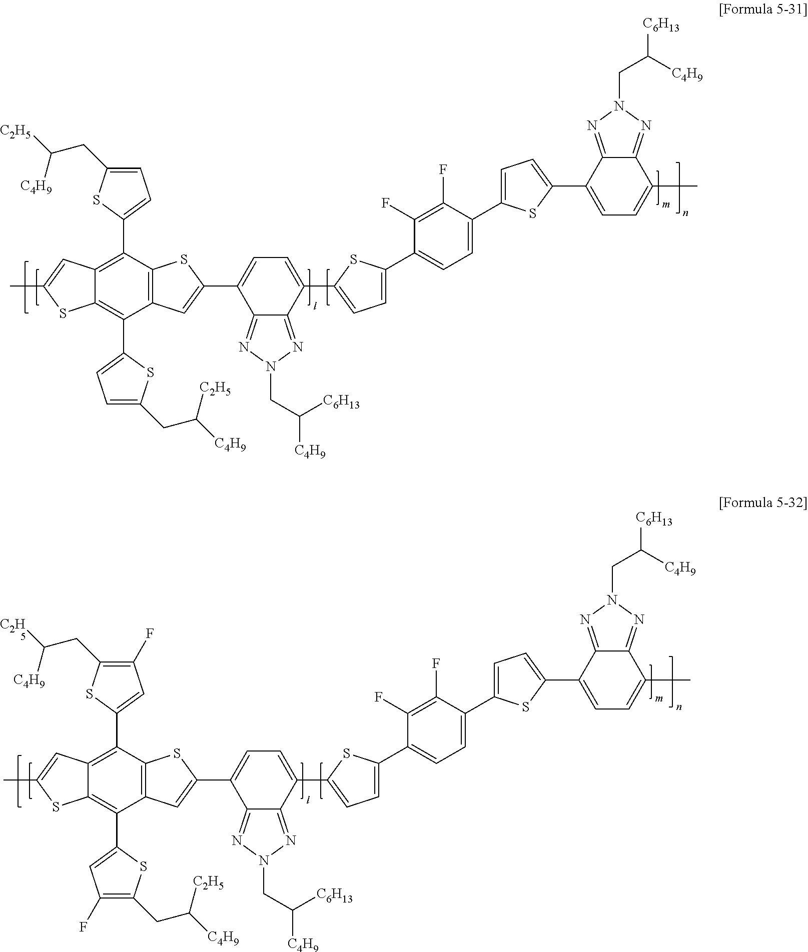

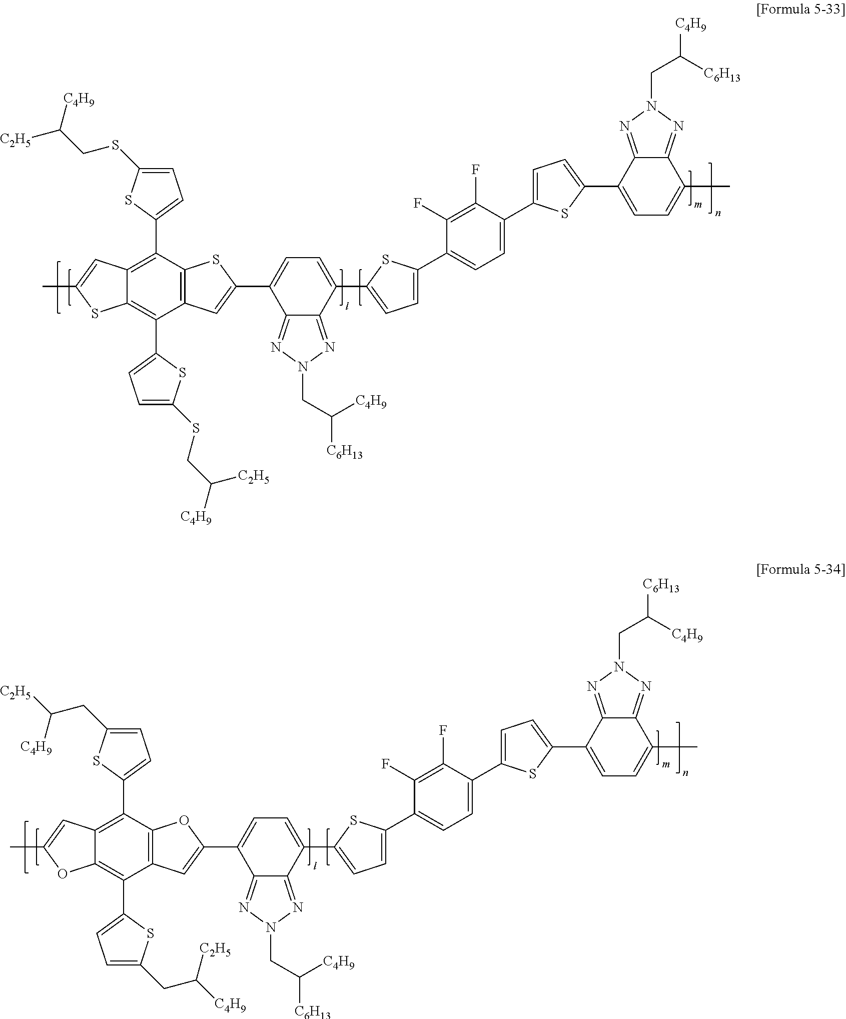

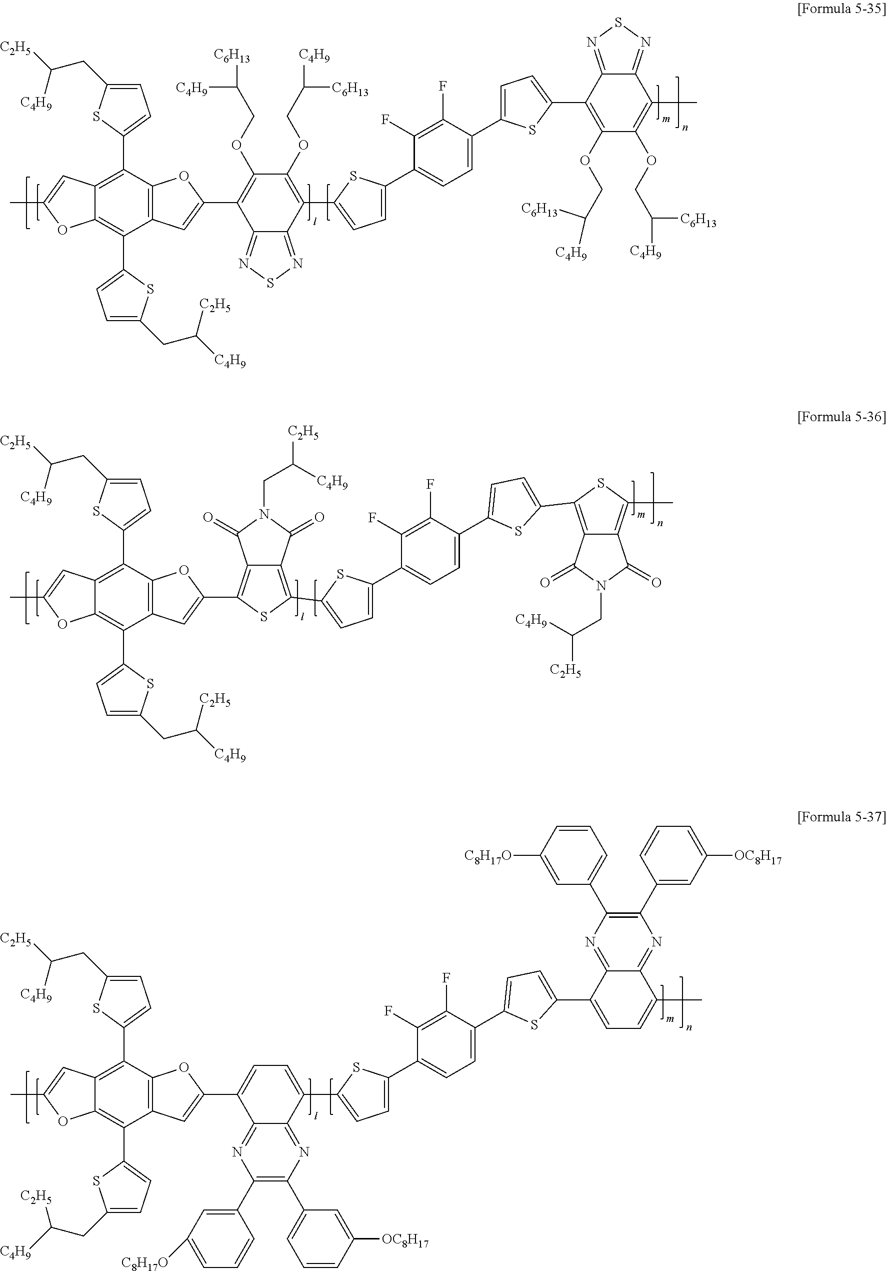

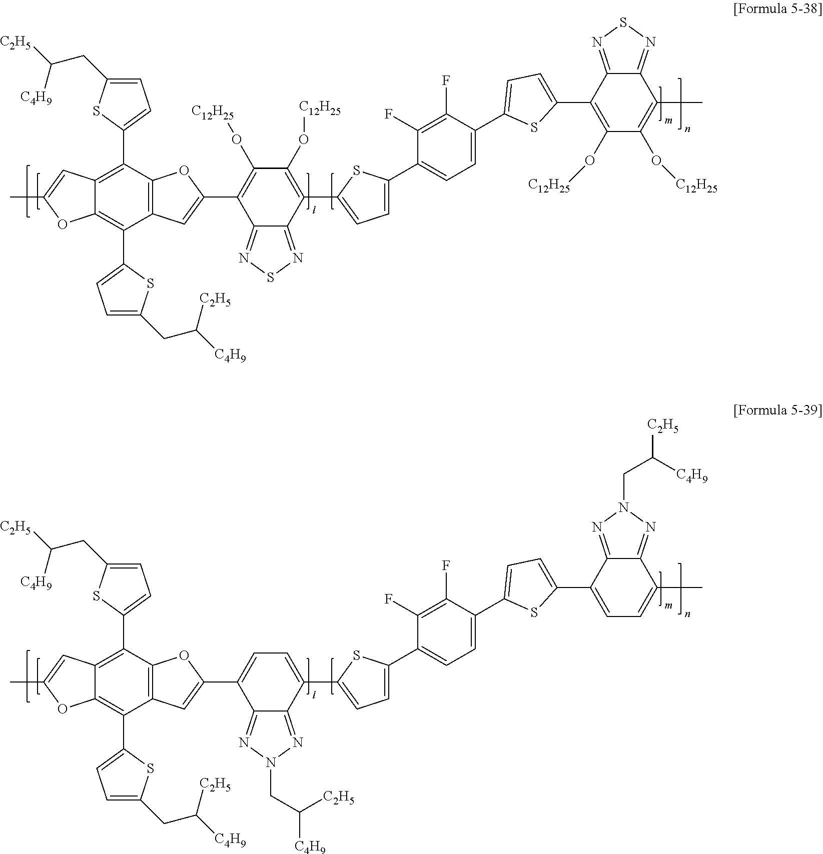

In Formulae 5-4 to 5-39,

l is a mole fraction, and a real number of 0<l<1,

m is a mole fraction, and a real number of 0<m<1,

l+m=1, and

n is a repeating number of the unit, and an integer from 1 to 10,000.

In an exemplary embodiment of the present specification, l is 0.5.

In another exemplary embodiment, m is 0.5.

In another exemplary embodiment of the present specification, l is 0.75.

In an exemplary embodiment of the present specification, m is 0.25.

In an exemplary embodiment of the present specification, the polymer is a random polymer. Further, the random polymer is economically efficient in terms of time and costs in the process of manufacturing a device due to the improved solubility.

In an exemplary embodiment of the present specification, an end group of the polymer is a substituted or unsubstituted heterocyclic group or a substituted or unsubstituted aryl group.

In an exemplary embodiment of the present specification, an end group of the polymer is a heterocyclic group which is unsubstituted or substituted with a halogen group, an alkyl group or a haloalkyl group; or an aryl group which is unsubstituted or substituted with a halogen group, an alkyl group, or a haloalkyl group.

In an exemplary embodiment of the present specification, an end group of the polymer is a heterocyclic group which is unsubstituted or substituted with a halogen group, a C₁ to C₆ alkyl group, or a C₁ to C₆ fluoroalkyl group; or an aryl group which is unsubstituted or substituted with a halogen group, a C₁ to C₆ alkyl group, or a C₁ to C₆ haloalkyl group. In an exemplary embodiment of the present specification, an end group of the polymer is a 4-(trifluoromethyl)phenyl group.

In an exemplary embodiment of the present specification, an end group of the polymer is a bromo-thiophene group.

In another exemplary embodiment, an end group of the polymer is a trifluoro-benzene group.

According to still another exemplary embodiment of the present specification, the polymer may not have an end group. In other words, the polymer may be a polymer without end-capping.

According to an exemplary embodiment of the present specification, the polymer has a number average molecular weight of preferably 5,000 g/mol to 1,000,000 g/mol.

According to an exemplary embodiment of the present specification, the polymer may have a molecular weight distribution of 1 to 10. Preferably, the polymer has a molecular weight distribution of 1 to 3.

The lower the molecular weight distribution is and the higher the number average molecular weight becomes, the better electrical characteristics and mechanical characteristics become.

Further, the number average molecular weight is preferably 100,000 or less, such that the polymer has a predetermined or more solubility, and thus, a solution application method is advantageously applied.

A number average molecular weight (Mn) and a weight average molecular weight (Mw) of the molecular weight were measured by GPC using chlorobenzene as a solvent, and the molecular weight distribution means a numerical value obtained by dividing the weight average molecular weight (Mw) by the number average molecular weight (Mn), that is, the weight average molecular weight (Mw)/the number average molecular weight (Mn).

The polymer may be prepared based on the Preparation Examples to be described below. The polymer was prepared by mixing the monomers of the respective units of the polymer with Pd₂(dba)₃ and P(o-tolyl)₃ using chlorobenzene as a solvent, and polymerizing the resulting mixture in a microwave reactor.

The polymer according to the present specification may be prepared by a multi-step chemical reaction. Monomers are prepared through an alkylation reaction, a Grignard reaction, a Suzuki coupling reaction, a Stille coupling reaction, and the like, and then final polymers may be prepared through a carbon-carbon coupling reaction such as a Stille coupling reaction. When the substituent to be introduced is a boronic acid or boronic ester compound, the polymer may be prepared through a Suzuki coupling reaction, and when the substituent to be introduced is a tributyltin or trimethyltin compound, the polymer may be prepared through a Stille coupling reaction, but the method is not limited thereto.

In an exemplary embodiment of the present specification, the composition may further include an electron acceptor.

According to an exemplary embodiment of the present specification, the electron acceptor is not particularly limited as long as the electron acceptor may serve as an electron acceptor in the relationship with the above-described polymer, and for example, it is possible to use one or two or more compounds selected from the group consisting of a non-fullerene-based compound, fullerene, a fullerene derivative, bathocuproine, a semiconducting element, and a semiconducting compound. Specifically, it is possible to use one or two or more compounds selected from the group consisting of fullerene, fullerene derivatives ((6,6)-phenyl-C61-butyric acid-methylester (PC₆₁BM), (6,6)-phenyl-C71-butyric acid-methylester (PC₇₁BM), (6,6)-phenyl-C70-butyric acid-methylester (PC₇₀BM), or (6,6)-phenyl-C61-butyric acid-cholesteryl ester (PC₆₁BCR)), perylene, polybenzimidazole (PBI), and 3,4,9,10-perylene-tetracarboxylic bis-benzimidazole (PTCBI).

In an exemplary embodiment of the present specification, the electron acceptor may be represented by the following Formula A.

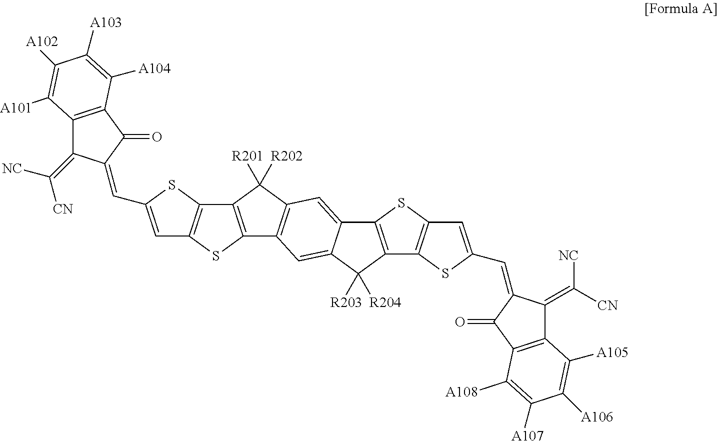

In Formula A,

R201 to R204 are the same as or different from each other, and are each independently a substituted or unsubstituted aryl group; or a substituted or unsubstituted heteroaryl group, and

A101 to A108 are the same as or different from each other, and are each independently hydrogen; a halogen group; or a substituted or unsubstituted alkyl group.

According to an exemplary embodiment of the present specification, in Formula A, R201 to R204 are the same as or different from each other, and are each independently an aryl group which is unsubstituted or substituted with an alkyl group; or a heteroaryl group which is unsubstituted or substituted with an alkyl group.

According to an exemplary embodiment of the present specification, in Formula A, R201 to R204 are the same as or different from each other, and are each independently a phenyl group which is unsubstituted or substituted with an alkyl group; or a thiophene group which is unsubstituted or substituted with an alkyl group.

According to an exemplary embodiment of the present specification, in Formula A, R201 to R204 are the same as or different from each other, and are each independently a phenyl group which is substituted with an n-hexyl group; or a thiophene group which is substituted with an n-hexyl group.

According to an exemplary embodiment of the present specification, in Formula A, R201 to R204 is a phenyl group which is substituted with an n-hexyl group.

According to an exemplary embodiment of the present specification, in Formula A, R201 to R204 is a thiophene group which is substituted with an n-hexyl group.

According to an exemplary embodiment of the present specification, in Formula A, A101 to A108 are hydrogen; fluorine; or a straight-chained or branched alkyl group.

According to an exemplary embodiment of the present specification, in Formula A, A101 to A104 are the same as or different from each other, and are each independently hydrogen; fluorine; or a straight-chained alkyl group.

According to an exemplary embodiment of the present specification, in Formula A, A101 to A104 are the same as or different from each other, and are each independently hydrogen; fluorine; or a methyl group.

According to an exemplary embodiment of the present specification, Formula A is represented by any one of the following Formulae A-1 to A-5.

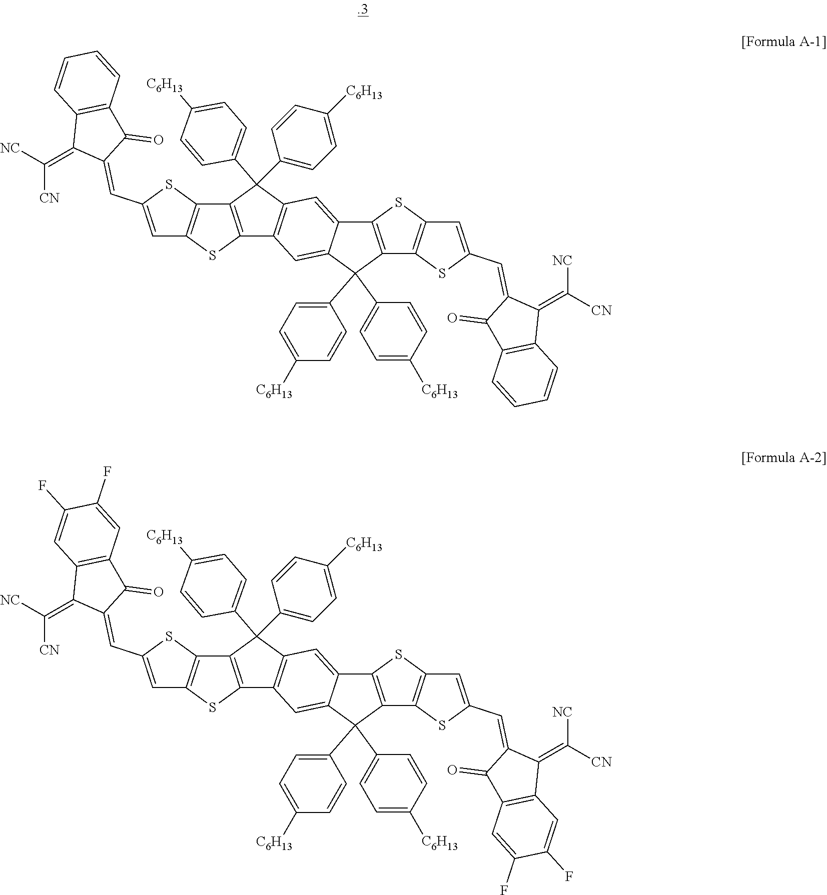

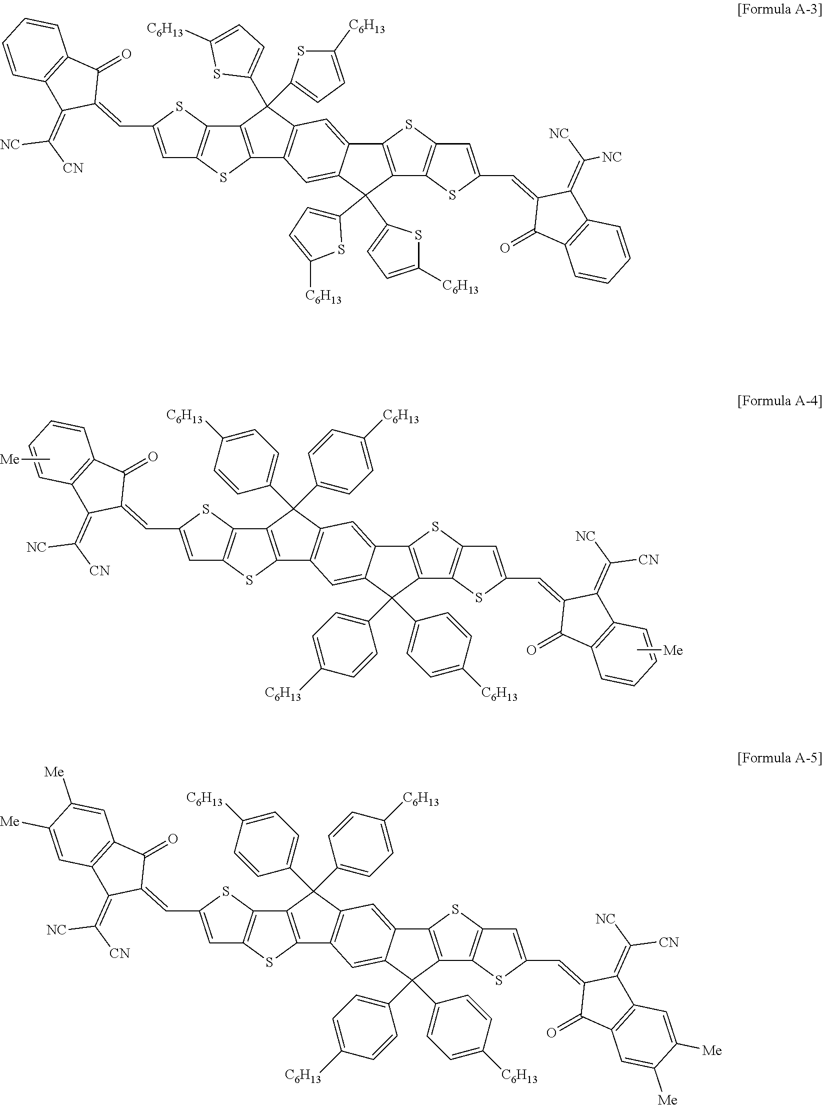

In an exemplary embodiment of the present specification, the above-described polymer may serve as an electron donor, and the electron donor and the electron acceptor constitute a bulk heterojunction (BHJ).

The bulk heterojunction means that an electron donor material and an electron acceptor material are mixed with each other in a photoactive layer of an organic solar cell.

In an exemplary embodiment of the present specification, the electron donor may also include an additional electron donor compound or polymer in addition to the above-described polymer, and may also be composed of only the above-described polymer.

In an exemplary embodiment of the present specification, the electron donor and the electron acceptor may be included at a mass ratio of 2:1 to 1:4, preferably, 1:1 to 1:4.

In an exemplary embodiment of the present specification, the composition for an organic material layer of an organic solar cell further includes an additive.

In an exemplary embodiment of the present specification, the additive has a molecular weight of 50 g/mol to 500 g/mol.

In another exemplary embodiment, the additive is an organic material having a boiling point of 30° C. to 300° C.

In the present specification, the organic material means a material including one or more carbon atoms.

In one exemplary embodiment, the additive may further include one or two additives selected from the group consisting of N-methyl-2-pyrrolidone (NMP), 1,8-diiodooctane (DIO), 1-chloronaphthalene (1-CN), diphenylether (DPE), octane dithiol, and tetrabromothiophene.

The additive may be included in an amount of 0.1 v/v % to 5 v/v %, specifically, 0.3 v/v % to 0.8 v/v %, based on the total volume of the composition or a photoactive layer of an organic solar cell to be described below.

An exemplary embodiment of the present specification relates to a method for manufacturing an organic solar cell, the organic solar cell including: a first electrode; a second electrode provided to face the first electrode; and an organic material layer having one or more layers provided between the first electrode and the second electrode and including a photoactive layer, and provides a method for manufacturing an organic solar cell, in which one or more layers of the organic material layer are formed by using the composition for an organic material layer of an organic solar cell according to the above-described exemplary embodiments. Here, cell structures, materials, and methods in the art may be applied, except that one or more layers of the organic material layer are formed by using the composition for an organic material layer of an organic solar cell according to the above-described exemplary embodiments. For example, the forming of the one or more layers of the organic material layer by using the composition for an organic material layer of an organic solar cell may be formed by coating with the composition. If necessary, drying or curing of the composition after coating with the composition may be performed. As the coating, a method known in the art may be used, and for example, spin coating, slot die, bar coater, doctor blade, dip coating methods, and the like may be applied.

An exemplary embodiment of the present specification provides an organic solar cell including: a first electrode; a second electrode provided to face the first electrode; and an organic material layer having one or more layers provided between the first electrode and the second electrode and including a photoactive layer, in which one or more layers of the organic material layer are formed by using the composition for an organic material layer of an organic solar cell according to the above-described exemplary embodiments.

When one member is disposed “on” another member in the present specification, this includes not only a case where the one member is brought into contact with another member, but also a case where still another member is present between the two members.

The organic solar cell according to an exemplary embodiment of the present specification includes a first electrode, a photoactive layer, and a second electrode. Here, the photoactive layer may include the composition for an organic material layer of an organic solar cell according to the above-described exemplary embodiments. The organic solar cell may further include a substrate, a hole transport layer, and/or an electron transport layer.

In an exemplary embodiment of the present specification, when the organic solar cell accepts a photon from an external light source, an exciton is separated into an electron and a hole at the interface between an electron donor and an electron acceptor of the photoactive layer. The separated hole is transported from a hole transport layer to a positive electrode via the electron donor in the photoactive layer, and the separated electron is transported from an electron transport layer to a negative electrode via the electron acceptor in the photoactive layer.

In an exemplary embodiment of the present specification, the organic material layer includes a hole transport layer, a hole injection layer, or a layer which simultaneously transports and injects holes, and the hole transport layer, the hole injection layer, or the layer which simultaneously transports and injects holes includes the polymer.

In another exemplary embodiment, the organic material layer includes an electron injection layer, an electron transport layer, or a layer which simultaneously injects and transports electrons, and the electron injection layer, the electron transport layer, or the layer which simultaneously injects and transports electrons includes the polymer.

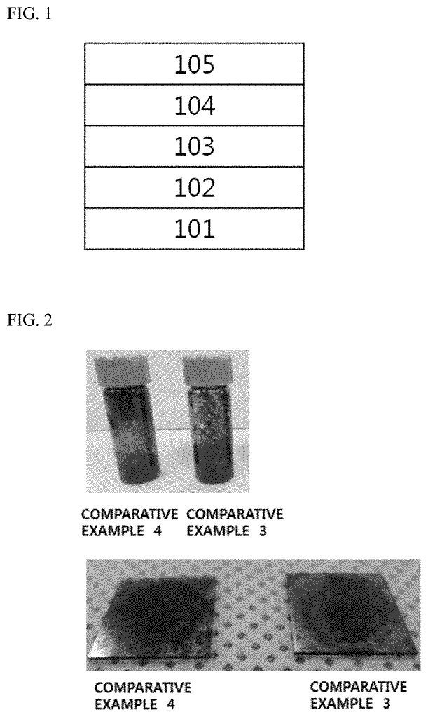

FIG. 1 is a view illustrating an organic solar cell according to an exemplary embodiment of the present specification, and illustrates a structure in which an electron transport layer 102, a photoactive layer 103, a hole transport layer 104, and a second electrode 105 are sequentially stacked on a first electrode 101, but the structure of the organic solar cell of the present specification is not limited thereto.

In an exemplary embodiment of the present specification, the organic solar cell may further include an additional organic material layer. The organic solar cell may reduce the number of organic material layers by using an organic material which simultaneously has various functions.

In an exemplary embodiment of the present specification, the first electrode is an anode, and the second electrode is a cathode. In another exemplary embodiment, the first electrode is a cathode, and the second electrode is an anode.

In an exemplary embodiment of the present specification, in the organic solar cell, a cathode, a photoactive layer, and an anode may be arranged in this order, and an anode, a photoactive layer, and a cathode may be arranged in this order, but the arrangement order is not limited thereto.

In another exemplary embodiment, in the organic solar cell, an anode, a hole transport layer, a photoactive layer, an electron transport layer, and a cathode may also be arranged in this order, and a cathode, an electron transport layer, a photoactive layer, a hole transport layer, and an anode may also be arranged in this order, but the arrangement order is not limited thereto.

In an exemplary embodiment of the present specification, the organic solar cell has a normal structure. The normal structure may mean that an anode is formed on a substrate. Specifically, according to an exemplary embodiment of the present specification, when the organic solar cell has a normal structure, a first electrode to be formed on a substrate may be an anode.

In an exemplary embodiment of the present specification, the organic solar cell has an inverted structure. The inverted structure may mean that a cathode is formed on a substrate. Specifically, according to an exemplary embodiment of the present specification, when the organic solar cell has an inverted structure, a first electrode to be formed on a substrate may be a cathode.

In an exemplary embodiment of the present specification, the organic solar cell has a tandem structure. In this case, the organic solar cell may include a photoactive layer having two or more layers. The organic solar cell according to an exemplary embodiment of the present specification may have a photoactive layer having one or two or more layers.

In another exemplary embodiment, a buffer layer may be provided between the photoactive layer and the hole transport layer, or between the photoactive layer and the electron transport layer. In this case, a hole injection layer may be further provided between an anode and a hole transport layer. Further, an electron injection layer may be further provided between the cathode and the electron transport layer.

In the present specification, the substrate may be a glass substrate or a transparent plastic substrate having excellent transparency, surface smoothness, ease of handling, and waterproofing properties, but is not limited thereto, and the substrate is not limited as long as the substrate is typically used in the organic solar cell. Specific examples thereof include glass or polyethylene terephthalate (PET), polyethylene naphthalate (PEN), polypropylene (PP), polyimide (PI), triacetyl cellulose (TAC), and the like, but are not limited thereto.

The first electrode may be a material which is transparent and has excellent conductivity, but is not limited thereto. Examples thereof include: a metal, such as vanadium, chromium, copper, zinc, and gold, or an alloy thereof; a metal oxide, such as zinc oxide, indium oxide, indium tin oxide (ITO), and indium zinc oxide (IZO); a combination of metal and oxide, such as ZnO:Al or SnO₂:Sb; a conductive polymer, such as poly(3-methylthiophene), poly[3,4-(ethylene-1,2-dioxy)thiophene] (PEDOT), polypyrrole, and polyaniline; and the like, but are not limited thereto.

A method of forming the first electrode is not particularly limited, but the first electrode may be formed, for example, by being applied onto one surface of a substrate or by being coated in the form of a film using a method such as sputtering, e-beam, thermal deposition, spin coating, screen printing, inkjet printing, doctor blade, or gravure printing.

When the first electrode is formed on a substrate, the first electrode may be subjected to processes of cleaning, removing moisture, and hydrophilic modification.

For example, a patterned ITO substrate is sequentially cleaned with a cleaning agent, acetone, and isopropyl alcohol (IPA), and then dried on a hot plate at 100° C. to 150° C. for 1 to 30 minutes, preferably at 120° C. for 10 minutes in order to remove moisture, and when the substrate is completely cleaned, the surface of the substrate is hydrophilically modified.

Through the surface modification described above, the junction surface potential may be maintained at a level suitable for a surface potential of a photoactive layer. Further, during the modification, a polymer thin film may be easily formed on the first electrode, and the quality of the thin film may also be improved.

Examples of a pre-treatment technology for a first electrode include a) a surface oxidation method using a parallel flat plate-type discharge, b) a method of oxidizing the surface through ozone produced by using UV rays in a vacuum state, c) an oxidation method using oxygen radicals produced by plasma, and the like.

One of the methods may be selected according to the state of the first electrode or the substrate. However, although any method is used, it is preferred to commonly prevent oxygen from being separated from the surface of the first electrode or the substrate, and maximally inhibit moisture and organic materials from remaining. In this case, it is possible to maximize a substantial effect of the pre-treatment.

As a specific example, it is possible to use a method of oxidizing the surface through ozone produced by using UV. In this case, a patterned ITO substrate after being ultrasonically cleaned is baked on a hot plate and dried well, and then introduced into a chamber, and the patterned ITO substrate may be cleaned by ozone generated by allowing an oxygen gas to react with UV light by operating a UV lamp.

However, the surface modification method of the patterned ITO substrate in the present specification need not be particularly limited, and any method may be used as long as the method is a method of oxidizing a substrate.

The second electrode may be a metal having a low work function, but is not limited thereto. Specific examples thereof include: a metal such as magnesium, calcium, sodium, potassium, titanium, indium, yttrium, lithium, gadolinium, aluminum, silver, tin, and lead, or an alloy thereof; and a multi-layer structured material, such as LiF/Al, LiO₂/Al, LiF/Fe, Al:Li, Al:BaF₂, and Al:BaF₂:Ba, but are not limited thereto.

The second electrode may be deposited and formed in a thermal depositor showing a vacuum degree of 5×10⁻⁷ torr or less, but the forming method is not limited to this method.

A material for the hole transport layer and/or a material for the electron transport layer serve to efficiently transfer electrons and holes separated from a photoactive layer to an electrode, and the materials are not particularly limited.

The material for the hole transport layer may be poly(3,4-ethylenedioxythiophene) doped with poly(styrenesulfonic acid) (PEDOT:PSS) and molybdenum oxide (MoOₓ); vanadium oxide (V₂O₅); nickel oxide (NiO); tungsten oxide (WOₓ); and the like, but is not limited thereto.

The material for the electron transport layer may be electron-extracting metal oxides, and specific examples thereof include: metal complexes of 8-hydroxyquinoline; complexes including Alq₃; metal complexes including Liq; LiF; Ca; titanium oxide (TiOₓ); zinc oxide (ZnO); vanadium oxide (VOx); cesium carbonate (Cs₂CO₃); non-conjugated polyelectrolytes (NPE), for example, polyethyleneimine (PEI), polyethyleneimine ethoxylate (PETE), polyallylamine (PAA), and the like, but are not limited thereto.

The photoactive layer may be formed by dissolving a composition including an electron donor and an electron acceptor in an organic solvent, and then applying the solution by a method such as spin coating, dip coating, screen printing, spray coating, doctor blade, and brush painting, but the forming method is not limited thereto.

Hereinafter, the present specification will be described in detail with reference to Examples for specifically describing the present specification. However, the Examples according to the present specification may be modified in various forms, and it is not interpreted that the scope of the present specification is limited to the Examples described below in detail. The Examples of the present specification are provided to more completely explain the present specification to a person with ordinary skill in the art.

### MODE FOR INVENTION

### Synthesis of Polymer

### Synthesis Example 1

Monomers A-1, B-1, and C-1 were mixed with Pd₂(dba)₃ and P(o-tolyl)₃ using chlorobenzene as a solvent, and the resulting mixture was polymerized in a microwave reactor, thereby preparing the following Polymer 1.

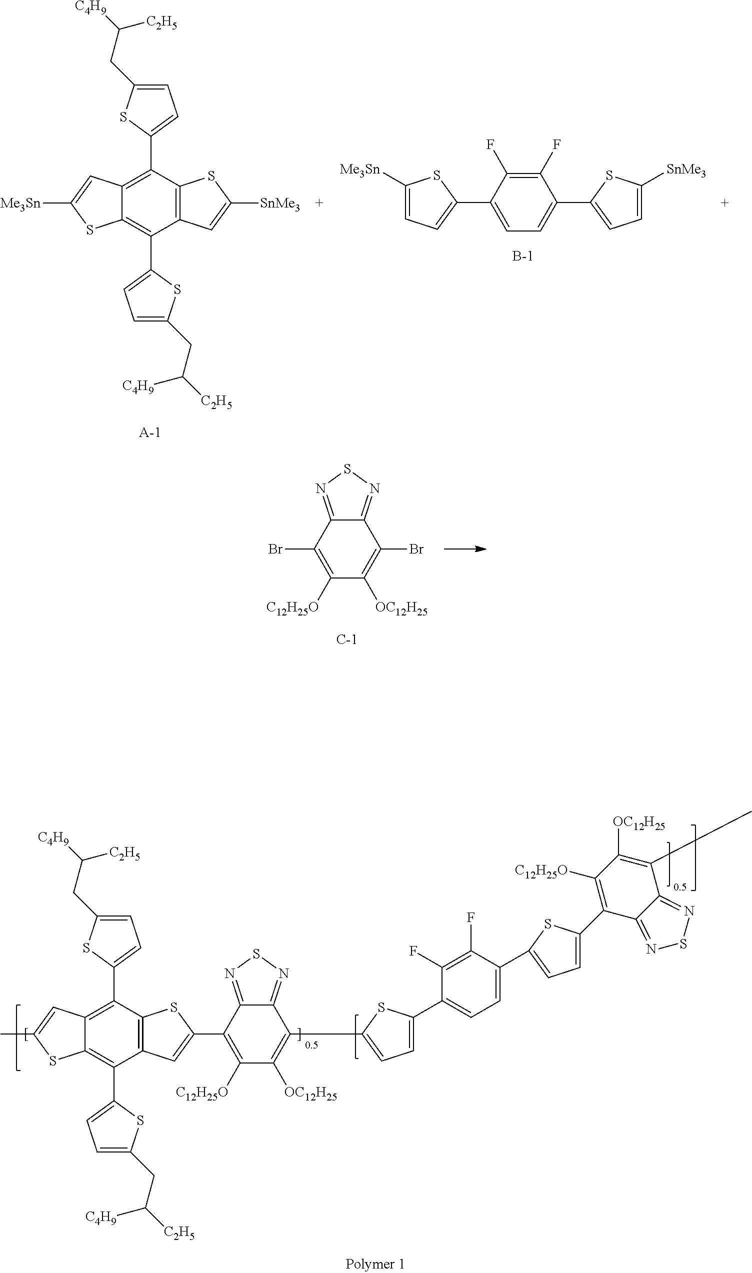

### Synthesis Example 2

The following Polymer 2 was prepared by performing the same method as in Synthesis Example 1, except that the following Monomer A-2 was used instead of Monomer A-1.

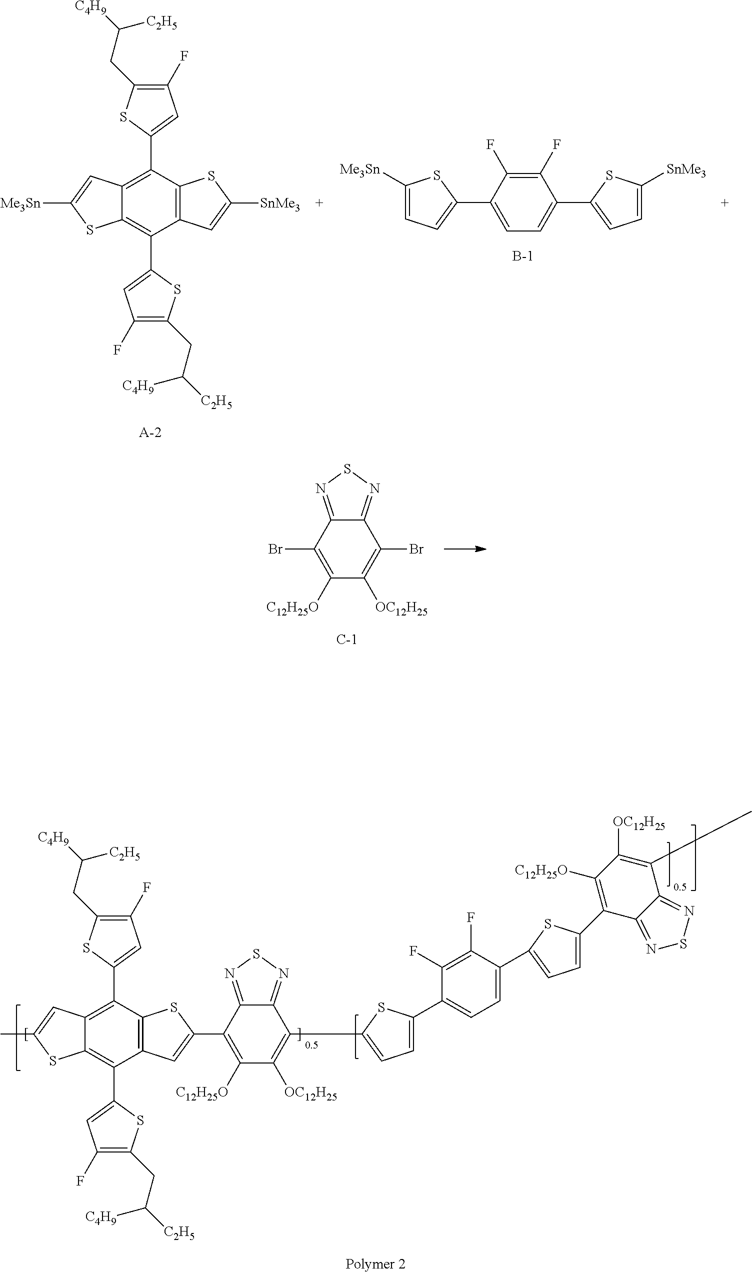

### Synthesis Example 3

The following Polymer 3 was prepared by performing the same method as in Synthesis Example 1, except that the following Monomer C-2 was used instead of Monomer C-1.

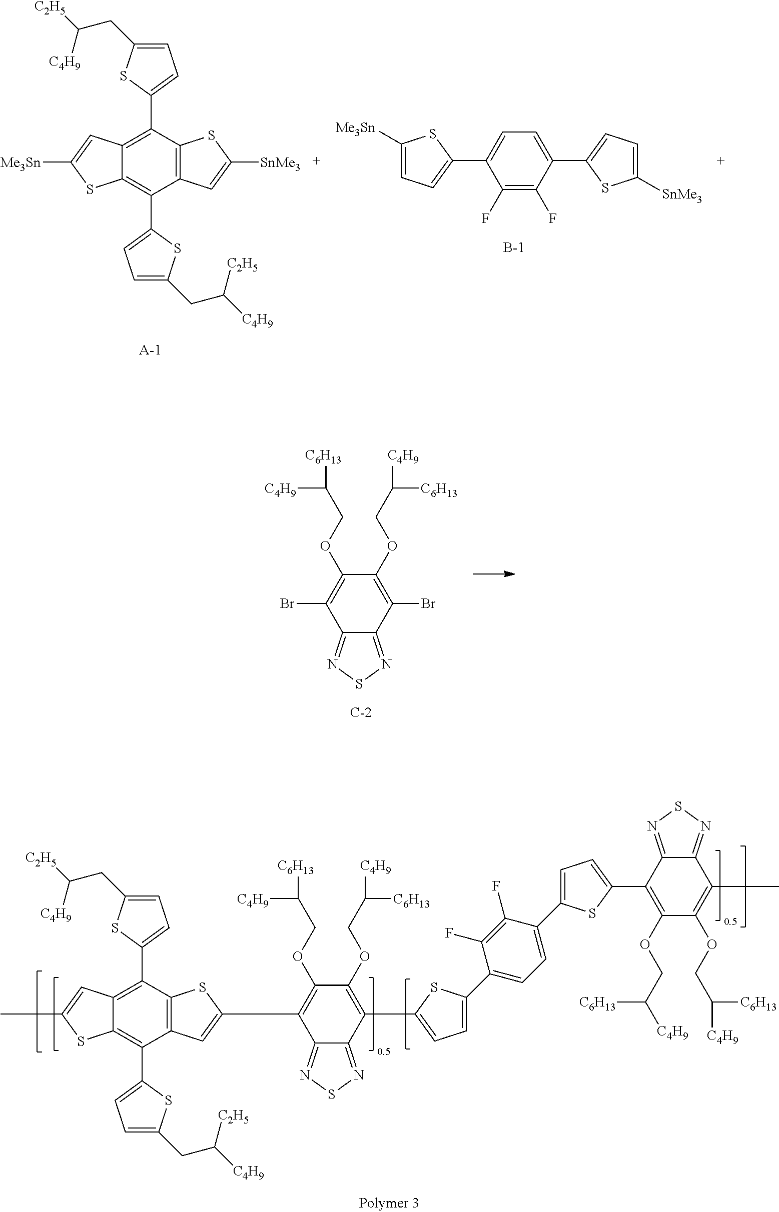

### Synthesis Example 4

The following Polymer 4 was prepared by performing the same method as in Synthesis Example 1, except that the following Monomer A-2 was used instead of Monomer A-1, and the following Monomer C-2 was used instead of Monomer C-1.

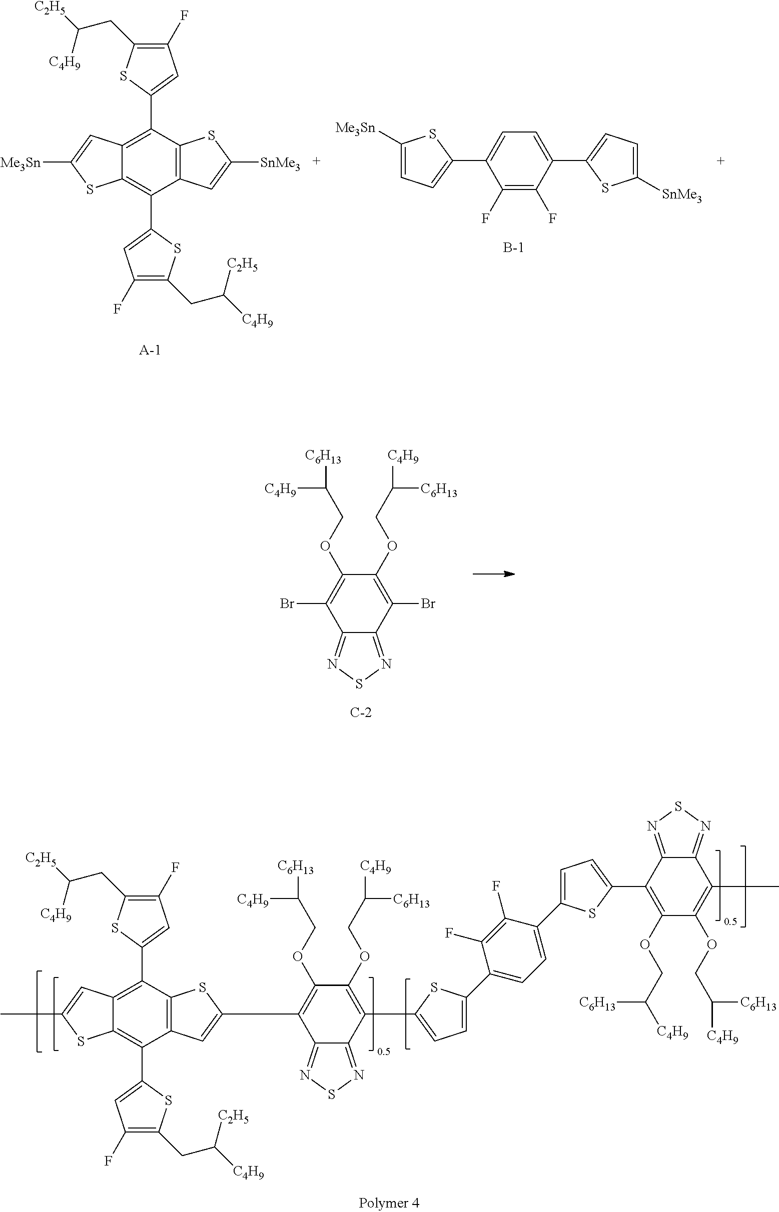

### Synthesis Example 5

The following Polymer 5 was prepared by performing the same method as in Synthesis Example 1, except that the following Monomer A-3 was used instead of Monomer A-1.

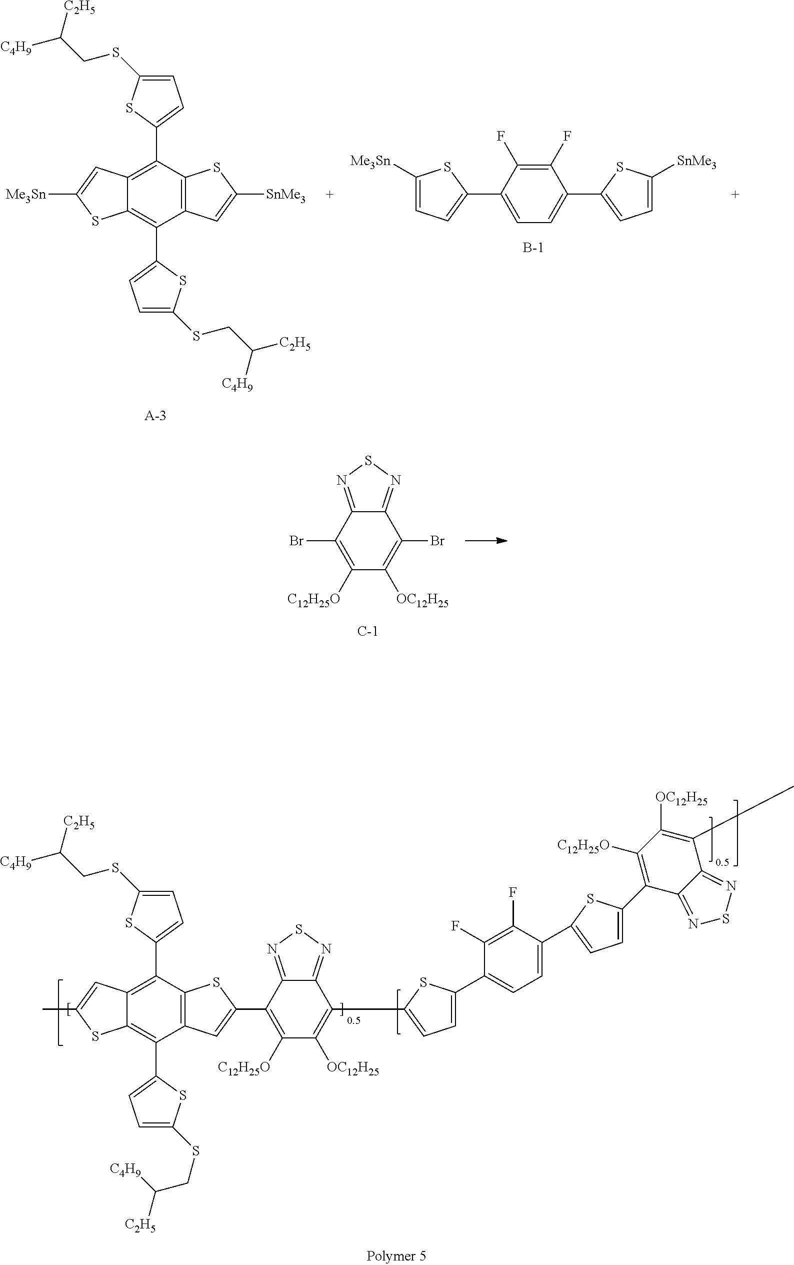

### Synthesis Example 6

The following Polymer 6 was prepared by performing the same method as in Synthesis Example 1, except that the following Monomer A-4 was used instead of Monomer A-1.

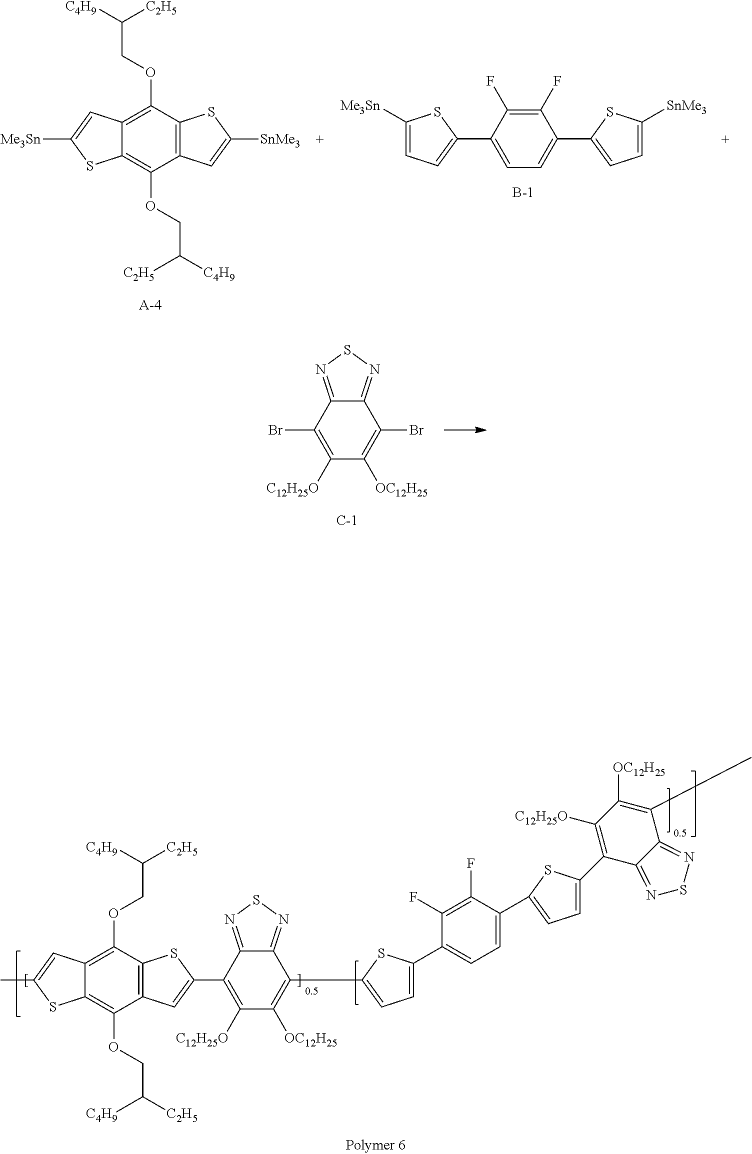

### Synthesis Example 7

The following Polymer 7 was prepared by performing the same method as in Synthesis Example 1, except that the following Monomer C-3 was used instead of Monomer C-1.

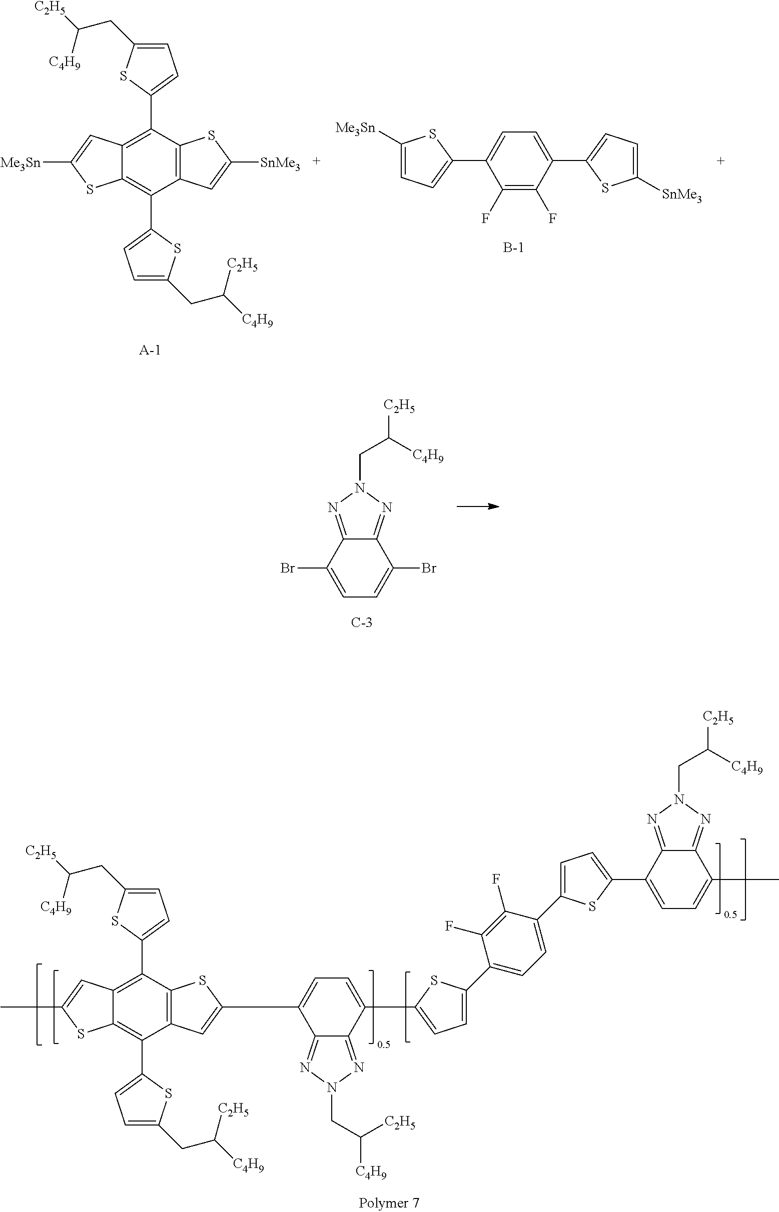

### Synthesis Example 8

The following Polymer 8 was prepared by performing the same method as in Synthesis Example 1, except that the following Monomer A-2 was used instead of Monomer A-1, and the following Monomer C-3 was used instead of Monomer C-1.

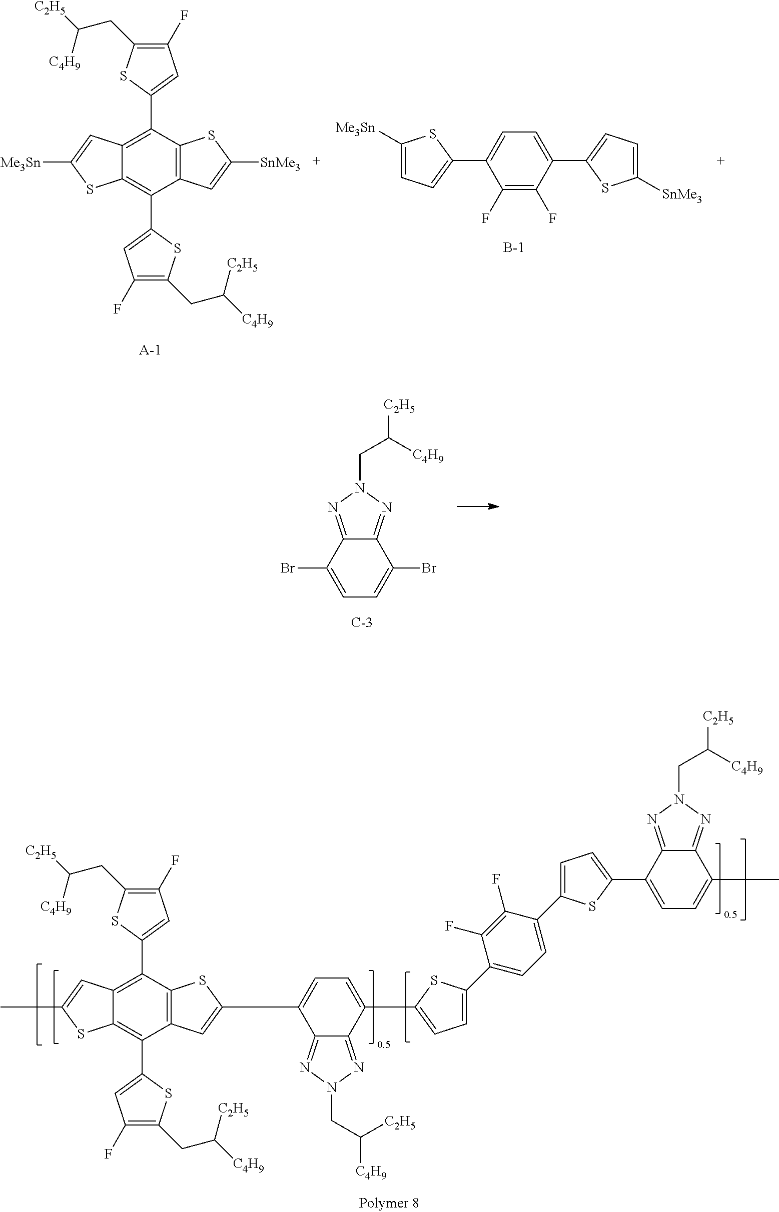

### Synthesis Example 9

The following Polymer 9 was prepared by performing the same method as in Synthesis Example 1, except that the following Monomer A-3 was used instead of Monomer A-1, and the following Monomer C-3 was used instead of Monomer C-1.

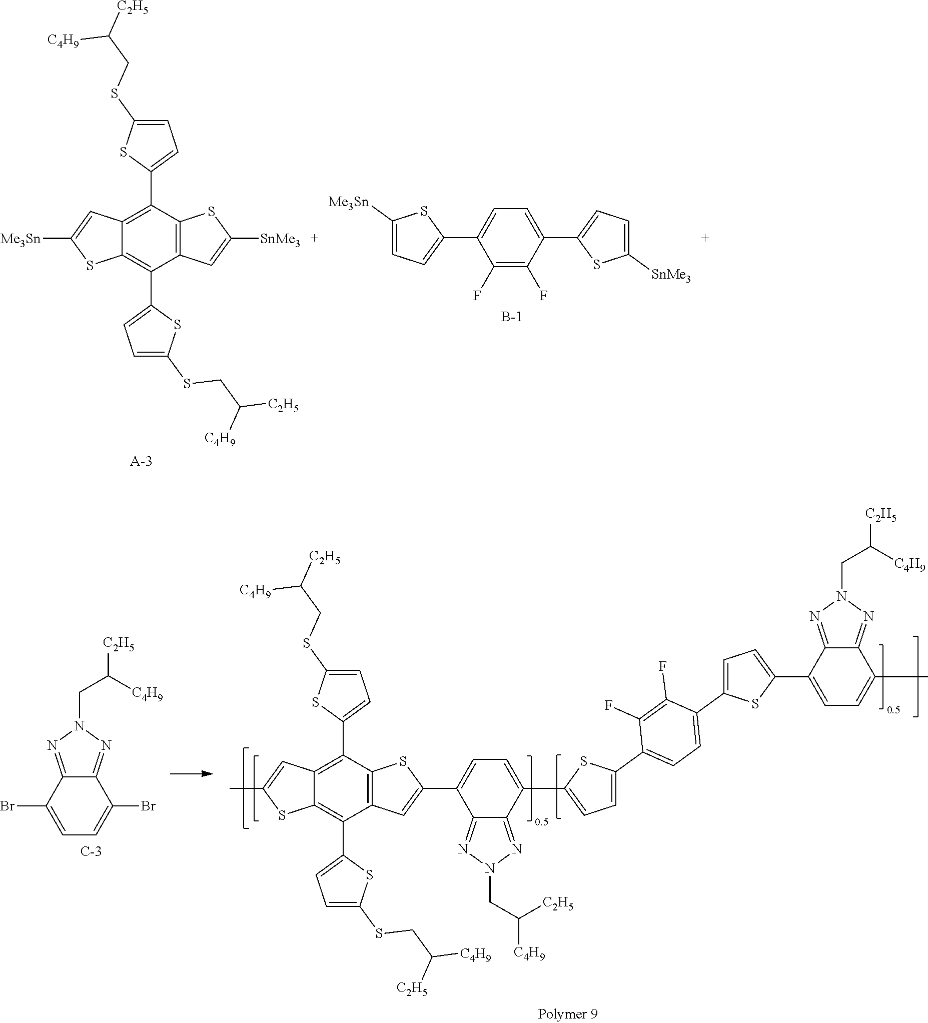

### Synthesis Example 10

The following Polymer 10 was prepared by performing the same method as in Synthesis Example 1, except that the following Monomer C-4 was used instead of Monomer C-1.

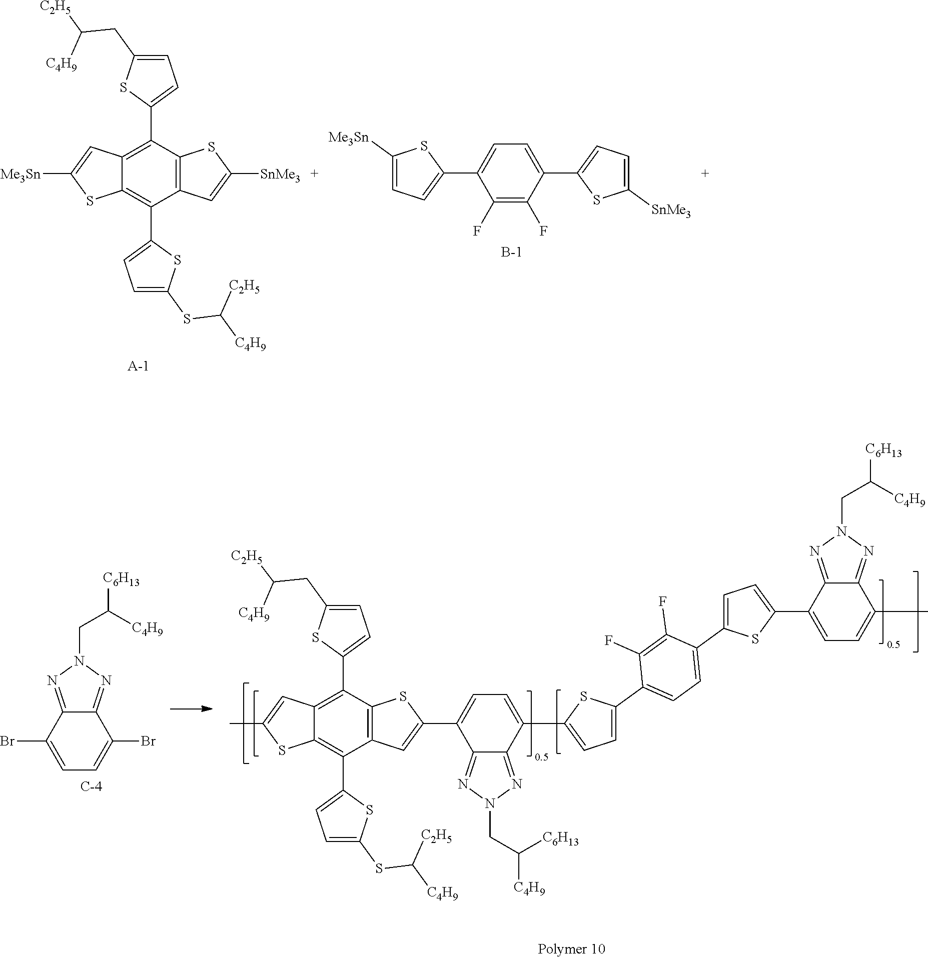

### Synthesis Example 11

The following Polymer 11 was prepared by performing the same method as in Synthesis Example 1, except that the following Monomer A-2 was used instead of Monomer A-1, and the following Monomer C-4 was used instead of Monomer C-1.

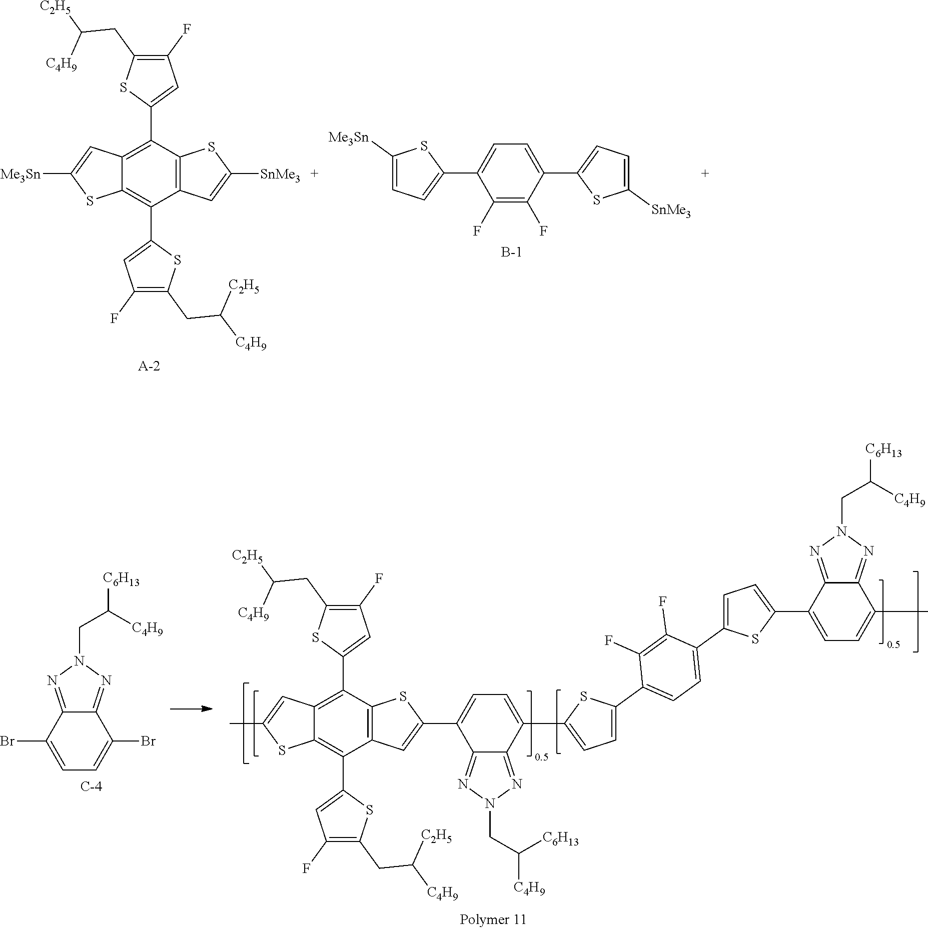

### Synthesis Example 12

The following Polymer 12 was prepared by performing the same method as in Synthesis Example 1, except that the following Monomer A-3 was used instead of Monomer A-1, and the following Monomer C-4 was used instead of Monomer C-1.

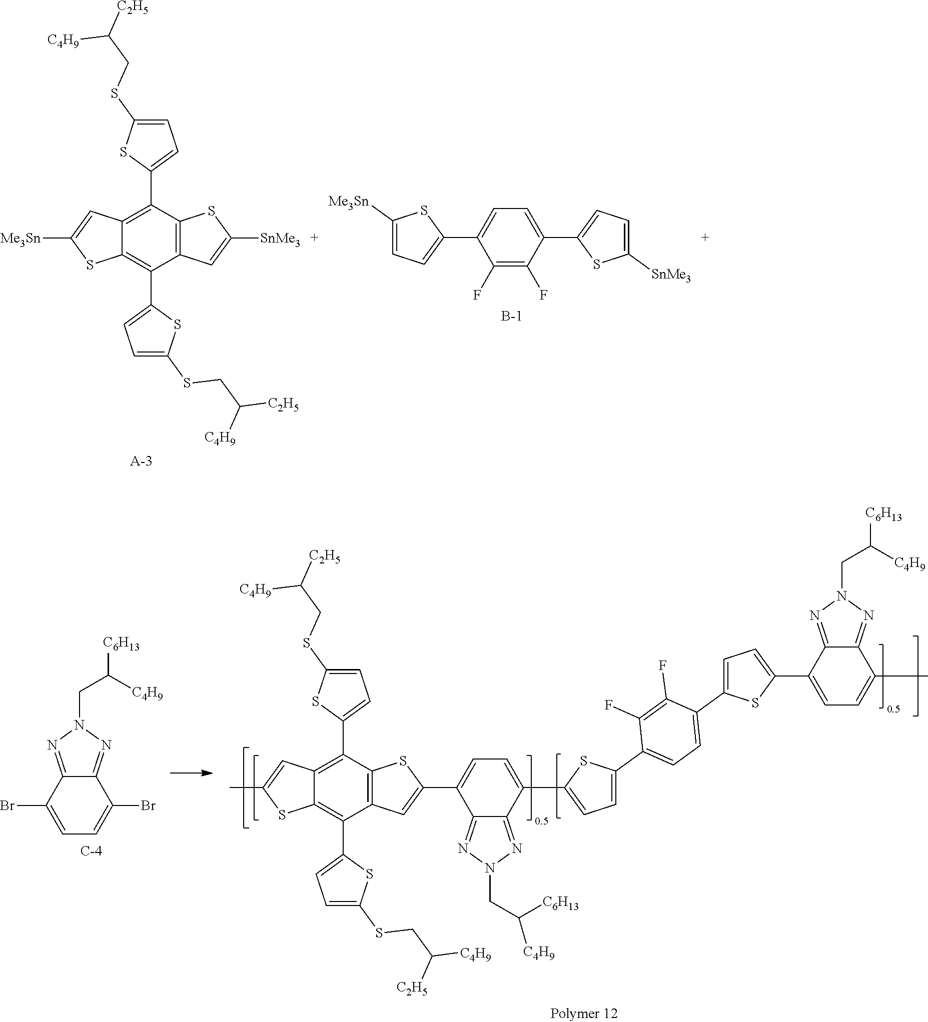

The molecular weight and molecular weight distribution of each of the polymers prepared in Synthesis Examples 1 to 12 are shown in the following Table 1.

TABLE 1

| | | | PDI |
|---|---|---|---|
| | Mn (Number | Mw (Weight | (Molecular |
| | average | average | weight |
| | molecular | molecular | distribution, |
| | weight) | weight) | Mw/Mn) |
| Polymer 1 | 33,860 | 57,490 | 1.7 |
| Polymer 2 | 62,300 | 71,900 | 1.15 |
| Polymer 3 | 28,500 | 42,720 | 1.50 |
| Polymer 4 | 35,870 | 48,250 | 1.34 |
| Polymer 5 | 34,580 | 43,770 | 1.26 |
| Polymer 6 | 27,850 | 36,290 | 1.3 |
| Polymer 7 | 19,930 | 28,590 | 1.43 |
| Polymer 8 | 20,080 | 30,220 | 1.50 |
| Polymer 9 | 25,370 | 34,290 | 1.35 |
| Polymer 10 | 29,930 | 40,590 | 1.35 |
| Polymer 11 | 31,220 | 39,680 | 1.27 |
| Polymer 12 | 33,420 | 42,290 | 1.26 |

In Table 1, a number average molecular weight (Mn) and a weight average molecular weight (Mw) of the molecular weight were measured by GPC using chlorobenzene as a solvent, and the molecular weight distribution means a numerical value obtained by dividing the weight average molecular weight (Mw) by the number average molecular weight (Mn), that is, the weight average molecular weight (Mw)/the number average molecular weight (Mn).

Although only the synthesis methods of Polymers 1 to 12 were exemplified above, polymers other than the aforementioned polymers may be synthesized by appropriately changing the substituents of Formulae 1, 2, and 3, or 1, 2, and 4 according to an exemplary embodiment of the present specification.

[Manufacture of Organic Solar Cell]

### Example 1

A composite solution was prepared by dissolving Polymer 1 and the following Formula A-1 at a weight ratio of 1:2 in toluene. In this case, the concentration of the composite solution was adjusted to 2 wt %, and the organic solar cell was made to have an inverted structure of ITO/ZnO/a photoactive layer/MoO₃/Ag by using the concentration of 2 wt %.

Specifically, ITO was formed as a first electrode on a substrate, the ITO substrate was ultrasonically washed by using distilled water, acetone, and 2-propanol, and the ITO surface was treated with ozone for 10 minutes.

An electron transport layer (thickness 40 nm) was formed by spin-coating the ITO with ZnO. Next, a photoactive layer (thickness 100 nm) was formed by spin-coating the electron transport layer with the composite solution of Polymer 1 and the following Formula A-1, and a hole transport layer was formed by depositing MoO₃ to have a thickness of 10 nm on the photoactive layer. Finally, Ag was deposited to have a thickness of 100 nm by using a thermal evaporator under a vacuum of 3×10⁻⁸ torr in order to form a second electrode, thereby manufacturing an organic solar cell.

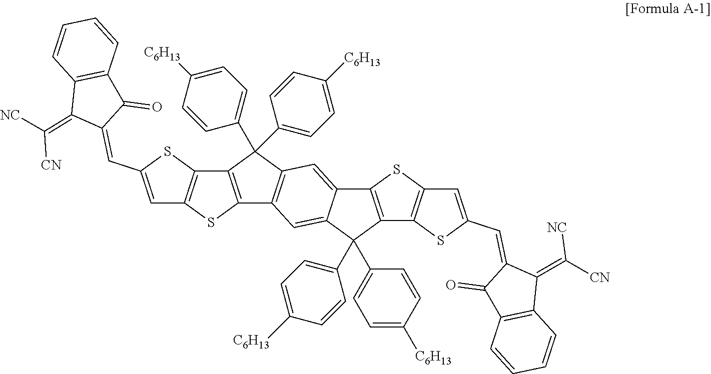

### Example 2

An organic solar cell was manufactured in the same manner as in Example 1, except that the following Formula A-2 was used instead of Formula A-1 in Example 1.

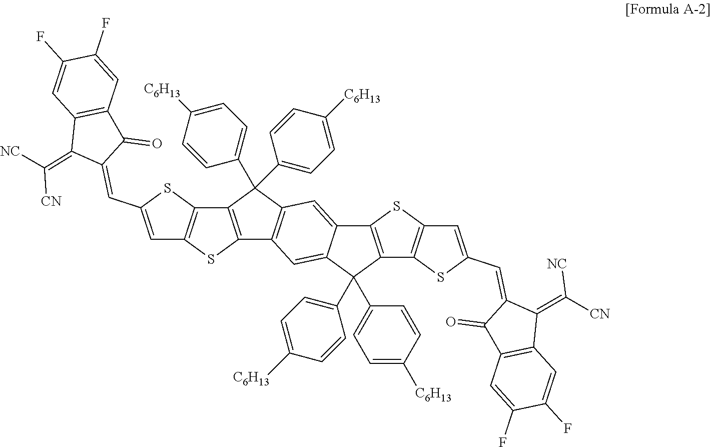

### Example 3

An organic solar cell was manufactured in the same manner as in Example 1, except that Polymer 2 was used instead of Polymer 1 in Example 1.

### Example 4

An organic solar cell was manufactured in the same manner as in Example 3, except that Formula A-2 was used instead of Formula A-1 in Example 3.

### Examples 5 to 14

Organic solar cells were manufactured in the same manner as in Example 1, except that the following Polymers 3 to 12 were used instead of Polymer 1 in Example 1.

### Examples 15 to 28

Organic solar cells were manufactured in the same manner as in Examples 1 to 14, except that as the solvent, 2-methylanisole was used instead of toluene.

### Comparative Example 1

An organic solar cell was manufactured in the same manner as in Example 1, except that the following Comparative Compound 1 was used instead of Polymer 1 in Example 1.

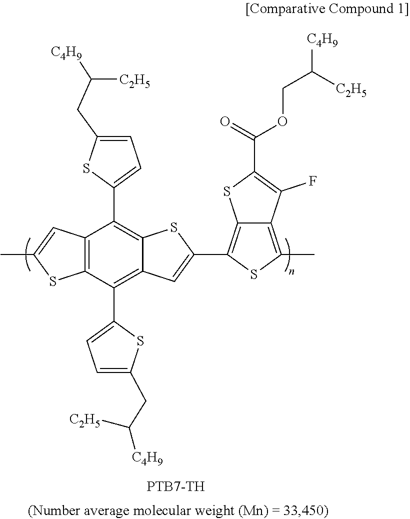

### Comparative Example 2

An organic solar cell was manufactured in the same manner as in Comparative Example 1, except that Comparative Compound 1 and the compound of Formula A-1 were used at a mass ratio of 1:1.5.

Comparative Examples 3 and 4 The same experiment as in Comparative Examples 1 and 2 was performed, except that as the solvent, 2-methylanisole was used instead of toluene. However, a film was not formed because the material was not dissolved in the solvent as illustrated in FIG. 2, and accordingly, a device could not be manufactured.

### Comparative Example 5

An organic solar cell was manufactured in the same manner as in Example 1, except that the following Comparative Compound 2 was used instead of Polymer 1 in Example 1.

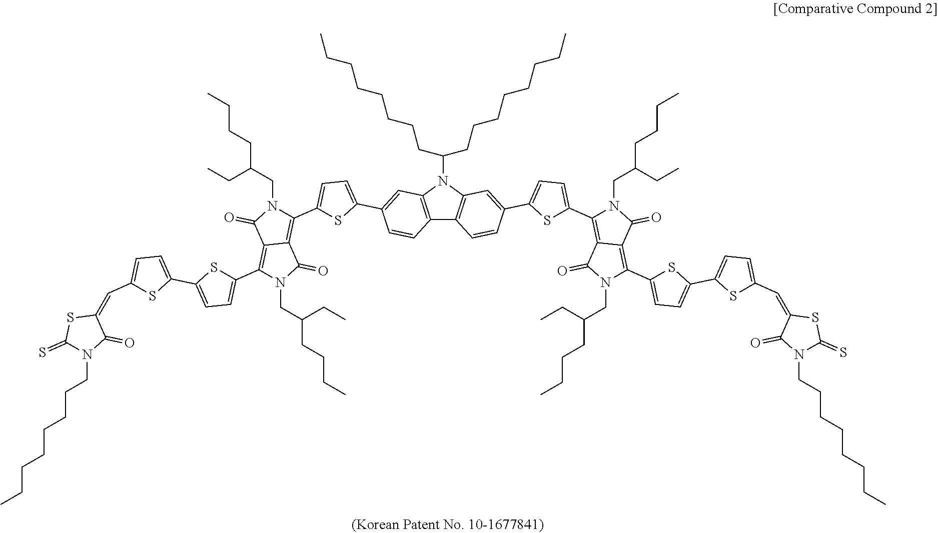 [SMILES: CCCCCCCCC(CCCCCCCC)n1c2cc(-c3ccc(C4=C5C(=O)N(CC(CC)CCCC)C(c6ccc(-c7ccc(/C=C8/SC(=S)N(CCCCCCCC)C8=O)s7)s6)=C5C(=O)N4CC(CC)CCCC)s3)ccc2c2ccc(-c3ccc(C4=C5C(=O)N(CC(CC)CCCC)C(c6ccc(-c7ccc(/C=C8/SC(=S)N(CCCCCCCC)C8=O)s7)s6)=C5C(=O)N4CC(CC)CCCC)s3)cc21]

### Comparative Examples 6 and 7

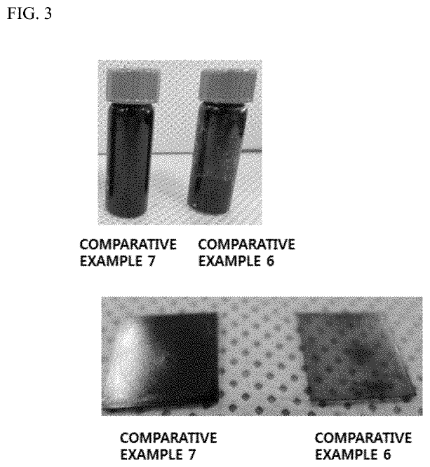

The same experiment as in Comparative Example 5 was performed, except that as the solvent, 2-methylanisole was used instead of toluene, and Comparative Compound 2 and the compound of Formula A-1 were used at a mass ratio of 1:2 (Comparative Example 6) and 1:1.5 (Comparative Example 7). However, a film was not formed because the material was not dissolved in the solvent as illustrated in FIG. 3, and accordingly, a device could not be manufactured.

### Comparative Example 8

An organic solar cell was manufactured in the same manner as in Example 10, except that the following Comparative Compound 3 was used instead of Polymer 8 in Example 10.

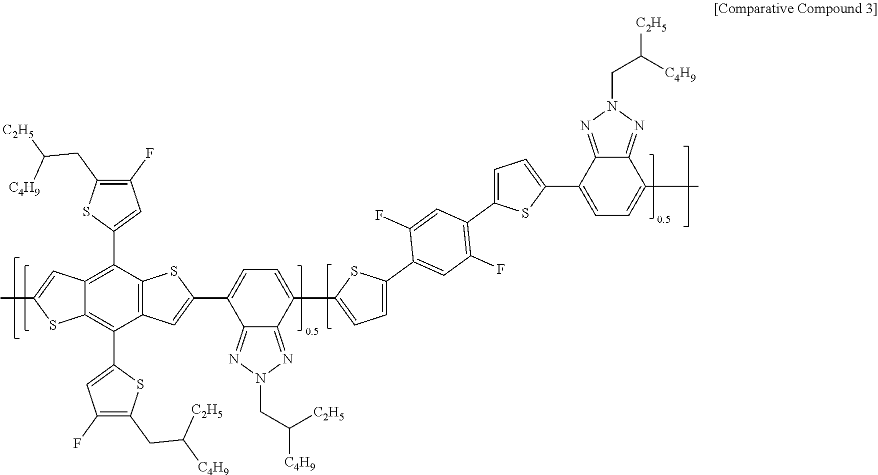

### Comparative Example 9

An organic solar cell was manufactured in the same manner as in Comparative Example 8, except that as the solvent, 2-methylanisole was used instead of toluene in Comparative Example 8.

The photoelectric conversion characteristics of the organic solar cells manufactured in the Comparative Examples and the Examples were measured under the condition of 100 mW/cm² (AM 1.5), and the results thereof are shown in the following Table 2.

TABLE 2

| | V_{oc} (V) | J_{sc} (mA/cm²) | FF | η (%) |
|---|---|---|---|---|
| Example 1 | 0.824 | 14.256 | 0.706 | 8.30 |
| Example 2 | 0.786 | 16.520 | 0.616 | 8.00 |
| Example 3 | 1.007 | 14.407 | 0.594 | 8.62 |
| Example 4 | 0.874 | 15.240 | 0.684 | 9.12 |
| Example 5 | 0.902 | 14.134 | 0.654 | 8.34 |
| Example 6 | 0.966 | 15.116 | 0.557 | 8.14 |
| Example 7 | 0.902 | 12.438 | 0.654 | 7.34 |
| Example 8 | 0.893 | 13.465 | 0.668 | 8.03 |
| Example 9 | 0.893 | 14.206 | 0.667 | 8.46 |
| Example 10 | 0.962 | 15.310 | 0.548 | 8.07 |
| Example 11 | 0.917 | 13.448 | 0.645 | 7.95 |
| Example 12 | 0.906 | 13.765 | 0.659 | 8.22 |
| Example 13 | 0.978 | 14.912 | 0.542 | 7.90 |
| Example 14 | 0.926 | 14.513 | 0.594 | 7.98 |
| Example 15 | 0.836 | 15.884 | 0.613 | 8.14 |
| Example 16 | 0.782 | 16.195 | 0.630 | 7.98 |
| Example 17 | 1.002 | 14.226 | 0.586 | 8.35 |
| Example 18 | 0.846 | 17.740 | 0.566 | 8.49 |
| Example 19 | 0.844 | 15.417 | 0.603 | 7.85 |
| Example 20 | 0.988 | 14.049 | 0.563 | 7.82 |
| Example 21 | 0.896 | 13.899 | 0.636 | 7.92 |
| Example 22 | 0.845 | 16.961 | 0.522 | 7.49 |
| Example 23 | 0.885 | 13.333 | 0.690 | 8.14 |
| Example 24 | 0.997 | 14.546 | 0.508 | 7.37 |
| Example 25 | 0.902 | 12.639 | 0.641 | 7.30 |
| Example 26 | 0.877 | 12.988 | 0.706 | 8.04 |
| Example 27 | 0.965 | 14.453 | 0.525 | 7.33 |
| Example 28 | 0.889 | 13.978 | 0.595 | 7.40 |
| Comparative | 0.703 | 2.662 | 0.517 | 0.97 |
| Example 1 | | | | |
| Comparative | 0.755 | 2.983 | 0.420 | 0.95 |
| Example 2 | | | | |
| Comparative | 0.588 | 1.717 | 0.367 | 0.37 |
| Example 5 | | | | |
| Comparative | 0.924 | 4.107 | 0.312 | 1.19 |
| Example 8 | | | | |
| Comparative | 0.687 | 4.739 | 0.324 | 1.06 |
| Example 9 | | | | |

V_{oc}, J_{sc}, FF, and η mean an open-circuit voltage, a short-circuit current, a fill factor, and energy conversion efficiency, respectively. The open-circuit voltage and the short-circuit current are an X axis intercept and a Y axis intercept, respectively, in the fourth quadrant of the voltage-current density curve, and as the two values are increased, the efficiency of the solar cell is preferably increased. In addition, the fill factor is a value obtained by dividing the area of a rectangle, which may be drawn within the curve, by the product of the short-circuit current and the open-circuit voltage. The energy conversion efficiency may be obtained when these three values are divided by the intensity of the irradiated light, and the higher value is preferred.

In Table 2, it could be confirmed that the Examples using the polymers according to the exemplary embodiments of the present specification exhibited excellent efficiencies even when the cells were manufactured by using a non-halogen-based solvent such as toluene or 2-methylanisole, but when the comparative compounds were used, the case where the non-halogen-based solvent was used had extremely low efficiencies. Specifically, PTB7-TH used in Comparative Example 1 is a highly efficient material well-known in the art, and it is known that when a halogen-based solvent such as chlorobenzene is used, PTB7-TH may achieve the efficiency of about 11% during the use with PCMB and the efficiency of about 7 to 8% during the use with Formula A-1 (DOI: 10.1002/adma.201404317 or DOI: 10.1002/adma.201404317). Further, Comparative Compound 2 used in Comparative Example 5 may also exhibit high efficiency when the halogen-based solvent is used (Korean Patent No. 10-1677841). However, it could be confirmed that as in Comparative Examples 1, 2, and 5 in Table 2, when the non-halogen-based solvent was used, the open-circuit voltage was very high, and the short-circuit current and the energy conversion efficiency were extremely low.

In addition, even when 2-methylanisole was used as the solvent, the organic solar cells exhibiting excellent characteristics were manufactured in the Examples, whereas in Comparative Examples 3, 4, 6, and 7, films could not be manufactured because the materials were not dissolved, and as a result, devices could not be manufactured.

Furthermore, when Example 10 and Example 24 were compared with Comparative Example 8 and Comparative Example 9, respectively, it can be confirmed that the case of using Comparative Example 3 in which fluorine was substituted at the para position of the benzene ring in the second unit of the polymer had significantly low energy conversion efficiency than the case of using Polymer 8 substituted at the ortho position. Specifically, it can be confirmed that in both Comparative Example 8 in which toluene was used as the solvent and Comparative Example 9 in which 2-methylanisole was used as the solvent, the device efficiencies were measured as a level of 1%.

1. A composition for an organic material layer of an organic solar cell, the composition comprising:
a polymer comprising a first unit of Formula 1, a second unit of Formula 2, and a third unit of Formula 3 or Formula 4; and
a non-halogen-based solvent: 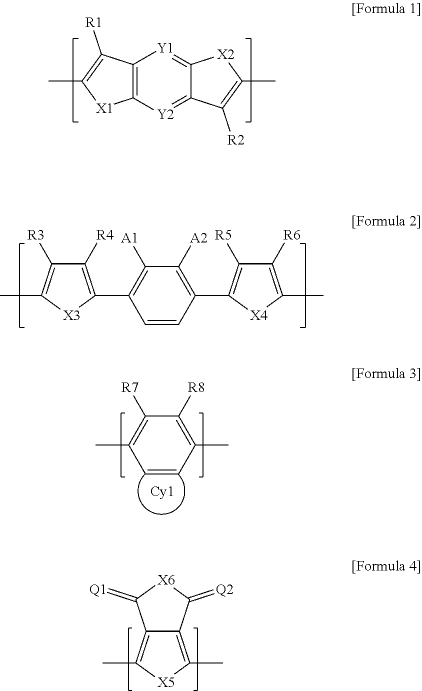
wherein:
X1 to X6 are the same as or different from each other, and are each independently CRR′, NR, O, SiRR′, PR, S, GeRR′, Se, or Te;
Y1 and Y2 are the same as or different from each other, and are each independently CR″, N, SiR″, P, or GeR″;
A1 and A2 are the same as or different from each other, and are each independently a halogen group;
Cy1 is a substituted or unsubstituted hetero ring;
Q1 and Q2 are the same as or different from each other, and are each independently O or S; and
R, R′, R″, and R1 to R8 are the same as or different from each other, and are each independently hydrogen, deuterium, a halogen group, a nitrile group, a nitro group, an imide group, an amide group, a hydroxyl group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted amine group, a substituted or unsubstituted aryl group, or a substituted or unsubstituted heterocyclic group.

2. The composition of claim 1, wherein the polymer is soluble in the non-halogen-based solvent in an amount of 1 mg or more per ml of the non-halogen-based solvent.

3. The composition of claim 1, wherein the non-halogen-based solvent comprises one or two or more selected from toluene, xylene, 2-methylanisole, ethylbenzene, trimethylbenzene, tolyl acetate, p-tolyl ether, and diphenyl ether.

4. The composition of claim 1, further comprising an electron acceptor.

5. The composition of claim 4, wherein the electron acceptor is a compound of Formula A: 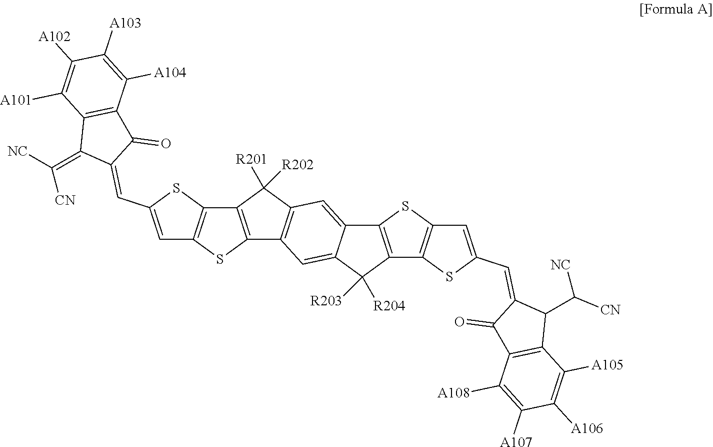
wherein:
R201 to R204 are the same as or different from each other, and are each independently a substituted or unsubstituted aryl group or a substituted or unsubstituted heteroaryl group; and
A101 to A108 are the same as or different from each other, and are each independently hydrogen, a halogen group, or a substituted or unsubstituted alkyl group.

6. The composition of claim 1, wherein the first unit is Formula 1-1: 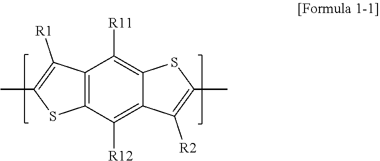
wherein:
of R1 and R2 are the same as defined in Formula 1; and
R11 and R12 are the same as or different from each other, and are each independently a substituted or unsubstituted alkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted aryl group, or a substituted or unsubstituted heterocyclic group.

7. The composition of claim 1, wherein the first unit is any one of Formulae 1-2 to 1-6: 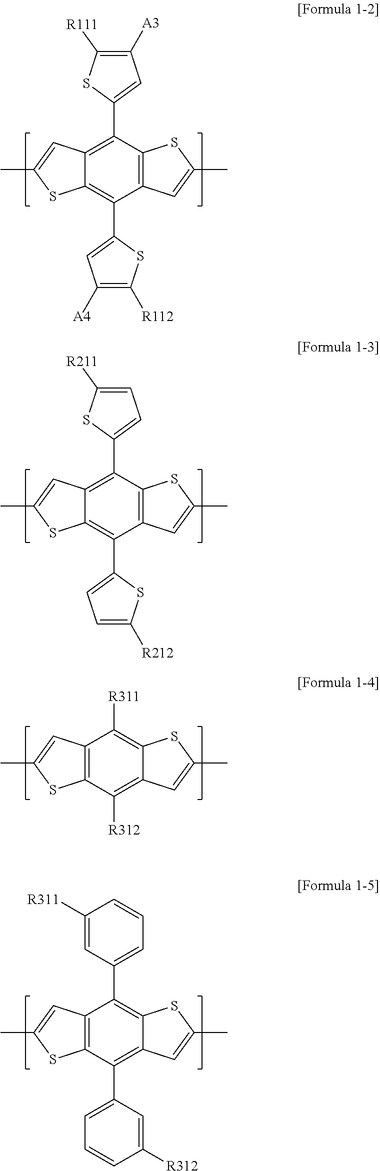 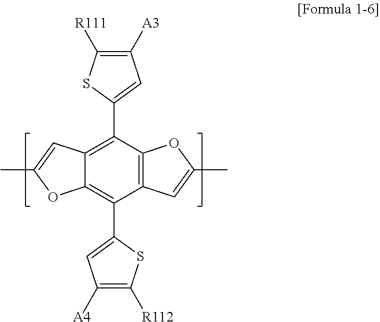
wherein:
A3 and A4 are the same as or different from each other, and are each independently a halogen group;
R111, R112, R211, and R212 are the same as or different from each other, and are each independently a substituted or unsubstituted alkyl group; or a substituted or unsubstituted alkylthioxy group; and
R311 and R312 are the same as or different from each other, and are each independently a substituted or unsubstituted alkyl group or a substituted or unsubstituted alkoxy group.

8. The composition of claim 1, wherein the second unit is Formula 2-1: 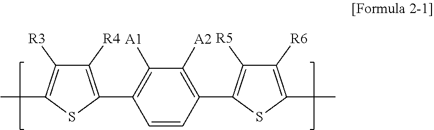
wherein R3 to R6, A1, and A2 are the same as defined in Formula 2.

9. The composition of claim 1, wherein the third unit is any one of Formulae 3-3 to 3-7: 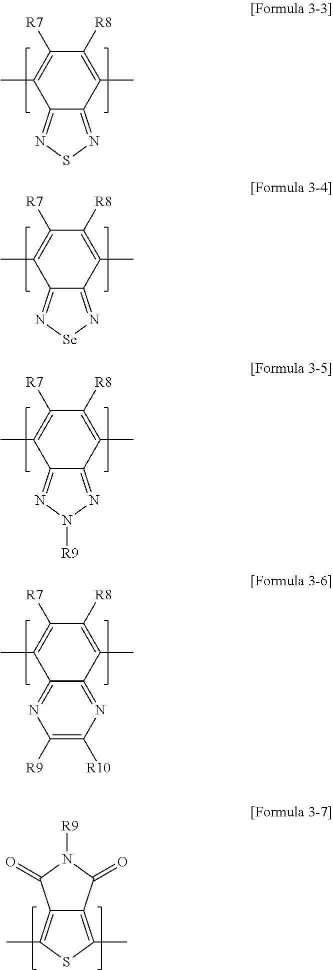
wherein:
R7 and R8 are the same as defined in Formula 3; and
R9 and R10 are the same as or different from each other, and are each independently hydrogen, a substituted or unsubstituted alkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted aryl group, or a substituted or unsubstituted heterocyclic group.

10. The composition of claim 1, wherein the polymer comprises a unit of Formula 5: 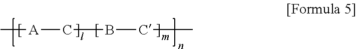
wherein:
l is a mole fraction and is a real number of 0<l<1;
m is a mole fraction and is a real number of 0<m<1;
l+m=1;
A is the first unit of Formula 1;
B is the second unit of Formula 2;
C and C′ are the same as or different from each other, and are each independently the third unit of Formula 3 or Formula 4; and
n is a repeating number of the unit and is an integer from 1 to 10,000.

11. The composition of claim 1, wherein the polymer comprises a unit of Formula 5-1 or 5-2: 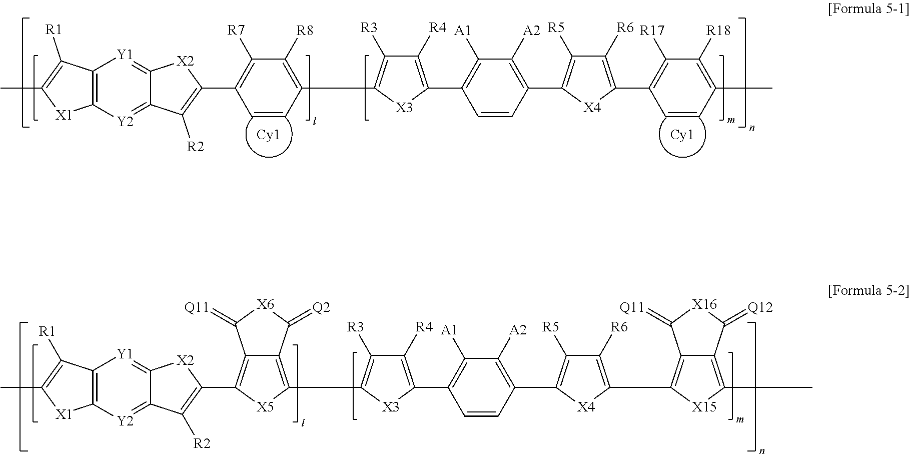
wherein:
X1 to X6, Y1, Y2, R1 to R8, Cy1, Q1, Q2, A1, and A2 are the same as defined in Formulae 1 to 4;
Cy11 is a substituted or unsubstituted hetero ring;
Q11 and Q12 are the same as or different from each other, and are each independently O or S;
X15 and X16 are the same as or different from each other, and are each independently CRR′, NR, O, SiRR′, PR, S, GeRR′, Se, or Te;
R, R′, R17, and R18 are the same as or different from each other, and are each independently hydrogen, deuterium, a halogen group, a nitrile group, a nitro group, an imide group, an amide group, a hydroxyl group, a substituted or unsubstituted alkyl group, a substituted or unsubstituted cycloalkyl group, a substituted or unsubstituted alkoxy group, a substituted or unsubstituted aryloxy group, a substituted or unsubstituted alkylthioxy group, a substituted or unsubstituted arylthioxy group, a substituted or unsubstituted alkylsulfoxy group, a substituted or unsubstituted arylsulfoxy group, a substituted or unsubstituted alkenyl group, a substituted or unsubstituted amine group, a substituted or unsubstituted aryl group, or a substituted or unsubstituted heterocyclic group;
l is a mole fraction and is a real number of 0<l<1;
m is a mole fraction and is a real number of 0<m<1;
l+m=1; and
n is a repeating number of the unit and is an integer from 1 to 10,000.

12. The composition of claim 1, wherein the polymer comprises a unit of Formula 5-3: 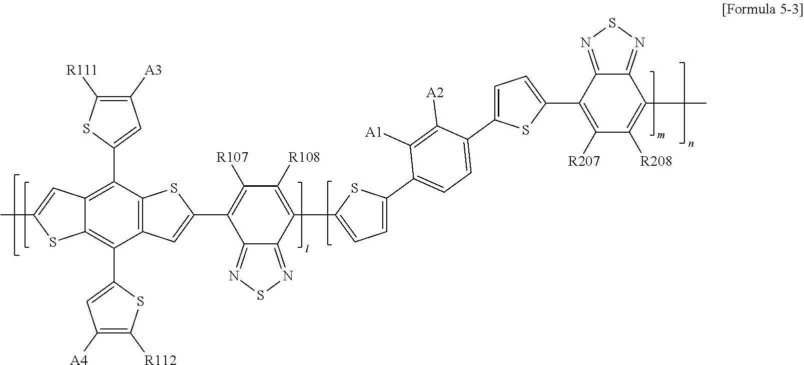
wherein:
A1 to A4 are the same as or different from each other, and are each independently a halogen group;
R107, R108, R207, and R208 are the same as or different from each other, and are each independently a substituted or unsubstituted alkoxy group;
R111 and R112 are the same as or different from each other, and are each independently a substituted or unsubstituted alkyl group or a substituted or unsubstituted alkylthioxy group;
l is a mole fraction and is a real number of 0<l<1;
m is a mole fraction and is a real number of 0<m<1;
l+m=1; and
n is a repeating number of the unit and is an integer from 1 to 10,000.

13. The composition of claim 1, wherein the polymer comprises a unit of any one of Formulae 5-4 to 5-39: 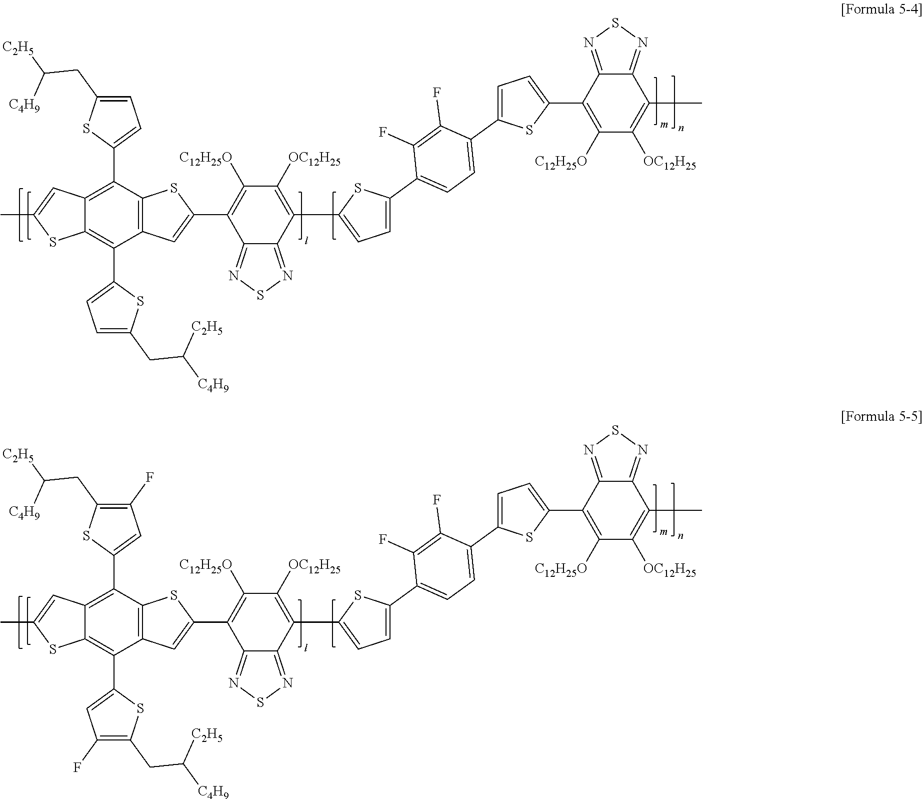 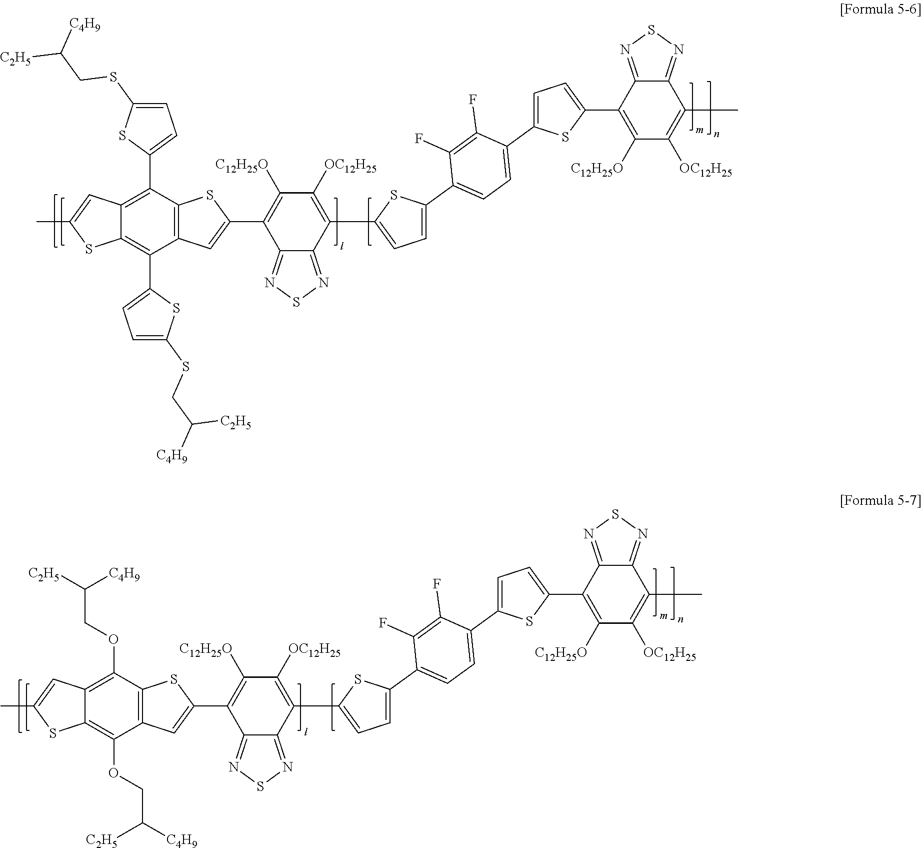 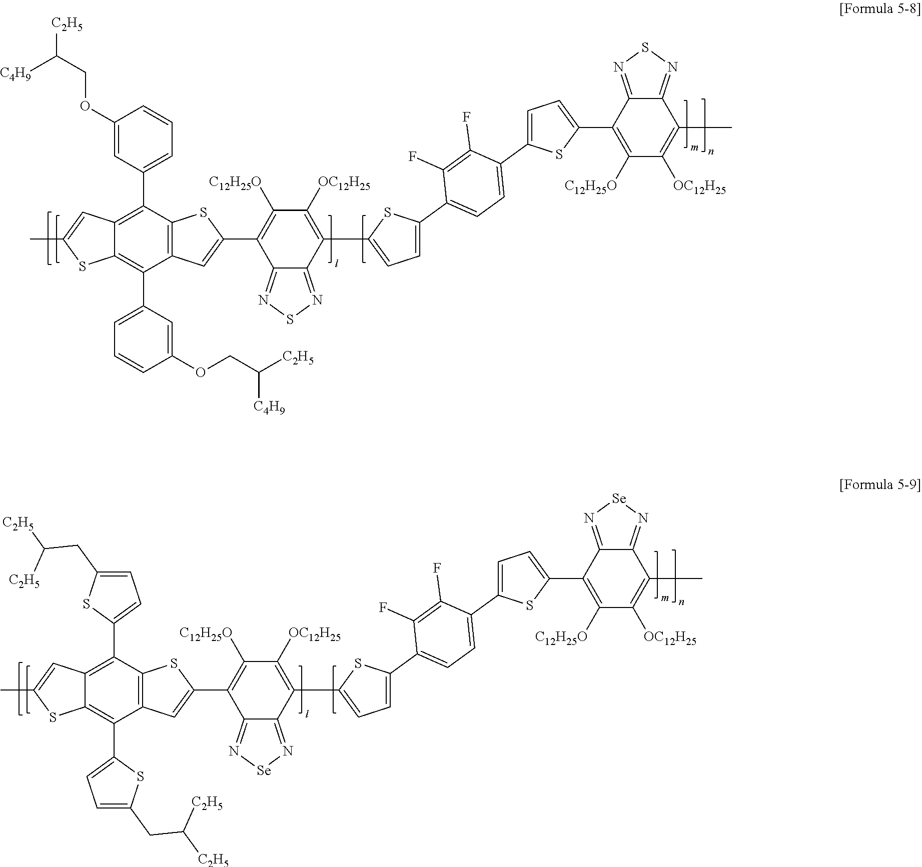 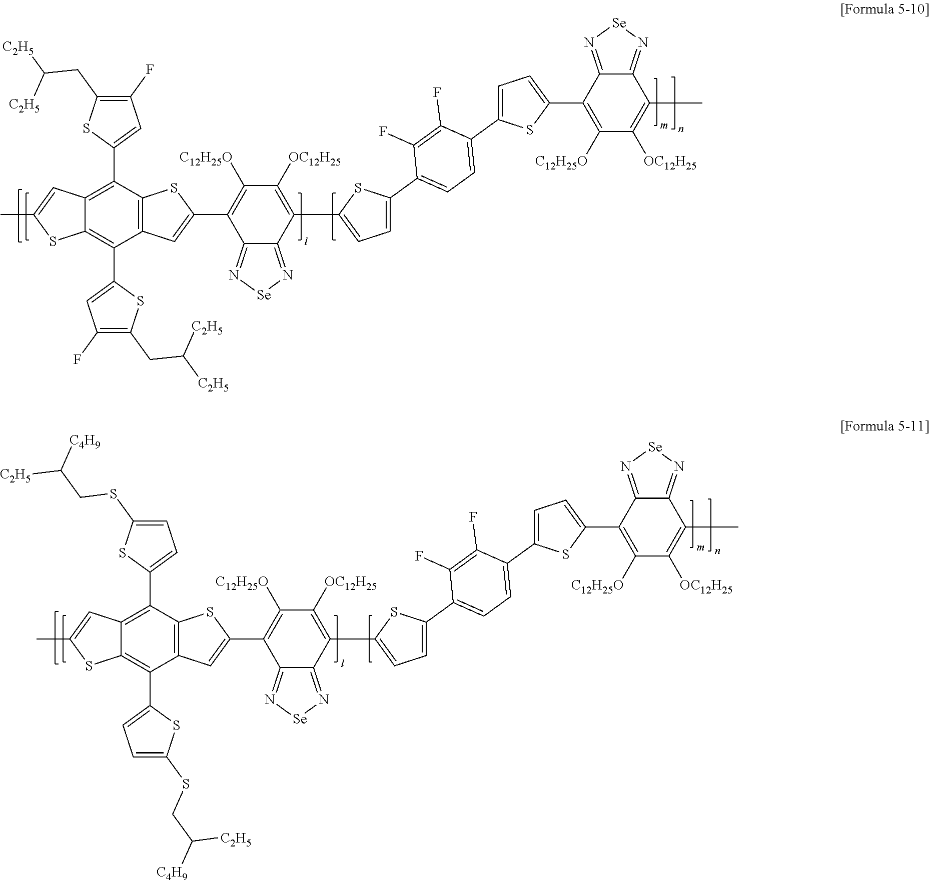 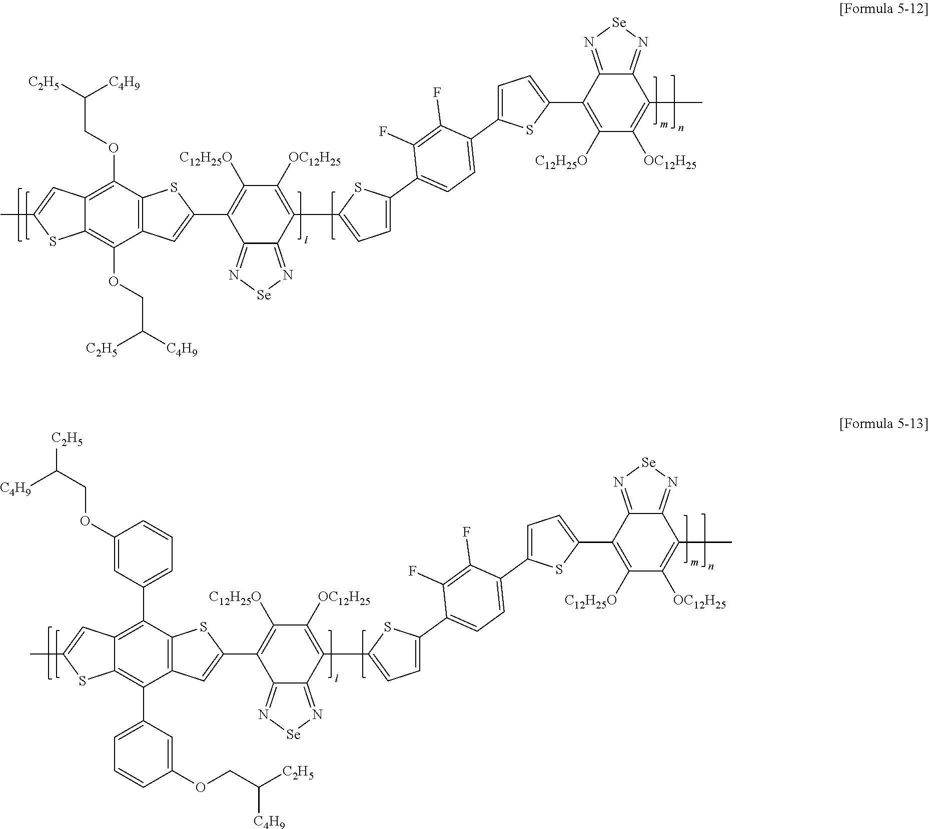 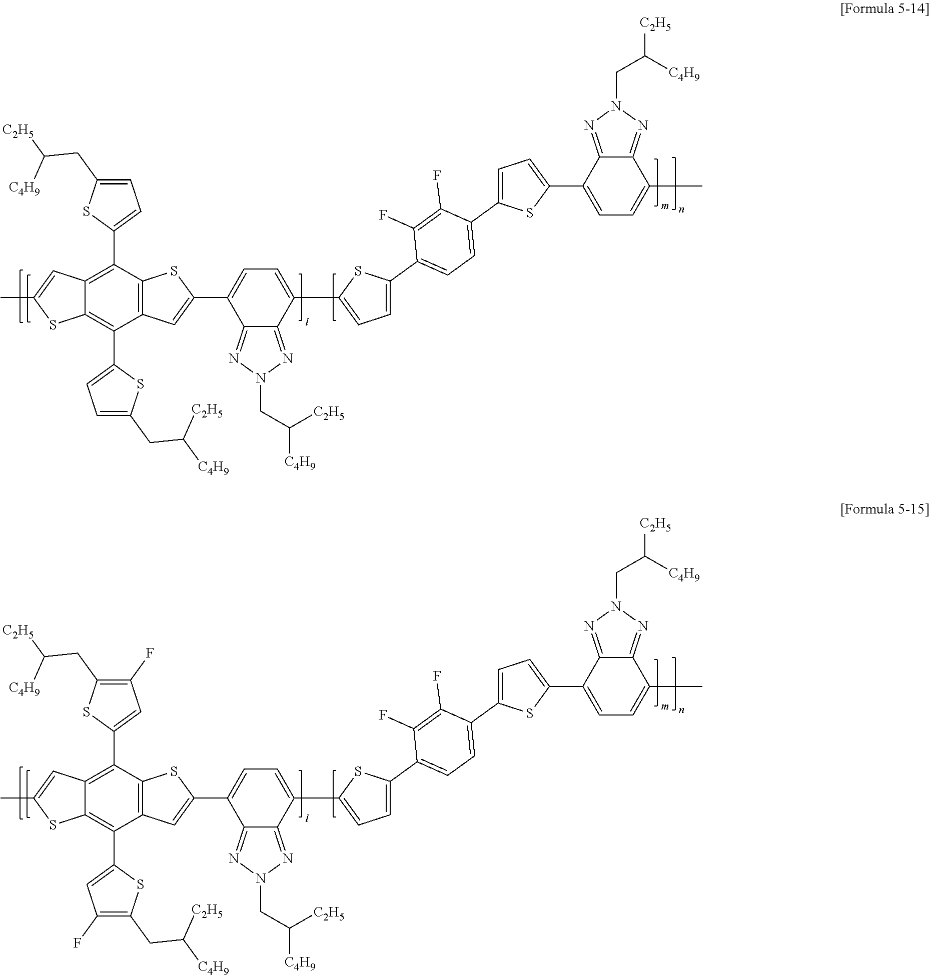 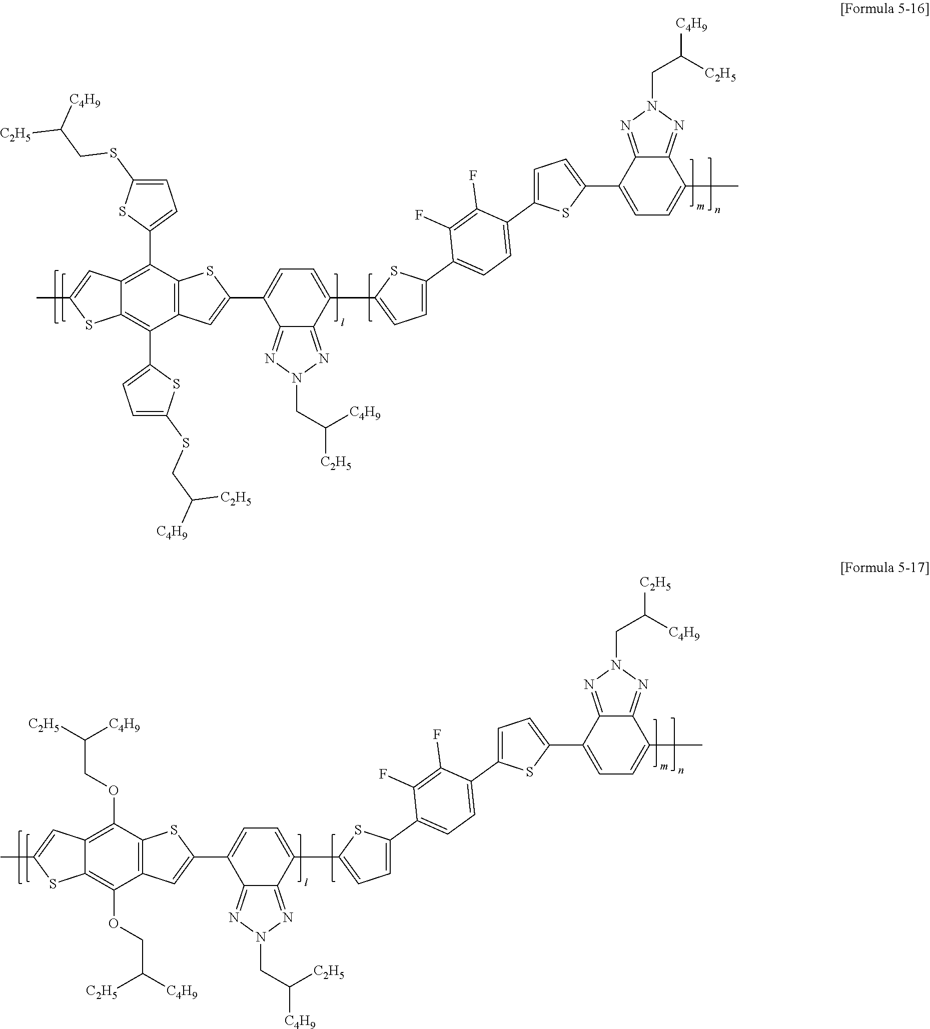 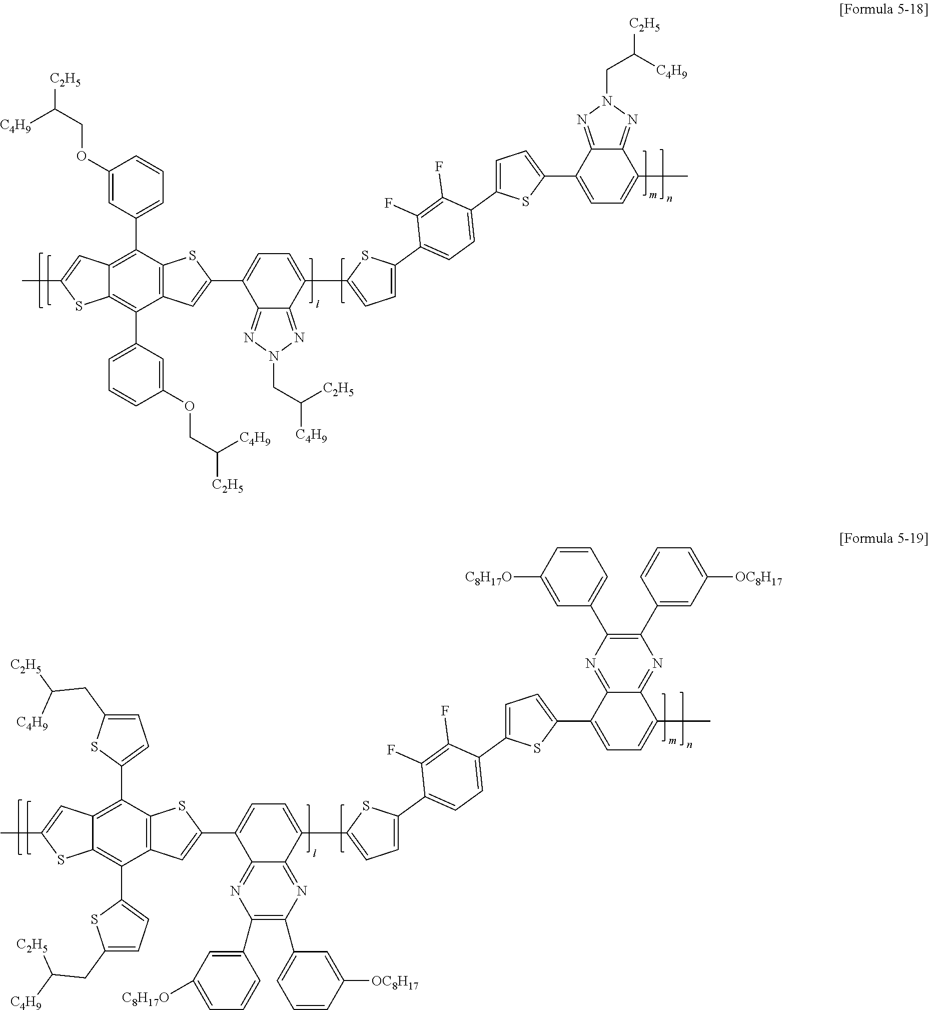 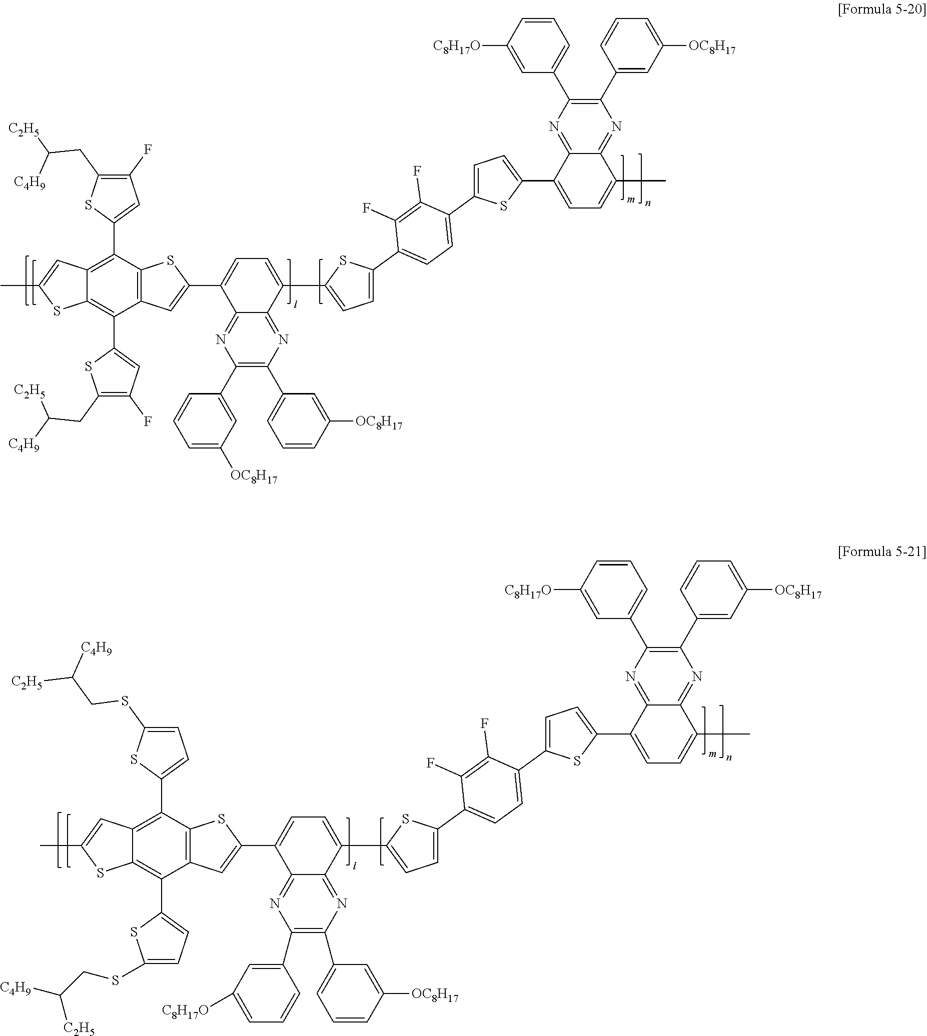 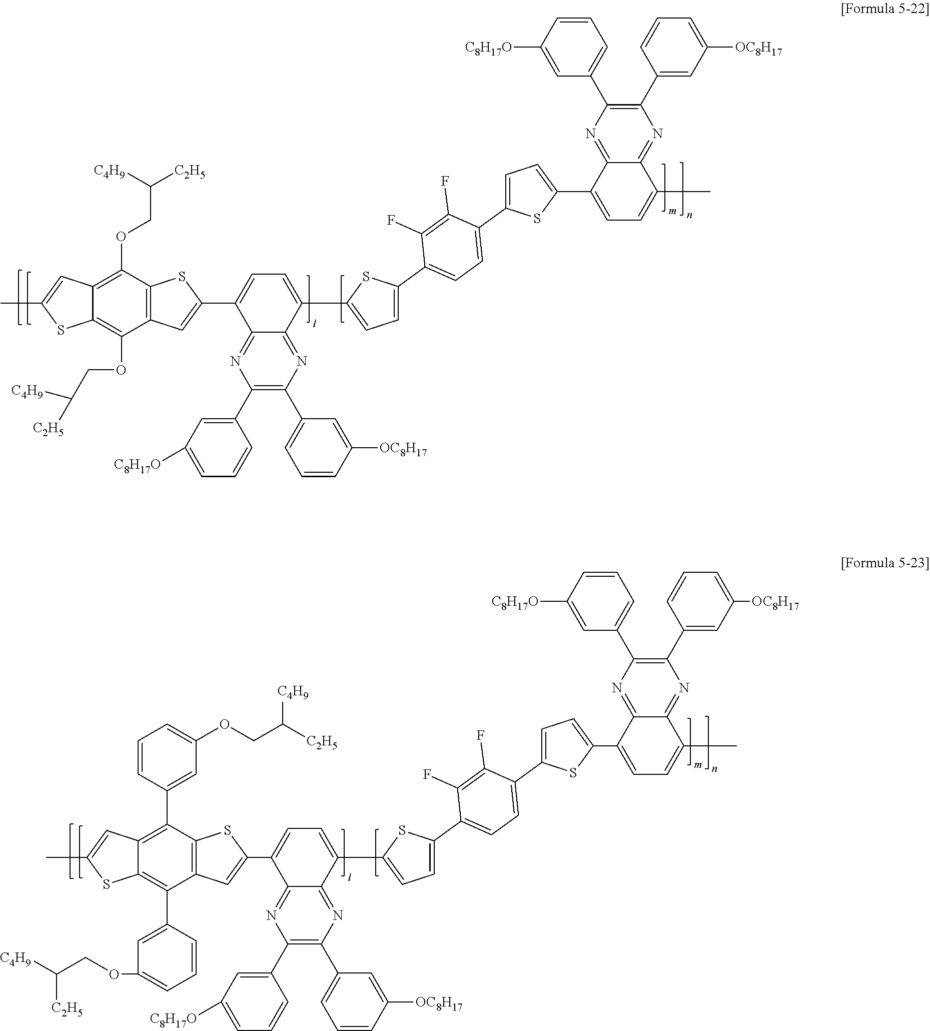 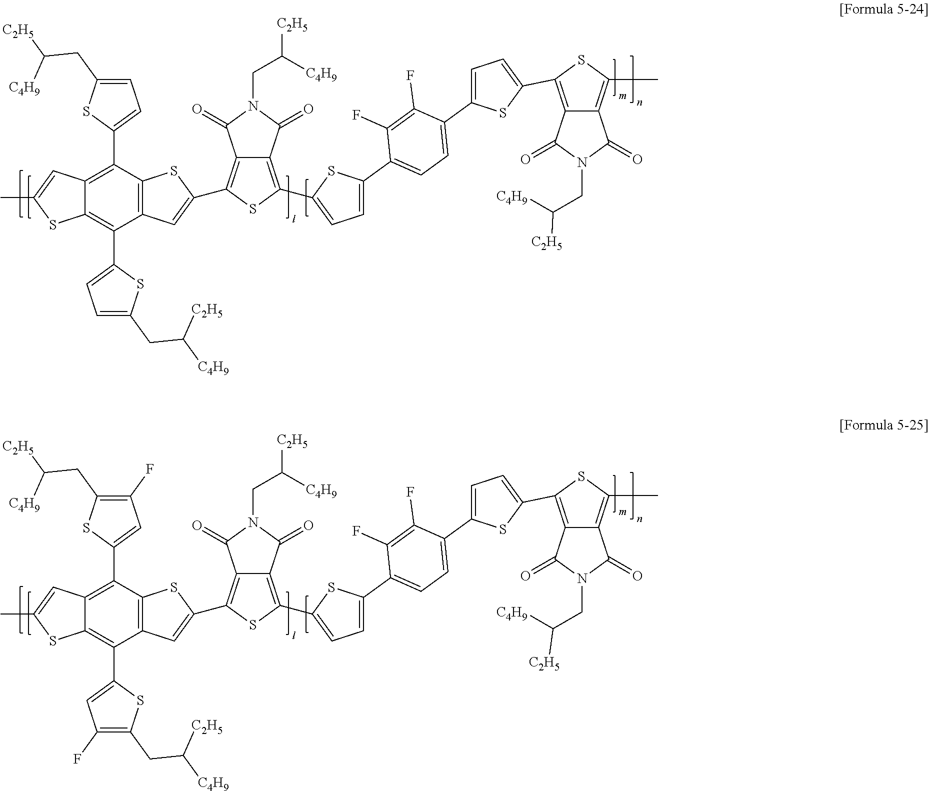 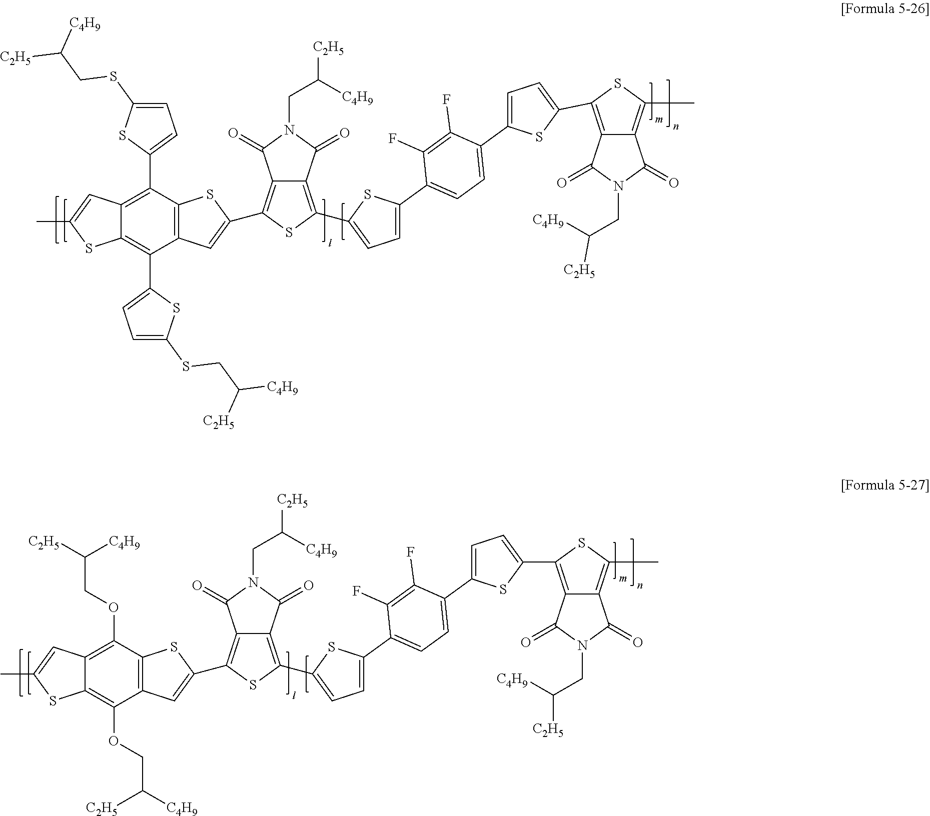 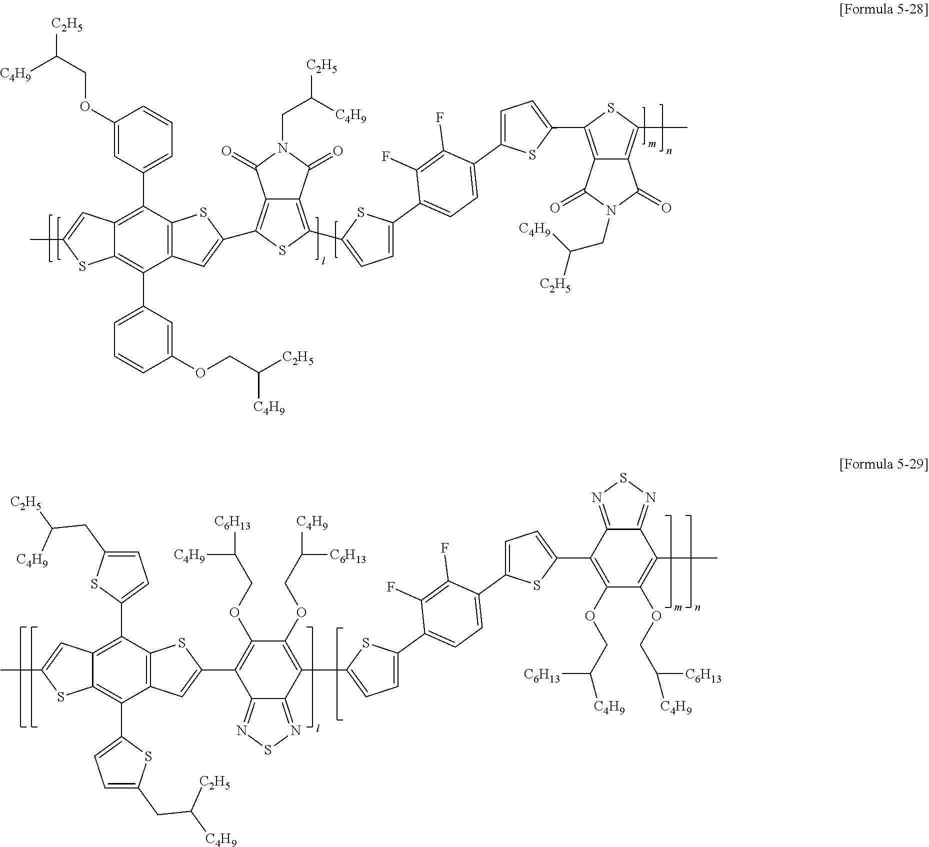 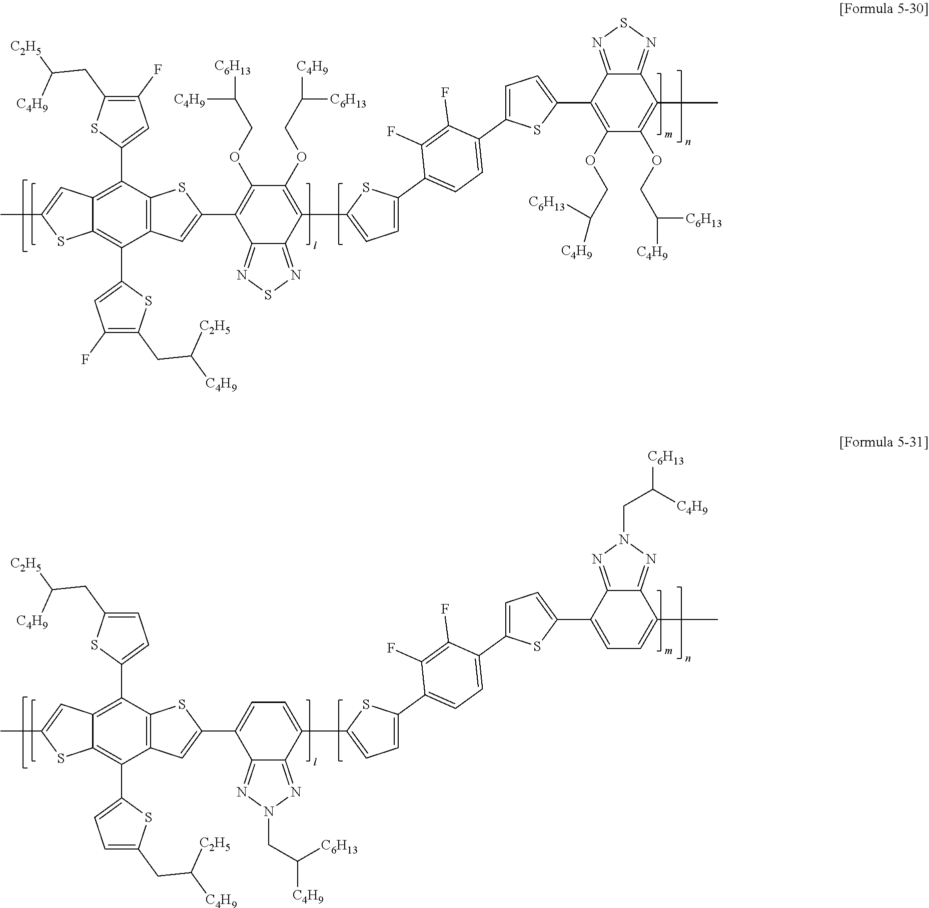 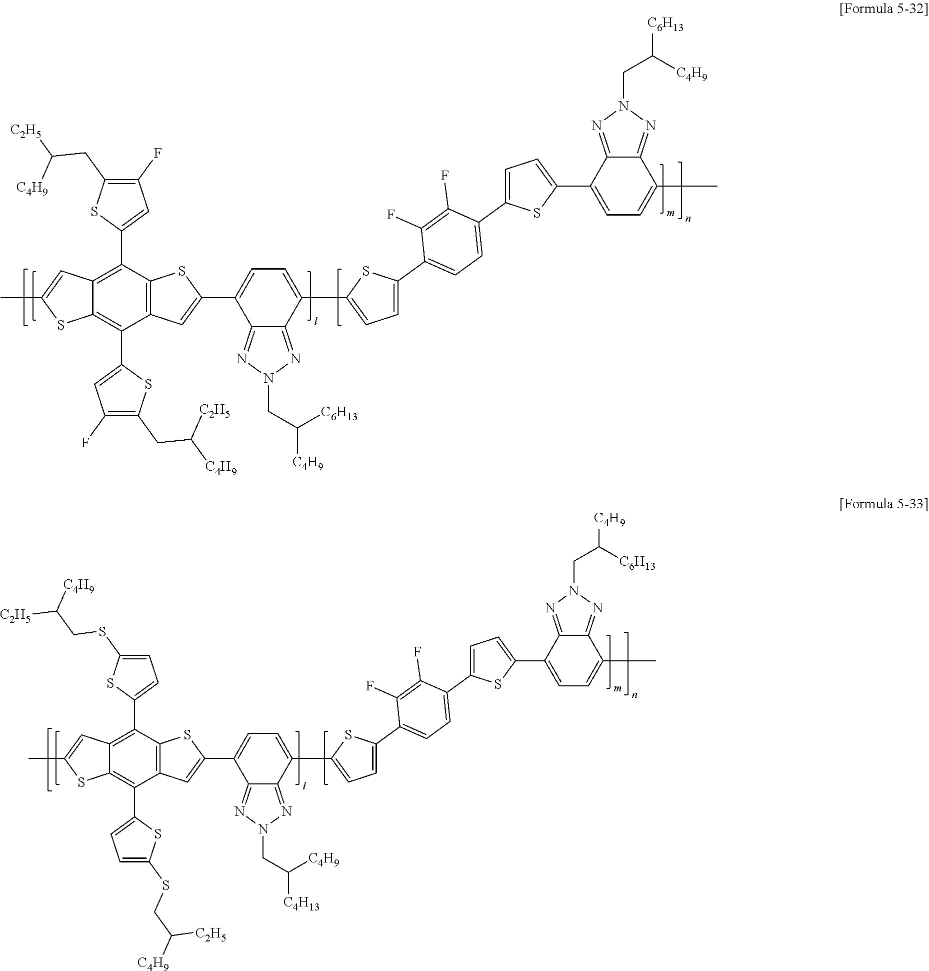 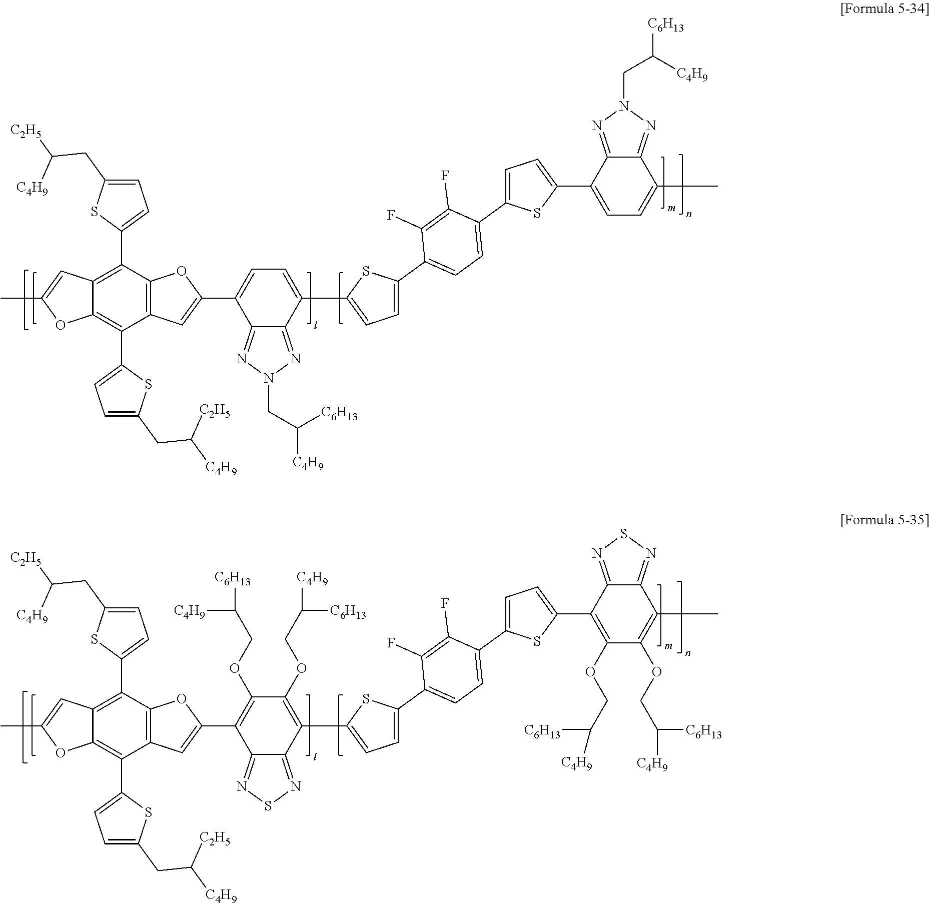 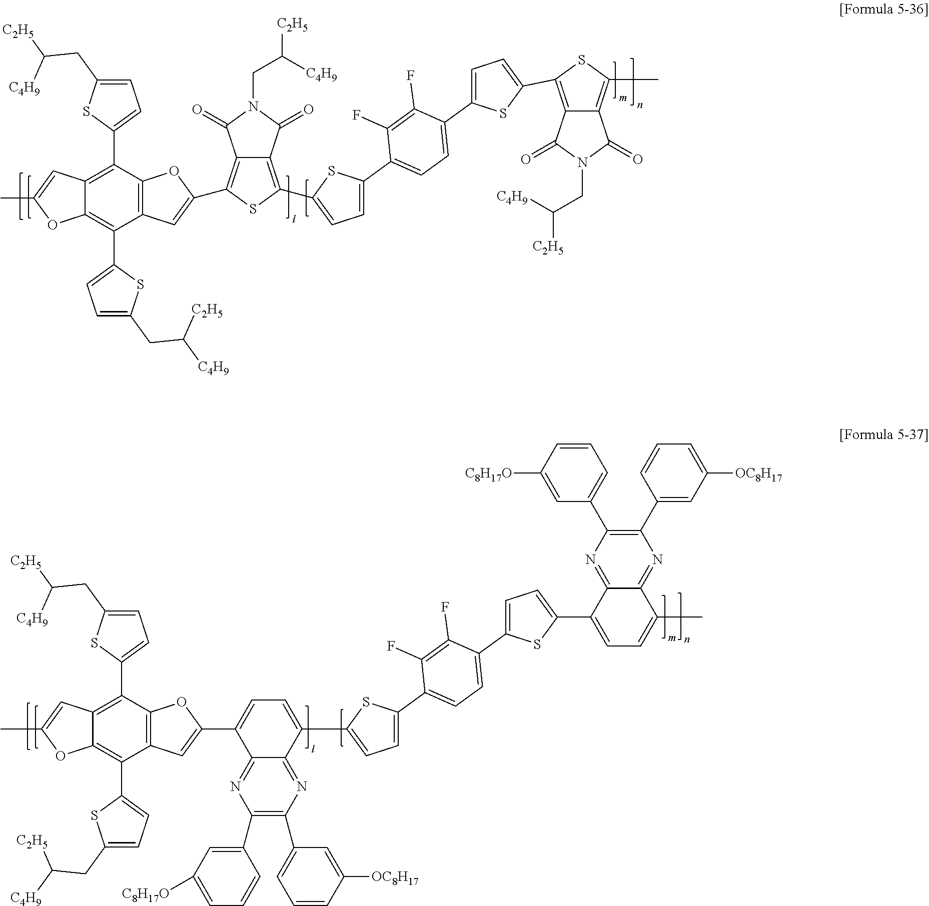 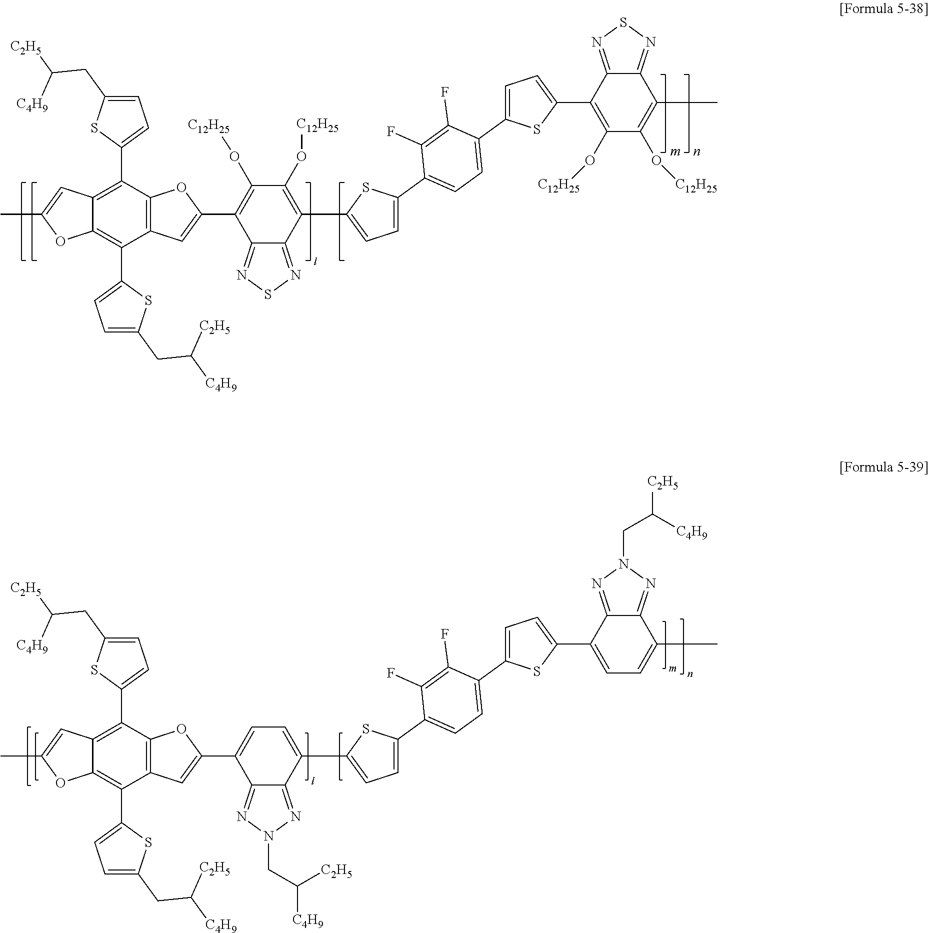
wherein:
l is a mole fraction and is a real number of 0<l<1;
m is a mole fraction and is a real number of 0<m<1;
l+m=1; and
n is a repeating number of the unit and is an integer from 1 to 10,000.

14. A method for manufacturing an organic solar cell, the organic solar cell comprising:
a first electrode;
a second electrode on the first electrode; and
an organic material layer comprising one or more layers, wherein the organic material layer is between the first electrode and the second electrode and comprises a photoactive layer, and
wherein the one or more layers of the organic material layer are formed by using the composition of claim 1.

15. An organic solar cell comprising:
a first electrode;
a second electrode on the first electrode; and
an organic material layer comprising one or more layers, wherein the organic material layer is between the first electrode and the second electrode and comprises a photoactive layer, and
wherein the one or more layers of the organic material layer are formed by using the composition of claim 1.

16. The composition of claim 1, wherein the second unit is Formula 2-2:

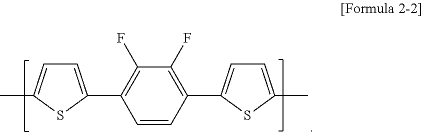

17. The composition of claim 13, wherein l is 0.5, and m is 0.5.
